(19) United States
(12) Patent Application Publication
(10) Pub. No.: US 2022/0115503 A1
(43) Pub. Date: Apr. 14, 2022

(54) Methods of Design and Use of High Mobility P-Type Metal Oxides

(71) Applicants: Board of Regents, The University of Texas System, Austin, TX (US); Cornell University, Ithaca, NY (US); University of Notre Dame du Lac, South Bend, IN (US)

(72) Inventors: Kyeongjae Cho, Frisco, TX (US); Yaoqiao Hu, Richardson, TX (US); Darrell Galen Schlom, Ithaca, NY (US); Suman Datta, South Bend, IN (US)

(21) Appl. No.: 17/068,337

(22) Filed: Oct. 12, 2020

(51) Int. Cl. H01L 29/24; H01L 29/66; H01L 29/786

(52) U.S. Cl. CPC H01L 29/24; H01L 29/7869; H01L 29/66969

(57) ABSTRACT

Provided by the inventive concept are electronic devices, such as semiconductor devices, including p-type oxide materials having and selected for having improved hole mobilities, band gaps, and phase stability, and methods for fabricating electronic devices having such p-type oxide materials.

### CROSS REFERENCE TO RELATED APPLICATION

This application claims the benefit of U.S. Provisional Application Ser. No. 63/913,909, filed Oct. 11, 2019, the entirety of which is incorporated herein by reference.

### STATEMENT OF GOVERNMENT SUPPORT

This invention was made with government support under Grant No. HR0011-18-3-0004 awarded by the Department of Defense/Defense Advanced Research Products Agency (DARPA). The government has certain rights in the invention.

### FIELD

The inventive concept relates to improved materials, more particularly improved p-type oxides for use in the semiconductor industry.

### BACKGROUND

Monolithic 3D integration or vertical CMOS is considered an attractive option for hyper-scaling integrated circuits.^{1,2} In the vertical CMOS, multiple layers of logic circuitry and memory are vertically stacked so as to continue the exponential increase in the density of devices and alleviate the processing-storage communication bottleneck.¹⁻⁵ Vertical CMOS technology requires the upper layer circuits be processed with controlled thermal budget so as not to compromise the electrical quality of the lower front-end layers.^{4,5} In addition, access transistors and peripheral logic transistors in the vertically stacked memory cells should exhibit high on-state drive current and low off-state current leakage.¹ Accordingly, the channel materials for the upper layer transistors should have back-end-of-line (BEOL) compatible low processing temperature (below 400° C.), relatively large bandgap (>1.5 eV) to ensure ultra-low current leakage, and good carrier mobility (>150 cm²/(V·s) for electrons, >100 cm²/(V·s) for holes) for high drive current.¹ Semiconducting metal oxides (MO) are promising candidates for vertical CMOS channel materials due to their ease of synthesis at low temperature and wide band gap.^{1,6,7} To date, these metal oxide semiconductors have been almost exclusively studied as the transparent conducting electrodes for flexible electronics and optoelectronics.⁸⁻¹¹ For instance, indium tin oxide (ITO) films, with a band gap ˜3.75 eV, a resistivity as low as 10⁻⁴ Ω·cm, and the electron mobility up to 100 cm²/(V·s)¹⁰, are widely used for transparent electrodes in flat-panel displays and thin-film solar cells.⁸⁻¹³ For BEOL-compatible vertical FETs, high-mobility MO with bandgaps exceeding 1.5 eV appear attractive for n-channel transistors in the upper layers for applications as logic and memory access transistors.¹ However, most developed and commercialized oxide semiconductors are limited to n-type conduction, and p-type oxides have inferior performance due to carrier mobilities which are significantly lower than that of their n-type counterparts.¹⁴ Developing high mobility p-type oxides would enable a complementary transistor solution that provides more flexibility for the design and implementation of more efficient BEOL vertical CMOS devices.

The low hole mobilities in p-type oxides originate from the flat valence bands and the corresponding large effective mass of holes arising from the localized oxygen 2p orbitals at the valence band edge.^{15,16} Introducing extended orbital electronic states at the valence band maximum (VBM) above the oxygen 2p-orbital would enable a development of high mobility p-type oxides.¹ Such extended hybrid electronic states can be derived from a metal atom's s orbitals, and would result in a very small hole effective mass. This effect can provide high hole mobilities since the underlying mechanism for high mobility of n-type oxides arises from the same s orbitals as empty states. Tin based oxides such as SnO and K₂Sn₂O₃ have recently been shown to satisfy this condition, with the 5s orbital of Sn²⁺ forming the VBM.¹⁶ The electronic band structures of SnO and K₂Sn₂O₃ have been calculated confirming the large band dispersion at the VBM, which corresponds to small hole effective mass values.^{1,16} However, the band gap of SnO (˜0.6 eV) is too small for practical p-type oxide devices, and the marginal phase stability of K₂Sn₂O₃¹⁶ can be a serious issue leading to K contamination of the surrounding device structures by phase changes of K₂Sn₂O₃→KSn₂O₃+K→Sn₂O₃+2K. Furthermore, a design rule based simply on the carrier effective masses does not provide quantitative mobility values, which incorporate carrier scattering rates. Although the small effective mass is a key characteristic useful for rapid screening of high hole mobility oxides, a detailed mobility calculation is critical to obtain more accurate values of the intrinsic mobilities and to confirm whether a candidate p-type oxide exhibits high hole mobility.

Thus, there remains a need for improved p-type oxide materials for application in, for example, back-end-of-line (BEOL) vertical CMOS devices over those currently available.

### SUMMARY OF THE INVENTION

According to an aspect of the inventive concept, provided is a semiconductor device including a p-type metal oxide of formula: M-O—X, wherein M is a metal or metal ion having an electron configuration of (n−1)d¹⁰ns², X is a metal, metal ion, non-metal, or non-metal ion, and wherein M is a metal or metal ion having an electron configuration of (n−1)d¹⁰ns², X is a metal, metal ion, non-metal, or non-metal ion, and wherein the p-type oxide material has an Eₕᵤₗₗ less than or equal to about 0.03 eV, a hole mobility greater than about 30 cm²/Vs, and a band gap greater than or equal to about 1.5 eV.

According to another aspect of the inventive concept, provided is a method of forming an electronic device, the method including: forming a gate electrode on a substrate; forming a dielectric layer on the gate electrode, the dielectric layer comprising a p-type oxide material selected to provide extended orbital electronic states as a valence band electron above an oxygen p-orbital of the p-type oxide material and to provide phase stability of the p-type oxide material; forming a semiconductor substrate on the dielectric layer opposite the gate electrode to provide a channel region in the semiconductor substrate opposite the gate electrode; and forming a source region on the semiconductor substrate and forming a drain region on the semiconductor substrate at opposing ends of the channel region.

According to another aspect of the inventive concept, provided is a semiconductor device comprising a p-type oxide material of formula (I): M-O—X (I), wherein M is a metal or metal ion, X is a metal, metal ion, non-metal, or non-metal ion, and wherein the p-type oxide material is selected to provide extended orbital electronic states at a valence band maximum (VBM) above an oxygen p-orbital of the p-type oxide material and to provide phase stability of the p-type oxide material.

### BRIEF DESCRIPTION OF THE DRAWINGS

FIG. 1 The electron-phonon coupling matrix elements for each POP (both LO and TO) mode at |q|=0.05 2π/a (a is lattice constant) in (a) SnO, (b) SnO₂, and (c) Ta₂SnO₆. The squared modulus of coupling matrix elements is used and normalized according to 1=Σ_{λ}(g_{q}^{λ})² FIG. 2. Total scattering rates and the contributions by several strong coupling branches in (a) SnO, (b) SnO₂, and (c) Ta₂SnO₆. The carrier distributions are also plotted to the righty axis. Only electron/hole moving along z direction are presented.

FIG. 3 Illustration of materials screening procedure for high-mobility and thermodynamically stable p-type oxides.

FIG. 4 Flow chart of materials screening and selection for high-mobility and thermodynamically stable p-type oxides.

FIG. 5 First-principles calculated phase stability diagram of Sn—Sr—O in the Sn—Sr chemical potential space. Various combinations of the competing phases including all the existing binary and ternary compounds originates from the Materials Project. Clearly, there is no space for SrSnO₃, which means that SrSnO₃ is not a stable phase over the entire the Sn—Sr chemical potential range.

FIG. 6 First-principles calculated phase stability diagram of Sn—Ba—O in the Sn—Ba chemical potential space. Various combinations of the competing phases including all the existing binary and ternary compounds originates from the Materials Project. Similarly, there is no space for BaSnO₃, which means that BaSnO₃ is not a stable phase over the entire the Sn—Ba chemical potential range.

FIG. 7 Mobility versus effective mass for the identified Sn²⁺ based p-type oxides. The detailed data fitting revels that the hole mobility quite follows the effective mass by a power function with the parameter of −1.89.

FIG. 8 Crystal structure of (a) SnO, (b) K₂Sn₂O₃, and (c) Ta₂SnO₆. The SnOₓ and XOₓ polyhedra in these compounds are shown. In K₂Sn₂O₃ the SnO₄ polyhedra are continuously connected while in Ta₂SnO₆ the SnO₄ and TaO₆ are alternating with each other.

FIG. 9 First principles calculated phase stability diagram in terms of Sn—X chemical potential maps. The panels refer to (a) K—Sn—O, (b) Rb—Sn—O, (c) P—Sn—O, (d) Ti—Sn—O, (e) Ta—Sn—O, (f) Cs—Sn—O, (g) Na—Sn—O, (h) Ge—Sn—O, (i) B—Sn—O. The green region of Sn and X chemical potentials indicates where the identified p-type Sn—O—X compound phase is stable.

FIG. 10 (a) Molecular orbital diagrams and (b) band structures of SnO. The band structure is computed at HSE level A color scheme is used to visualize the atomic orbital contribution to each band. Blue color represents Sn atom while red represents O atom.

FIG. 11 (a), (d) Molecular orbital diagrams, (b), (e) band structures of Sn—O—X compounds, and (c), (f) band structures of Sn—O—X lattices without X elements. (a), (b) and (c) correspond to K₂Sn₂O₃ while (d), (e), (f) correspond to Ta₂SnO₆. The band structures are computed at GGA level. No scissor operator has been applied since there are no available experimental band gaps for these Sn—O—X compounds. A color scheme is used to visualize the atomic orbital contribution to each band. Blue color stands for Sn atom, red for O atom, and green for X atom.

FIG. 12 Mobility versus band gap for the identified Sn²⁺ based p-type oxides. There is a broad distribution of both the hole mobility and the effective mass among the Sn²⁺ containing ternary oxides.

FIG. 13 Zoomed in chemical potential phase diagram of Ti—Sn—O and Ta—Sn—O illustrating the geometric features of Sn²⁺—O—X p-type oxides. The stability area for (a) TiSnO₃ and (b) Ta₂SnO₆ are defined by two sets of borderlines. One set are two parallel borderlines with TiO₂ and SnO (first common feature) dictating the propensity of decomposition into its constituent binary oxides, while the other set are borderlines with pure Sn and SnO₂ (second common feature) corresponding to the Sn²⁺ valance stability.

FIG. 14 Convex hull of the ternary Sn—O—X system with the component binary oxides at two ends showing the stabilization energy of p-type oxides Sn²⁺—O—X. The vertical axis is the formation energy and the horizontal axis is composition. For Ta and Ti, Sn²⁺—O—X compounds is the only possible Sn—O—X ternary system, hence the stabilization energy is directly governed by the formation energy difference between Sn²⁺—O—X and their component binary oxides. For K, however, in addition to p-type oxides K₂Sn₂O₃, K₂SnO₂ and K₄SnO₃ can also stably exist, limiting K₂Sn₂O₃ phase to a marginal stability area. It can be seen that although K₂Sn₂O₃ shows a large stabilization energy (SE) against SnO and K₂O, it does not exhibit a deep formation energy (δE′) when compared to its bordered phases.

### DETAILED DESCRIPTION

The foregoing and other aspects of the present invention will now be described in more detail with respect to other embodiments described herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

Unless otherwise defined, all technical and scientific terms used herein have the same meaning as commonly understood by one of ordinary skill in the art to which this invention belongs.

The present inventive concept relates to the development of high-mobility p-type oxides. Two of the features described in this inventive concept include: the design process for high p-type mobility oxides is based on the Sn²⁺ containing oxide compounds; and using the valence band dispersions available from the online database Materials Project as an efficient and reliable screening parameter to rapidly identify high-mobility p-type oxides.

The low hole mobilities in p-type oxides originate from the flat valence bands and the resulting large effective hole mass, due to the localized oxygen 2p orbitals at the valence band edge (VBE) or valence band maximum (VBM). Introducing extended orbital electronic states at the VBM above the oxygen 2p orbital would enable a development of high mobility p-type oxides. Such extended hybrid electronic states can be derived from a metal atom's s orbitals and are expected to bring about a very small hole effective mass. This effect can provide high hole mobilities since the underlying mechanism for high mobility of n-type oxides arises from the same s orbitals as empty states. Tin based oxides such as SnO and K₂Sn₂O₃ have recently been shown to satisfy this condition, with the 5s orbital of Sn²⁺ forming the VBE. The electronic band structures of SnO and K₂Sn₂O₃ have been calculated confirming the large band dispersion at the VBM, which corresponds to small hole effective mass values. Given this, high-hole-mobility p-types oxides can be identified or designed by the rules that oxides have Sn²⁺ as their chemical constituent and that their VBMs contain considerable Sn²⁺ 5s orbital contribution.

For the purpose of designing p-type high mobility oxides, phase stability is another important criterion. Since the additional valance states by metal's orbitals above oxygen p-orbital would have general tendency to make the oxide less stable, the material design has to ensure their thermodynamic phase stabilities while achieving the low effective hole masses. Several promising oxide systems (REZnPO (RE=rare earth), ABi₂Ta₂O₉ (A=Ca, Sr, Ba), etc.) have shown that such balance can be achievable. Phase stability can be evaluated through calculating the phase diagram using the principles of thermodynamics, which can be readily accomplished by first-principles calculations. The process of developing high-mobility p-type oxides is designed as follows. (1) Potential oxide candidates are first selected from materials database (e.g., Materials Project, Inorganic Crystal Structure Database, etc.) based on the rule that Sn exhibits nominal +2 charge state and that its valence band edge shows strong E-k dispersion. (2) A Bader charge analysis can then be performed to confirm the Sn 2+ oxidation state in the potential candidates. (3) The effective hole masses and band gaps are then evaluated through a detailed electronic band structure calculation. A scaling relation between effective mass and mobility suggests that Sn²⁺ based oxides with effective hole mass <0.4 m₀ would generally exhibit a p-type mobility >100 cm²V⁻¹s⁻¹. (4) A phase diagram of Sn—O—X (X is the third element) system will be computed to ensure that the identified high-mobility p-type oxides are thermodynamically stable over other competing phases. The developing process described here is effective and efficient for high-mobility p-type oxides designing without having to resorting to intensive computation resources.

Under this designing framework, we have identified several high figure-of-merit p-type oxides from the ternary oxide databases, including K₂Sn₂O₃, Rb₂Sn₂O₃, TiSnO₃, Cs₂Sn₂O₃, and Ta₂SnO₆. All these candidates exhibit small effective hole masses and occupy considerable phase space in the Sn—O—X phase diagram. The method described here is a high-throughput computational screening that will accelerate the materials discovery and help guide the experimental realization of high mobility p-type oxides.

Vertical CMOS technology highly relies on the development of high-mobility p-type oxides. The present computational materials design of high-mobility Sn²⁺ based p-type oxides will provide a solution for the channel materials selection for the vertical CMOS technology. Our design process might also be helpful for the development of transparent conducting electrodes in flexible electronics and optoelectronics, where p-type oxides with good conductivity are required.

According to embodiments of the inventive concept, high-mobility p-type oxide materials provided include ternary oxides, for example, a material of formula (I):

M-O—X (I)

wherein M is a metal or metal ion, and X is a metal, a metal ion, a non-metal or a non-metal ion.

Characteristics of the p-type oxide material may include, for example, a high hole mobility, small hole effective mass, a large band gap, and good phase stability. In some embodiments, hole mobility of the p-type oxide material may be in a range of about 1-500 cm²V⁻¹s⁻¹, about 10-500 cm²V⁻¹s⁻¹, or about 30-500 cm²V⁻¹s⁻¹, for example, greater than or equal to about 5 cm²V⁻¹s⁻¹, about 10 cm²V⁻¹s⁻¹, about 20 cm²V⁻¹s⁻¹, about 30 cm²V⁻¹s⁻¹, about 40 cm²V⁻¹s⁻¹, about 50 cm²V⁻¹s⁻¹, about 60 cm²V⁻¹s⁻¹, about 70 cm²V⁻¹s⁻¹, about 80 cm²V⁻¹s⁻¹, about 90 cm²V⁻¹s⁻¹, about 100 cm²V⁻¹s⁻¹, about 200 cm²V⁻¹s⁻¹, about 300 cm²V⁻¹s⁻¹, or about 400 cm²V⁻¹s⁻¹, up to the theoretical predicted intrinsic mobilities for the p-type oxide material. In some embodiments, the hole effective mass may be in a range of about 0.1-10 m₀, or about 0.1-4 m₀, for example, less than or equal to about 5 m₀, about 4 m₀, about 3 m₀, about 2 m₀, about 1 m₀, about 0.9 m₀, about 0.8 m₀, about 0.7 m₀, about 0.6 m₀, about 0.5 m₀, about 0.4 m₀, about 0.3 m₀, or about 0.2 m₀. In some embodiments, the band gap of p-type oxide material has a band gap of about 1-5 eV, for example, greater than or equal to about 1.2 eV, about 1.5 eV, about 2.0 eV, about 2.5 eV, about 3.0 eV, or about 4.0 eV. In some embodiments, the phase stability of the p-type oxide material would be considered unstable if its formation energy lies above the minimum free-energy convex hull in the scatter plot of formation energy versus composition, i.e., Eₕᵤₗₗ is greater than about 0 eV, about 0.01 eV, about 0.02 eV, or about 0.03 eV.

According to embodiments of the inventive concept, the p-type oxide material of the inventive concept may be selected, for example, to provide extended orbital electronic states at a valence band maximum (VBM) or valence band edge (VBE) above oxygen p-orbitals of the p-type oxide material, and to provide phase stability of the p-type oxide material. In some embodiments, extending of the orbital electronic states at the VBM/VBE leads to low hole effective masses and high p-type mobilities. In some embodiments, the extended orbital electronic states at the VBM/VBE above the oxygen p-orbital of the p-type oxide material may be provided by s-orbitals of a metal or metal ion included in the p-type oxide material. In some embodiments, the metal or metal ion included in the p-type oxide material has an electron configuration of (n−1)d¹⁰ns², for example, reduced metals/metal ions such as, but not limited to Sn²⁺, Pb²⁺, Bi³⁻, and Tl¹⁺. In some embodiments, the extended orbital electronic states at the VBM/VBE above the oxygen p-orbital of the p-type oxide material are provided by fully or partially occupied s-orbitals from, for example, a reduced metal cation, such as Sn²⁺, Pb²⁺, Bi³⁺, and Tl¹⁺. In some embodiments, the p-type oxide material is selected to provide extended orbital electronic states at the VBM/VBE above the oxygen p-orbitals of the p-type oxide material and to further provide sufficient hole mobility. In some embodiments, the p-type oxide material may include a binary compound, a ternary compound, and/or a quaternary compound. In some embodiments, the p-type oxide material of the inventive concept may include a non-metal or non-metal ion, for example, B³⁺, Ge⁴⁺, S⁶⁺, and/or P⁵⁺.

In some embodiments, the p-type oxide material may be selected by assessing thermodynamic phases of the p-type oxide material to ensure phase stability. In some embodiments, the thermodynamic phases are assessed from chemical potentials of the constituent elements of the p-type oxide material, whereby phase stability is evaluated based on the stable region in a chemical potential map. In some embodiments, the chemical potential map of the constituent elements of the p-type oxide material is generated using DFT-based first principles calculation.

In some embodiments, the extended orbital electronic states at the VBM/VBE above the oxygen p-orbital of the p-type oxide material are provided by s-orbitals of a non-metal included in the p-type oxide material, for example, B¹⁺, Ge²⁺, Te⁴⁺, Sb³⁺, As³⁺, and/or P³⁺.

According to embodiments of the inventive concept, electronic devices, such as semiconductor devices, and methods of fabricating electronic devices, are provided. Although not particularly limited, the electronic devices may include, for example, back-end-of-line (BEOL) vertical CMOS devices including, but not limited to, thin-film transistors (TFTs), and methods for fabricating such devices. Steps involved in methods for fabricating such devices are not particularly limited, and include any that may be envisioned by one of skill in the art. In some embodiments, the methods of forming an electronic device may include, for example: forming a gate electrode on a substrate; forming a dielectric layer on the gate electrode, the dielectric layer comprising a p-type oxide material selected to provide extended orbital electronic states at a valence band maximum (VBM) above an oxygen p-orbital of the p-type oxide material and to provide phase stability of the p-type oxide material; forming a semiconductor substrate on the dielectric layer opposite the gate electrode to provide a channel region in the semiconductor substrate opposite the gate electrode; and forming a source region on the semiconductor substrate and forming a drain region on the semiconductor substrate at opposing ends of the channel region. The p-type oxide material used in the methods of fabricating electronic devices and/or semiconductor devices of the inventive concept may include any of the materials described or selected according to the embodiments described hereinabove.

Having described various aspects of the present invention, the same will be explained in further detail in the following examples, which are included herein for illustration purposes only, and which are not intended to be limiting to the invention.

### EXAMPLES

### Example 1: First Principles Calculations of Intrinsic Mobilities in Tin-Based Oxide Semiconductors

The low hole mobilities in p-type oxides originate from the flat valence bands and the corresponding large effective mass of holes arising from the localized oxygen 2p orbitals at the valence band edge.^{15,16} Introducing extended orbital electronic states at the valence band maximum (VBM) above the oxygen 2p-orbital would enable a development of high mobility p-type oxides.¹ Such extended hybrid electronic states can be derived from a metal atom's s-orbitals, and would result in a very small hole effective mass. This effect can provide high hole mobilities since the underlying mechanism for high mobility of n-type oxides arises from the same s orbitals as empty states. Tin based oxides such as SnO and K₂Sn₂O₃ have recently been shown to satisfy this condition, with the 5s orbital of Sn²⁺ forming the VBM.¹⁶ The electronic band structures of SnO and K₂Sn₂O₃ have been calculated confirming the large band dispersion at the VBM, which corresponds to small hole effective mass values.^{1,16} However, the band gap of SnO (˜0.6 eV) is too small for practical p-type oxide devices, and the marginal phase stability of K₂Sn₂O_{3,6} can be a serious issue leading to K contamination of the surrounding device structures by phase changes of K₂Sn₂O₃→KSn₂O₃+K→Sn₂O₃+2K. Furthermore, a design rule based simply on the carrier effective masses does not provide quantitative mobility values, which incorporate carrier scattering rates. Although the small effective mass is a key characteristic useful for rapid screening of high hole mobility oxides, a detailed mobility calculation is critical to obtain more accurate values of the intrinsic mobilities and to confirm whether a candidate p-type oxide exhibits high hole mobility.

Recent electrical characterizations of p-type SnO have shown room-temperature carrier mobility in the range of 0.1-20 cm²/(V·s),^{6,17,18} values which are uncharacteristically low for a high-mobility p-type oxide. It is not well understood if the poor hole mobility can be improved for higher quality SnO samples. A crystalline phase-based mobility simulation does not necessarily represent the behavior of a practical device due to the polycrystal or amorphous nature of p-type oxides where more significant scattering mechanisms such as grain boundary scattering and surface scattering^{19,20} are present. Despite this, the phonon-limited intrinsic mobilities provide an upper limit to the real values and help guide the material selections process. In order to design a p-type oxide with high mobility and stability, we started by varying the composition of K₂Sn₂O₃ to search for complex Sn—O—X ternary oxides with higher phase stability. Through this search process, we identified a promising candidate: Ta₂SnO₆, which stoichiometrically is equivalent to Ta₂O₅+SnO. Compared to K₂Sn₂O₃=K₂O+2SnO, Ta₂O₅ is thermodynamically more stable than K₂O, and also compatible with the conventional device processing. Furthermore, Ta₂SnO₆ exhibits a larger band gap (>2 eV) than SnO as well as strong valence band dispersion, which are all promising characteristics.

In this example, we report the calculations of both electron and hole mobilities in tin-based oxides including p-type SnO and Ta₂SnO₆ and n-type SnO₂. We study the phonon limited intrinsic mobility values in these oxides, given that phonon scattering is the intrinsic scattering mechanism and often dominates at room temperature.²¹ We formulate the scattering rate in the presence of multiple phonon modes, which we then use to determine carrier mobility. Our calculations show that SnO₂ is a good n-type semiconductor with high electron mobility, whereas p-type SnO and Ta₂SnO₆ exhibit slightly lower hole mobilities. The theoretically predicted intrinsic mobilities for SnO, Ta₂SnO₆ and SnO₂ provide the upper limit to the real mobilities for their device applications.

### Computational Methodology

The density functional theory (DFT) calculations were performed by using Vienna ab initio Simulation Package (VASP)^{22,23} using projected augmented wave (PAW)^{24,25} pseudopotentials. Perdew-Burke-Ernzerhof generalized gradient approximation (GGA-PBE) functional was employed to depict the exchange-correlation potential energy. For all calculations, an energy cutoff of 520 eV was adopted for plane wave basis expansion. Brillouin-zone integrations were performed based on the Gamma-centred Monkhorst-Pack k-point mesh, with sampling density varying with lattice constants to ensure the desired accuracy. Structures were relaxed using conjugate gradient (CG) method with the convergence criterion of the force on each atom less than 0.02 eV/Å. The converged energy criterion is 10⁻⁵ eV for electronic minimization. The phonon frequencies at Gamma point were calculated by using density functional perturbation theory (DFPT) as implemented in VASP. For electron-phonon coupling matrix elements evaluation, the phonopy code²⁶ was used to extract the force constant matrix from Hellmann-Feynman forces and to subsequently calculate the eigen frequencies and eigen displacements. Since the carrier mobilities are sensitive to the electronic structures, especially effective masses, we used Heyd-Scuseria-Ernzerhof (HSE)²⁷ hybrid functional to obtain an accurate evaluation of effective masses and band gaps. The screening parameter in HSE was fixed at 0.2 Å⁻¹ (HSE06) while the fraction of Hartree-Fock exchange (α) was varied in order to reproduce the known lattice constants and band gaps. This fraction was finally tuned at α=0.32 for SnO₂ and α=0.25 for SnO, which yields consistent lattice constants and band gaps when compared with experiments (Table 1). The band gap of SnO predicted in this work stands somewhat lower than that in the reference work (0.84 eV)²⁸ because the band gap of SnO is sensitive to the interlayer distance between SnO layers and the optimized c-axis lattice constant (4.95 Å, agreeing well with the experimental value 4.84 Å) is slightly smaller compared to the reference (5.03 Å).²⁸

TABLE 1
The HSE mixing parameter α, calculated lattice
constants, and band baps in SnO, SnO₂, and Ta₂SnO₆.
Experimental data are shown in parentheses.

| | crystal | α | a (Å) | b (Å) | c (Å) | E_{g} (eV) |
|---|---|---|---|---|---|---|
| SnO | tetragonal | 0.25 | 3.79 | 3.79 | 4.95 | 0.6 |
| | | | (3.80)²⁹ | (3.80) | (4.84) | |
| SnO₂ | tetragonal | 0.32 | 4.74 | 4.74 | 3.18 | 3.6 |
| | | | (4.74)³⁰ | (4.74) | (3.19) | (3.6-3.7)³¹ |
| Ta₂SnO₆ | monoclinic | 0.25 | 8.97 | 8.97 | 5.53 | 3.0 |

### Results and Discussion

### A. Mobility Theory

In the Boltzmann transport theory, the drift mobility is connected to conductivity through μ=σ/(ne), where σ is conductivity, n is carrier density, and e is electron charge. Within the relaxation time approximation (RTA), the mobility is given by the well-known Drude expression:

$$μ = \frac{e 〈 〈 {τ}_{k} 〉 〉}{{m}^{*}} \qquad ( 1 )$$

where τₖ is energy-dependent relaxation time and [symbol] ⋅ [symbol] indicates the energy-weighted average relaxation time and is defined as

$$〈 〈 {τ}_{k} 〉 〉 = \frac{\int {dE}_{k} D ( {E}_{k} ) f ( {E}_{k} ) τ ( {E}_{k} ) {E}_{k}}{\int {dE}_{k} D ( {E}_{k} ) f ( {E}_{k} ) {E}_{k}} \qquad ( 2 )$$

where E is the carrier energy, D(E) is the density of states, f(E)=1/{exp[(E−E_{F})/kT]+1} is the equilibrium distribution given by Fermi-Dirac function, and E_{F} is fermi-level. When the system is nondegenerate, the Fermi-Dirac distribution is usually approximated by the Boltzmann distribution. We will see that only electrons at the conduction band minimum (CBM) and holes at the VBM are relevant to the averaged relaxation time. In relatively pure crystalline samples with negligible impurities, the dominant scattering mechanism is electron-phonon scattering. In this case, the relaxation time, or scattering rate, is determined through the Fermi's golden rule³²

$$\frac{1}{{τ}_{k}} = \frac{2 π}{ℏ} {\sum }_{λ} {\int }_{BZ} dq {\vert {g}_{q}^{λ} \vert}^{2} δ ( {E}_{q + k} - {E}_{q} ∓ ℏω ) \{ \begin{matrix}{N}_{q} \\ {N}_{q} + 1\end{matrix} \} . \qquad ( 3 )$$

Here, [symbol] is reduced Planck's constant, A labels the phonon mode, g_{q}^{λ} is matrix element for electron-phonon coupling, N_{q} is phonon occupation number which is given by the Bose-Einstein distribution function, upper and lower symbols represent the absorption and emission, respectively. The Fermi-Dirac distribution for electrons does not appear in Eq. (3) since the carrier scattering rates will not depend on the electron distribution function when the low-filed transport and isotropic scattering are considered.³³ Note that in this evaluation model, only the intra-band scattering has been taken into account, since in the non-degenerate case and low-field transport condition, the phonon-induced potentials are not sufficiently strong to trigger the inter-band process. Finally, if more than one scattering mechanism exist, the total mobility, μₜₒₜ, is given by the Matthiessen's rule:

$$\frac{1}{{μ}_{tot}} = \frac{1}{{μ}_{I}} + \frac{1}{{μ}_{II}} + ⋯ \qquad ( 4 )$$

where μ_{I} and μ_{I1} represent the mobilities by the individual scattering mechanism.

### B. Acoustic Deformation Potential Scattering

The acoustic deformation potential (ADP) scattering comes from the local changes of the crystal potential associated with a lattice vibration due to an acoustic phonon. This scattering is dominant in non-polar semiconductors such as Si and graphene. In the presence of elastic scattering approximation, the relaxation time associated with the ADP scattering is given by³³

$$\frac{1}{{τ}_{k}} = \frac{π {D}_{A}^{2} {k}_{B} T}{ℏ {\overline{C}}_{l}} D ( {E}_{k} ) \qquad ( 5 )$$

where T is absolute temperature, C̅ₗ=(C₁₁+C₂₂+C₃₃)/3 is the average longitudinal elastic constant, D_{A} is acoustic deformation potential constant.³⁴ In the present work, the elastic constant is evaluated through the use of stress-strain relationships³⁵:

$${C}_{ii} = \frac{1}{V} \frac{{\partial }^{2} E}{\partial {ɛ}_{i}^{2}} {\vert}_{0} ,$$

where V is the cell volume at equilibrium, E is the total energy, E, is the strain along i-th axis. By quadratic fitting the total energy with respect to strain, one can obtain the elastic constant. The deformation potential constant is defined as³⁴

$$δ E = {D}_{A} \frac{δ a}{a} ,$$

where δE is the CBM or VBM change due to the uniaxial lattice deformation δa/a, where a is the lattice constant. Based on this definition, the deformation potential constant D_{A} can be calculated through³³

$${D}_{A} = \frac{\partial E}{\partial {ɛ}_{V}} {\vert}_{0} ,$$

where ε_{V} is the volumetric strain. By linear fitting the total energy with respect to volume strain, one can obtain the deformation potential constant. In the case of parabolic band approximation, the 3D density of states (DOS) can be written as

$$D ( E ) = \frac{1}{2 {π}^{2}} {( \frac{2 {m}_{dos}^{*}}{{ℏ}^{2}} )}^{\frac{3}{2}} {E}^{\frac{1}{2}} \qquad ( 6 )$$

where m_{dos}*=(mₓ*m_{y}*m_{z}*)^{1/3} is the density of states effective mass. Combining Eq. (2), (5) and (6), one obtains the ADP-limited mobility³⁶

$${μ}_{α} = \frac{2 \sqrt{2 π} e {\overline{C}}_{l} {ℏ}^{4}}{3 {( {k}_{B} T )}^{3 \text{/} 2} {D}_{A}^{2} {m}_{dos}^{*} {}_{ }^{3 \text{/} 2}{m}{}_{cond , α}^{*}} \qquad ( 7 )$$

where m_{cond}* is the conductivity effective mass and is equal to band effective mass, a is Cartesian direction.

TABLE 2
The elastic constants Cₗ, acoustic deformation potential constants D_{A}, carrier effective
masses m*, and ADP-limited mobilities μ_{ADP} in SnO, SnO₂, and Ta₂SnO₆. Values
form other calculation works are shown in parentheses.

| | | Cₗ (GPa) | | | | D_{A} | m* (m₀) | | | | μ_{ADP} (cm²/Vs) | | |
|---|---|---|---|---|---|---|---|---|---|---|---|---|---|
| System | | x | y | z | ave. | (eV) | x | y | z | dos | x | y | z |
| SnO | e | 96 | 96 | 36 | 76 | 3.51 | 0.25 | 0.25 | 0.43 | 0.30 | 9308 | 9308 | 5411 |
| | h | | | | | 4.33 | 2.98 | 2.98 | 0.64 | 1.78 | 35 | 35 | 164 |
| | | | | | | | (2.80)³⁷ | (2.80) | (0.59) | | | | |
| SnO₂ | e | 210 | 210 | 377 | 266 | 8.17 | 0.26 | 0.26 | 0.21 | 0.24 | 7954 | 7954 | 9848 |
| | | (261)³⁸ | (261) | (472) | | | (0.26)³⁹ | (0.26) | (0.20) | | | | |
| | h | | | | | 2.06 | 1.27 | 1.27 | 1.60 | 1.37 | 1899 | 1899 | 1508 |
| Ta₂SnO₆ | e | 187 | 192 | 199 | 193 | 1.35 | 2.20 | 31.6 | 0.83 | 3.86 | 392 | 27 | 1040 |
| | h | | | | | 2.80 | 8.4 | 0.72 | 0.98 | 1.81 | 74 | 868 | 638 |

The computed elastic constant, deformation potential constants, and ADP mobility for SnO, SnO₂, and Ta₂SnO₆ are listed in Table 2. Our calculated elastic constants for SnO₂ and hole effective masses for SnO are close to other calculation works.³⁷⁻³⁹ For both p-type SnO and n-type SnO₂, the electron effective masses are lower than the hole effective masses. The asymmetry of effective masses between electron and hole in SnO and SnO₂ accounts for the large difference of mobilities between the two types of carriers, as can be seen in Table 2. At low temperature (T<100K) where optical phonon scattering is suppressed, ADP scattering becomes a dominant factor in determining the intrinsic mobility. However, since there are no reports on low-temperature mobilities for SnO or SnO₂, we cannot validate our calculation results by comparing with experimental data. When compared with other non-polar semiconductors such as Si where the intrinsic mobility is limited by ADP, SnO₂ shows both good electron mobility and hole mobility, while SnO exhibits a much lower hole mobility, though it has even higher electron mobility. Ta₂SnO₆ shows both satisfying electron mobility and hole mobility, but with strong anisotropy along different directions due to the highly anisotropic effective mass values. Nevertheless, compared with ADP, POP scattering is more important in determining the room temperature mobility for polar crystals and will be discussed in the next part.

### C. Polar Optical Phonon Scattering

Polar crystals contain two or more atoms in a unit cell with non-zero Born effective charge tensors. Lattice vibrations associated with polar optical phonons (POP) at long wavelength give rise to macroscopic electric fields that can strongly scatter electrons or holes, which is described by the so-called Fröhlich interaction. In the Fröhlich model, the electron-transverse optical (TO) phonon coupling is neglected and the electron-longitudinal optical (LO) phonon coupling matrix element is given by⁴⁰

$${g}_{q} = \frac{1}{\vert q \vert} \sqrt{\frac{{e}^{2} {ℏω}_{LO}}{2 {ɛ}_{0} Ω} ( \frac{1}{{∞}_{}} - \frac{1}{{0}_{}} )} \qquad ( 8 )$$

where q is phonon wavevector, ε₀ is vacuum permittivity, Ω is volume of the unit cell, κ₀ and κ_{∞} are the static and high-frequency dielectric constants, respectively. When a dispersionless phonon is assumed, that is the phonon frequency ω_{LO} is independent to q, the scattering rate takes the form³³

$$\frac{1}{{τ}_{k}} = \frac{{e}^{2} {ω}_{LO} ( \frac{1}{{κ}_{∞}} - \frac{1}{{κ}_{0}} )}{4 {πɛ}_{0} ℏ \sqrt{2 {E}_{k} \text{/} {m}^{*}}} [ {N}_{ω} \sqrt{1 + \frac{{ℏω}_{LO}}{{E}_{k}}} + ( {N}_{ω} + 1 ) \sqrt{1 - \frac{{ℏω}_{LO}}{{E}_{k}}} - \frac{{ℏω}_{LO} {N}_{ω}}{{E}_{k}} {{sinh}^{- 1} ( \frac{{ℏω}_{LO}}{{E}_{k}} )}^{1 \text{/} 2} + \frac{{ℏω}_{LO} ( {N}_{ω} + 1 )}{{E}_{k}} {{sinh}^{- 1} ( \frac{{ℏω}_{LO}}{{E}_{k}} - 1 )}^{1 \text{/} 2} ] \qquad ( 9 )$$

where N_{ω} is the occupation number of phonons with frequency ω. For details about the derivation of this equation, we refer readers to Ref [33]. The Fröhlich model assumes an isotropic dielectric medium and only one polar LO mode that couples to the carriers. However, such conditions are clearly not satisfied in the case of SnO, SnO₂, and Ta₂SnO₆ where more than one LO modes exist. To incorporate crystal anisotropy and multiple LO modes scattering, we use the Vogl model⁴¹ which provides a more accurate description of electron-phonon coupling. Vogl model has been widely used for describing the electron-optical phonon coupling in polar crystals.^{32,41-43} Similar to the Fröhlich model, the key ingredient in the Vogl model is that it relates the perturbing potential induced by the optical phonons to the dielectric constants and the Born effective charges, both of which can be computed using DFT. In the Vogl model the coupling matrix element is given by^{32,42}

$${g}_{q}^{λ} = i \frac{4 π}{Ω} \frac{{e}^{2}}{4 {πɛ}_{0}} {\sum }_{j} \sqrt{\frac{ℏ}{2 {M}_{j} {ω}_{q}^{λ}}} \frac{q \cdot \overleftrightarrow{{Z}_{j}^{*}} \cdot {e}_{jq}^{λ}}{q \cdot \overleftrightarrow{{κ}_{∞}} \cdot q} \qquad ( 10 )$$

where Mⱼ is the atomic mass of j-th atom, [symbol] is born effective charge tensor, [symbol] is high-frequency dielectric constant tensor, e_{jq}^{λ} is eigen displacement of atom j in phonon mode λ, and is normalized according to Σⱼe_{jq}^{λ}·e_{jq}^{λ}=δ_{λ′λ}. Note that the expression for the coupling matrix element shown here differs from that by Verdi and Giustino⁴³ and in the latter there is an extra integration term that can be simplified and reduced to ours when only the polar couplings are taken into account. The simplified expression is adopted since it can enable the scattering rates to be expressed analytically. The Vogl model here includes the directional dependence of electron-phonon coupling in the sense that the coupling strength is proportional to the projection of the net dipole strength [symbol] ·e_{jq}^{λ} along the direction of q. The Vogl model also implies that the transverse optical (TO) phonon modes do not couple to the carriers since the q· [symbol] ·e_{jq}^{λ} term becomes zero in those cases. In general, the anisotropy of coupling strength is determined by the combined symmetry of both phonon and electronic states. Incorporating such anisotropy for the calculation of scattering rate requires a numerical integration indicated by Eq. (3), and often a Wannier-Fourier (WF)⁴⁴ interpolation is needed to obtain a very fine resolution of the matrix elements for achieving convergence. Such scheme, however, is beyond the scope of this study. In this work, we will instead consider an “isotropic approximation” by approximating the anisotropic electron-phonon coupling matrix elements with appropriate q-space angle-averaged quantities. This is implemented by the expression

$${〈 {\vert {g}_{\vert q \vert}^{λ} \vert}^{2} 〉}_{θ , φ} = \frac{1}{4 π} {\int }_{- 1}^{1} d ( cos θ ) {\int }_{0}^{2 π} d φ {\vert {g}_{q}^{λ} \vert}^{2} \qquad ( 11 )$$

where the brackets [symbol] ⋅ [symbol] denote averaging over the azimuthal angle θ and polar angle φ, performed numerically.

In addition, the Born effective charge is related with the static and high-frequency dielectric constants through⁴⁵

$$\frac{1}{{0}_{}} = \frac{1}{{∞}_{}} - {lim}_{q \to 0} \frac{1}{{∞}_{2}^{}} \frac{4 π}{Ω} \frac{{e}^{2}}{4 {πɛ}_{0}} {\sum }_{λ} {( {\sum }_{j} \frac{\overleftrightarrow{{Z}_{j}^{*}} \cdot {e}_{jq}^{λ}}{\sqrt{{M}_{j}} {ω}_{q}^{λ}} )}^{2} \qquad ( 12 )$$

where we have used the notations: [symbol] =1/ [symbol] ₀, and ( [symbol] )⁻¹=1/ [symbol] _{∞}. As mentioned previously, due to the anisotropy of lattice vibration in SnO, SnO₂, and Ta₂SnO₆, the static dielectric constants are direction dependent. To simplify this, here we adopted an isotropic approximation and a spatially averaged dielectric constant would be used, i.e., κ₀=(κ_{0,xx}+κ_{0,yy}+κ_{0,zz})/3, where κ_{0,xx}, κ_{0,yy}, and κ_{0,zz} are static dielectric constant along three Cartesian axes, respectively. The high-frequency dielectric constants, on the other hand, are usually nearly isotropic since the dielectric constants at high frequency are mainly contributed by electrons, as lattice ions cannot respond at high frequency.⁴⁶ Inserting Eq. (12) back into Eq. (10), we arrive at

$${g}_{q}^{λ} = \frac{i}{\vert q \vert} \sqrt{\frac{{e}^{2} {ℏω}_{q}^{λ}}{2 {ɛ}_{0} Ω} ( \frac{1}{{∞}_{}} - \frac{1}{{0}_{}} ) \cdot {w}_{q}^{λ}} \qquad ( 13 )$$

where w_{q}^{λ} is given by

$${w}_{q}^{λ} = \frac{{( {\sum }_{j} \frac{q \cdot \overleftrightarrow{{Z}_{j}^{*}} \cdot {e}_{jq}^{λ}}{\vert q \vert \sqrt{{M}_{j}} {ω}_{q}^{λ}} )}^{2}}{{\sum }_{{λ}^{′}} {( {\sum }_{j} \frac{\overleftrightarrow{{Z}_{j}^{*}} \cdot {e}_{jq}^{{λ}^{′}}}{\sqrt{{M}_{j}} {ω}_{q}^{{λ}^{′}}} )}^{2}} \qquad ( 14 )$$

We note that in low-symmetry crystals, the longitudinal mode or transverse mode is not exactly parallel or perpendicular to the direction of q. If we consider the strict LO (TO) modes in which the dipole strength [symbol] ·e_{jq}^{λ} is parallel (perpendicular) to the wavevector q, Eq. (14) will further reduce to

$${w}_{q}^{λ} = \frac{{( {Σ}_{j} \frac{{Z}_{j}^{*} \cdot {e}_{jq}^{λ}}{\sqrt{{M}_{j}} {ω}_{q}^{λ}} )}^{2}}{{{Σ}_{{λ}^{′}} ( {Σ}_{j} \frac{{Z}_{j}^{*} \cdot {e}_{jq}^{{λ}^{′}}}{\sqrt{{M}_{j}} {ω}_{q}^{{λ}^{′}}} )}^{2}} . \qquad ( 15 )$$

Compared with Eq. (8), Eq. (13) shows that in the case of multiple POP modes coupling, each mode contributes to the total coupling strength by the weight w_{q}^{λ}. We note that if there is only one LO mode, Eq. (13) reduces correctly to the Fröhlich model in Eq. (8). Assuming the phonons are dispersionless, one obtains the relaxation time for multiple phonon modes scattering

$$\frac{1}{{τ}_{k}} = {Σ}_{λ} \frac{{w}^{λ}}{{τ}_{k}^{λ}} \qquad ( 16 )$$

with w^{λ} and τ_{q}^{λ} given by Eq. (14) and Eq. (9), respectively.

The scattering rates can be expressed analytically when the simplifications including parabolic energy bands, dispersionless optical phonons, and isotropic phonon scattering are introduced. Without these simplifications, scattering rates can only be evaluated by carrying out a series of numerical integrals of millions of electron-phonon coupling elements, which would be computationally very expensive. Parabolic band approximation is a very common practice in semiconductor physics, and it is also the essence of the effective mass approximation theory. For non-degenerate semiconductors under low-field transport, carriers are occupying the conduction/valence band edges which rationalizes the parabolic band approximation. The dispersionless approximation is also called Einstein model, where phonon frequency is regarded independent on the phonon wave vector q. The simplified dispersion relation for optical modes is often used for scattering calculations. However, the “dispersionless approximation” in our model does not requires that phonon mode be dispersionless or almost dispersionless. This is because the phonons involved in the scattering process are those with wave vector q near the center of the Brilliouin zone due to momentum and energy conservation.³³ Since the energies associated with the phonons are significantly lower than those with the electrons, the final states that electrons are scattered into cannot differ too much from the initial states in terms of energies. This determines that within intraband scatterings electron momentum differences cannot be large, which implies that the scattering phonons are near the center of the Brilliouin zone. In this regard, we can assume their frequencies are invariant when the wave vectors of phonons of interest only occupy a small range near the center of the Brilliouin zone in the q-space. As for the isotropic approximation, we need to consider the directionality of both electron momentum state k and phonon wavevector q, as the scattering rates depends on both quantities. The anisotropy of scattering rates due to the directionality of k turns out to be characterized by the anisotropy of the effective mass, and such anisotropy has already been taken into account in our evaluation model, as shown in Eq (9). The anisotropy of electron-phonon coupling matrix elements arising from its q dependence is alleviated by using an average value to approximate those matrix elements of the spherical surface in the q-space. The matrix elements are dumped into an averaged value and will lead to an analytical integration which avoids intensive computations needed for numerical integrations.

Nevertheless, such a simplified model and the assumptions inherent in it are subject to be substantiated. To further verify these approximations and evaluate how accurate the model is, we have tested our model in a wide range of compound semiconductors, including III-V semiconductors, II-VI semiconductors, and metal oxides. Table 3 lists the computed and experimental mobilities of these compound semiconductors, with related parameters needed for the calculation of mobilities also included. Note that all the materials parameters, including effective masses, dielectric constants, and LO phonon frequencies are experimental values, unless they are not available from literatures and in that case the DFT predicted values are used instead. All of the experimental values are measured based on the single-crystal samples. Broadly speaking, the model gives quantitively reasonable predictions for the mobilities in these tested compounds, though with a systematic overestimation when compared to the experiments (in general 1.5-2 times of the experimental values). The overestimations may come from the approximations assumed in the model and the ionized impurity scattering in the real samples and it is hard to determine which factor is more dominant since the carrier concentrations in the experimental samples vary with a wide range. Nonetheless, our simulated mobilities are in fair agreement with experimental values from the engineers' point of view. With a simplified analytical expression and less intensive computations, our model would be rather helpful in the rapid prediction of the upper limit of the intrinsic mobilities of materials.

TABLE 3
POP-limited motility model test in GaAs, ZnO, PbS, In₂O₃, and TiO₂. The effective mass
m*, static dielectric constant κ₀, high-frequency dielectric constant κ_{∞}, LO phonon frequency ω_{LO}
are experiment values, unless they are not available from literatures and in that case the DFT
predicted values are used instead. In compounds with the hexagonal or tetragonal crystal structure,
the effective mass and dielectric constant exhibit two distinct values along the c-axis (∥) and in-
plane (⊥) directions. The characteristics of the LO mode in the crystals, whether isotropic or
anisotropic and whether single LO mode or multiple LO modes, are also indicated. For a fair
comparison, the experimental measured mobilities are from single-crystal samples.

| | | | | Dielectric | | | | μ (cm²/Vs) | | μ (cm²/Vs) | |
|---|---|---|---|---|---|---|---|---|---|---|---|
| | Crystal | m*(m₀) | | constant | | ω_{LO} | LO | calc. | | exp. | |
| System | structure | e | h | κ₀ | κ_{∞} | (cm⁻¹) | mode | e | h | e | h |
| GaAs⁴⁷ | Zinc | 0.067 | 0.51 | 12.9 | 10.89 | 291 | Isotropic | 12234 | 949 | 8500 | 400 |
| | Blende | | | | | | Single | | | | |
| | (cubic) | | | | | | | | | | |
| ZnO⁴⁸ | Wurtzite | 0.29 | 0.78 | 7.77(⊥) | 3.68(⊥) | 583(⊥) | Anisotropic | 365 | 82.7 | 205 | 50 |
| | (hexagonal) | | | 8.91(∥) | 3.72(∥) | 574 (∥) | Multiple | | | | |
| PbS4⁹ | Halite | 0.18* | 0.16* | 169 | 15.2 | 202 | Isotropic | 760 | 861 | 600⁵⁰ | 600⁵⁰ |
| | (cubic) | | | | | | single | | | | |
| In₂O₃⁵¹ | bixbyite | 0.30[6] | 2.87* | 8.952 | 4.152 | 245* | Isotropic | 342 | 11.6 | 160 | — |
| | (cubic) | | | | | 196* | multiple | | | | |
| | | | | | | 194* | | | | | |
| TiO₂⁵³ | Anatase | 0.45*(⊥) | 2.19*(⊥) | 45.1(⊥) | 5.4(⊥) | 161* | Anisotropic | 81.5(⊥) | 7.62(⊥) | 18⁵⁴ | — |
| | (tetragonal) | 4.54*(∥) | 1.03*(∥) | 22.7(∥) | 5.8(∥) | 876(⊥) | Multiple | 2.55(∥) | 24.2(∥) | | |
| | | | | | | 366(⊥) | | | | | |
| | | | | | | 755(∥) | | | | | |

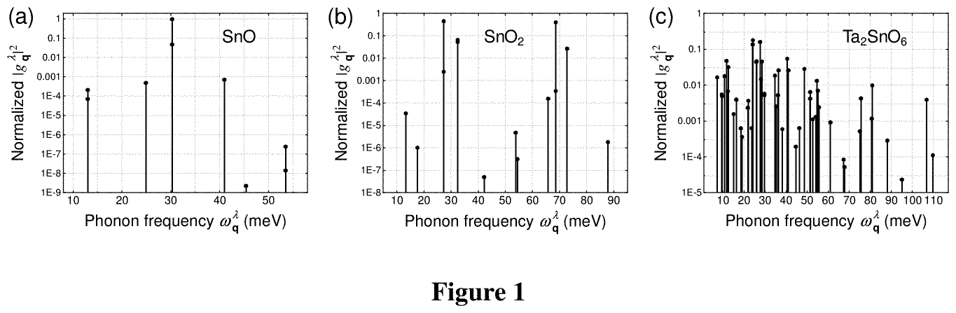

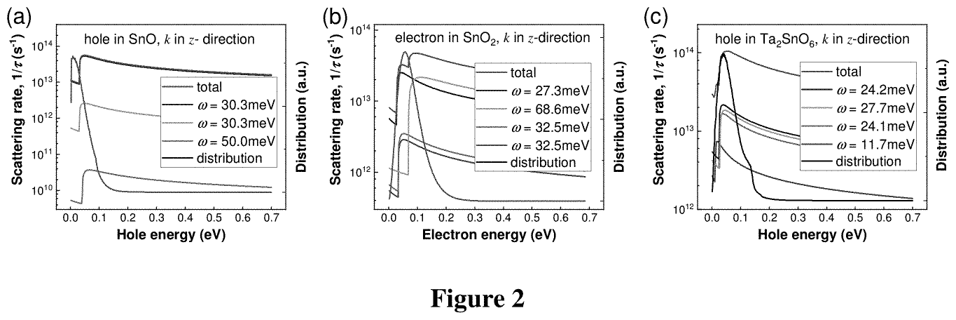

It is expected that different POP modes contribute differently to the total scattering rate. By plotting the mode-resolved coupling strength g_{q}^{λ} in Eq. (13) for different mode λ, one can visualize the detailed contributions of each mode to the total carrier scattering. FIG. 1 shows the computed angularly averaged coupling matrix elements for different phonon modes at a fixed magnitude of |q|=0.05 2π/a (a is lattice constant) for SnO, SnO₂, and Ta₂SnO₆. Because the calculated phonon eigenvectors are not exactly parallel or perpendicular to q, we calculate coupling matrix elements for all the optical phonon modes that appear in the phonon dispersion. We can see that in these three crystals, different modes make different contributions, with some modes accounting for almost total coupling strength while other modes contributing only marginally. Specifically, in SnO the phonon mode w^{λ}′=30.3 meV accounts for nearly 100% of the total coupling strength, with the remaining modes give two orders of magnitude smaller coupling. Predictably, this vibration mode will play the dominant role in determining the POP mobility of SnO. In SnO₂, however, several significantly strong couplings are observed, for example, 27.3 meV, 32.5 meV, 68.6 meV, and 72.7 meV. When compared with SnO and SnO₂, Ta₂SnO₆ shows more dispersed coupling strengths among different modes, which might result from the asymmetry of its crystal structure. Another interesting finding is that although SnO and SnO₂ exhibit mode degeneracy due to tetragonal symmetry, these degenerate modes do not give the same coupling strength. A closer look at the phonon structures of SnO and SnO₂ reveals that those frequency-degenerate modes do not assume degenerate or equivalent eigen displacements, which would account for the different coupling strength. In Ta₂SnO₆, however, because of monoclinic crystal nature, no degenerate modes are observed.

Next, we calculated the scattering rates at room temperature for different POP modes in SnO, SnO₂, and Ta₂SnO₆. As discussed previously, the matrix elements show the direction dependence and we thus adopted a spherically averaging approximation. The resulting scattering rates with k along z-direction are shown in FIG. 2. For each material, the total scattering rate as well as scattering rates by several strong coupling branches are plotted. The contribution to the total scattering rate by each mode in SnO, SnO₂, and Ta₂SnO₆ is consistent with the result shown in FIG. 1. In SnO the total scattering rate for holes moving along the z direction almost follows that of phonon mode w^{λ}=30.3 meV because this mode is responsible for nearly all the scattering events. Since the POP scattering includes both phonon absorption and emission processes, the scattering rate for each mode clearly shows the kink at the point of phonon energy, which corresponds to the onset of phonon emission. By comparing the two modes 27.3 and 68.6 meV which give the similar coupling strength in SnO₂, we found that low-energy phonon 27.3 meV is more effective in scattering. This is because low-energy phonon modes are efficiently activated at room temperature and provide two scattering channels (absorption and emission) for electrons near the Fermi level. The scattering rate gradually drops at higher electron/hole energy, due to the decreased available density of sates that carriers can be scattered into. FIG. 2 also shows the carrier distribution obtained by combining the Fermi-Dirac distribution function and electron/hole DOS. The energy range which shows a high electron/hole distribution will be more relevant to the averaged relaxation time, as indicated by Eq. (2).

The POP mobilities at room temperature for SnO, SnO₂, and Ta₂SnO₆ were then calculated, as listed in Table 4. Generally, in polar crystals, the POP is the dominant scattering mechanism limiting the room temperature intrinsic mobilities.³³ In our results, the POP mobilities are much lower than the ADP mobilities agreeing with the expectation. To compare with experimental data, we also calculated the POP limited Hall mobility. The Hall mobility differs from the drift mobility by the so-called Hall factor which can be calculated as: r_{H}= [symbol] τ² [symbol] / [symbol] τ [symbol] ², where double brackets represent energy-weighted average as indicated in Eq. (2). Since POP scattering is the limiting factor, we will use our calculated POP mobilities to compare with experiments. For SnO, we obtain the hole mobilities of 9.4 and 94.4 cm²/(V·s) for x and z directions, respectively, leading to an average hole mobility of 38 cm²/(V·s). Correspondingly, the p-type Hall mobility averages out at 67 cm²/(V·s). In comparison, experiments have so far achieved room-temperature hole drift mobilities ranging from 0.1 to 10 cm²/(V·s) and Hall mobilities from 1 to 18 cm²/(V·s), depending on the materials crystallinity and the device geometries.^{6,7,18} Our results are in fair agreement with the reported experimental value, if one considers that other extrinsic factors such as ionized impurity scattering are expected to exist in experimental samples. For electrons in SnO₂, our calculated drift mobility varies from 170 cm²/(V·s) in x direction to 235 cm²/(V·s) in z direction, with spatially averaged value at 192 cm²/(V·s). This results in an averaged Hall mobility of 265 cm²/(V·s), which agrees well with the experimental value at 300 K (240 cm²/(V·s)) as well as other theoretical calculations (310 cm²/(V·s)).⁵⁵ For Ta₂SnO₆, there has been the experimental report on the electrical characterization of Sn—O—Ta compound, but only with the Ta₂Sn₂O₇ stoichiometry.⁵⁶ The measured mobility for Ta₂Sn₂O₇ (˜0.1 cm²/(V·s)) stands much lower than our predicted mobility for TaSn₂O₆ due to the more flat valence band and the resulting larger effective hole mass in Ta₂Sn₂O₇.⁵⁷ Finally, we calculated the total mobility taking both ADP and POP into account, as presented in Table 4. For all these materials, the phonon-limited intrinsic mobilities are close to the POP mobilities, indicating that POP plays a dominant role in carrier scattering.

TABLE 4
The the static and high-frequency dielectric constants κ₀ and κ_{∞}, POP-limited mobilities μ_{POP},
mobilities limited by both ADP and POP in SnO, SnO₂, and Ta₂SnO₆, Hall factors r_{H}, averaged
Hall mobilities μ_{Hall} (ave.) limited by POP, and the experimentally determined Hall mobilities μ_{H} (exp.).

| | | | | | | | | μ_{POP} | | | μ_{POP+ADP} | | | | | |
|---|---|---|---|---|---|---|---|---|---|---|---|---|---|---|---|---|
| | | κ₀ | | | κ_{∞} | | | (cm²/Vs) | | | (cm2Ns) | | | | μ_{Hall} | μ_{Hall} |
| System | | x | y | z | x | y | z | x | y | z | x | y | z | rH | (ave.) | (exp.) |
| SnO | e | 21.7 | 21.7 | 11.8 | 7.0 | 6.4 | 6.4 | 289 | 289 | 128 | 280 | 280 | 125 | 1.30 | 306 | — |
| | h | | | | | | | 9.4 | 9.4 | 94.4 | 7.4 | 7.4 | 60.0 | 1.77 | 66.8 | 1~18^{6, 16, 29} |
| SnO₂ | e | 13.0 | 13.0 | 8.8 | 4.0 | 4.0 | 4.3 | 170 | 170 | 235 | 166 | 166 | 229 | 1.38 | 265 | 240⁵⁵ |
| | h | | | | | | | 15.8 | 15.8 | 11.1 | 15.7 | 15.7 | 11.0 | 1.37 | 19.5 | — |
| Ta₂SnO₆ | e | 38.8 | 35.7 | 60.0 | 5.7 | 5.6 | 5.8 | 6.4 | 0.2 | 27.8 | 6.3 | 0.2 | 27.1 | 1.14 | 13.0 | — |
| | h | | | | | | | 0.9 | 33.8 | 21.3 | 0.9 | 32.5 | 20.6 | 1.09 | 20.4 | — |

### D. Discussion

Although a spherical averaging approximation was adopted in treating the anisotropy of lattice vibrations, the carrier mobilities in SnO, SnO₂, and Ta₂SnO₆ are still highly anisotropic, due to the strong anisotropy of the electronic structure, i.e., effective mass. This is manifested by the almost 10 times difference of hole mobility in different directions in SnO. The tetragonal layer-structured SnO shows only two hole effective masses: 0.64 m₀ along the z direction (interlayer) and 2.98 m₀ in the plane perpendicular to the former direction (intralayer). The smaller effective mass in the interlayer direction leads to a higher mobility along the direction, in contrast to other 2D materials such as MoS₂ where intralayer transport is often superior than interlayer transport.⁵⁸ Compared with SnO and SnO₂, Ta₂SnO₆ shows relatively low room-temperature mobilities for both electron and hole due to the large effective masses, which in turn suggests that the effective masses account for the differences in the mobilities in difference materials.

Interestingly, our results show that SnO exhibits an excellent electron mobility with an average value of 228 cm²/(V·s). This value is even higher than that in n-type SnO₂ where electron mobility averages out at 187 cm²/(V·s). This finding may motivate experimentalists to incorporate SnO as a n-type semiconductor into the already realized unipolar p-type SnO based transistors to implement high-performance complementary circuits. Currently, oxide semiconductor research community is searching for promising p-type oxides with good mobility as they remain elusive. SnO₂ has been proposed as a potential p-type oxide due to its compatibility with the commercialized n-type SnO₂ based electronics. However, the acceptor doping for p-type SnO₂ has recently proven unachievable, due to the hole trap center formation associated with the acceptor defects.⁵⁹ Since SnO has been identified as a p-type oxide candidate, if validated having good n-type doping ability, it could be potentially introduced as a bipolar semiconductor into oxide electronics that requires both n-type and p-type MO materials.

SnO is expected to exhibit good hole mobility due to its relatively low effective hole mass resulted by the hybridization of pseudo-closed 5s² orbitals of Sn²⁺ and oxygen 2p orbitals.⁶ However, our calculated result shows that the highest possible hole mobility for SnO stands at 60 cm²/(V·s), slightly lower than targeted value of 100 cm²/(V·s) to be considered as a high-mobility p-type oxide. Ta₂SnO₆ shows even lower hole mobility than SnO, indicating a necessity of further investigation to discover higher mobility p-type oxides. Alternative compounds can be identified through searching for the materials with even lower hole effective masses. This can be implemented based on the screening rule that VBM are largely occupied by the delocalized s-orbital of non-transition metal (TM) or d-orbital of TM. A few novel materials including B₆O, A₂Sn₂O₃ (A=K, Na), and ZrOS have recently been identified as low-effective-mass oxides according to such rule.¹⁴ However, their mobilities are subject to further investigation, as mobilities are also influenced by various scattering mechanisms.

### Conclusions

A first-principles approach to calculate intrinsic phonon-limited mobilities for Sn-based oxide semiconductors including p-type SnO and Ta₂SnO₆, and n-type SnO₂ was employed. Having considered multi-phonon modes scattering, room temperature electron/hole mobilities in these oxides are found to be predominantly limited by the POP scattering. Our results agree well with previous theoretical calculations and experimental data for SnO and SnO₂. Although p-type SnO exhibits an excellent electron mobility, the upper limit for its hole mobility stands only at 60 cm²/(V·s), slightly lower than the threshold value of 100 cm²/(V·s) to be considered as a high-mobility p-type oxide for vertical CMOS. SnO₂ shows good electron mobility with an average value of 192 cm²/(V·s), confirming its promise as a n-type semiconductor. p-type Ta₂SnO₆ shows lower hole mobility than SnO, indicating a necessity of further investigation to discover higher mobility p-type oxides. Calculated effective masses directly correlate to the differences in mobilities of different materials, which makes it an effective screening criterion in searching for high-mobility p-type oxides.

### REFERENCES IN EXAMPLE 1

¹ S. Salahuddin, K. Ni, and S. Datta, Nat. Electron. 1, 442 (2018).
² M. M. Shulaker, G. Hills, R. S. Park, R. T. Howe, K. Saraswat, H.-S. P. Wong, and S. Mitra, Nature 547, 74 (2017).
³ T. F. Wu, H. Li, P.-C. Huang, A. Rahimi, G. Hills, B. Hodson, W. Hwang, J. M. Rabaey, H.-S. P. Wong, and M. M. Shulaker, IEEE J SOLID-ST CIRC. 53, 3183 (2018).
⁴ M. S. Ebrahimi, G. Hills, M. M. Sabry, M. M. Shulaker, H. Wei, T. F. Wu, S. Mitra, and H.-S. P. Wong, in Monolithic 3D integration advances and challenges: From technology to system levels, 2014 (IEEE), p. 1.
⁵ M. M. Shulaker, T. F. Wu, A. Pal, L. Zhao, Y. Nishi, K. Saraswat, H.-S. P. Wong, and S. Mitra, in Monolithic 3D integration of logic and memory: Carbon nanotube FETs, resistive RAM, and silicon FETs, 2014 (IEEE), p. 27.4. 1.
⁶ Y. Ogo, H. Hiramatsu, K. Nomura, H. Yanagi, T. Kamiya, M. Hirano, and H. Hosono, Appl. Phys. Lett. 93, 032113 (2008).
⁷ E. Fortunato, R. Barros, P. Barquinha, V. Figueiredo, S.-H. K. Park, C.-S. Hwang, and R. Martins, Appl. Phys. Lett. 97, 052105 (2010).
⁸ K. Nomura, H. Ohta, A. Takagi, T. Kamiya, M. Hirano, and H. Hosono, Nature 432, 488 (2004).
⁹ E. Fortunato, P. Barquinha, and R. Martins, Adv. Mater. 24, 2945 (2012).
¹⁰ K. Ellmer, Nat. Photonics 6, 809 (2012).
¹¹ L. Petti, N. Münzenrieder, C. Vogt, H. Faber, L. Blithe, G. Cantarella, F. Bottacchi, T. D. Anthopoulos, and G. Troster, Appl. Phys. Rev 3, 021303 (2016).
¹² J. K. Jeong, J. H. Jeong, H. W. Yang, J.-S. Park, Y.-G. Mo, and H. D. Kim, Appl. Phys. Lett. 91, 113505 (2007).
¹³ C. G. Granqvist, Sol. Energy Mater. Sol. Cells 91, 1529 (2007).
¹⁴ G. Hautier, A. Miglio, G. Ceder, G.-M. Rignanese, and X. Gonze, Nat. Commun. 4, 2292 (2013).
¹⁵ S. Sheng, G. Fang, C. Li, S. Xu, and X. Zhao, Phys. Status Solidi A 203, 1891 (2006).
¹⁶ A. Banerjee and K. Chattopadhyay, Prog. Cryst. Growth Charact. Mater 50, 52 (2005).
¹⁷ W. Guo, L. Fu, Y. Zhang, K. Zhang, L. Liang, Z. Liu, H. Cao, and X. Pan, Appl. Phys. Lett. 96, 042113 (2010).
¹⁸ J. Caraveo-Frescas and H. N. Alshareef, Appl. Phys. Lett. 103, 222103 (2013).
¹⁹ M. V. Frischbier, H. F. Wardenga, M. Weidner, O. Bierwagen, J. Jia, Y. Shigesato, and A. Klein, Thin Solid Films 614, 62 (2016).
²⁰ S. Nakao, N. Yamada, T. Hitosugi, Y. Hirose, T. Shimada, and T. Hasegawa, Appl. Phys. Express 3, 031102 (2010).
²¹ K. Kaasbjerg, K. S. Thygesen, and K. W. Jacobsen, Phys. Rev. B 85, 115317 (2012).
²² G. Kresse and J. Hafner, Phys. Rev. B 47, 558 (1993).
²³ G. Kresse and J. Furthmüller, Phys. Rev. B 54, 11169 (1996).
²⁴ G. Kresse and J. Hafner, J. Phys. Condens. Matter 6, 8245 (1994).
²⁵ G. Kresse and D. Joubert, Phys. Rev. B 59, 1758 (1999).
²⁶ A. Togo and I. Tanaka, Scr. Mater 108, 1 (2015).
²⁷ J. Paier, M. Marsman, K. Hummer, G. Kresse, I. C. Gerber, and J. G. Ángyan, J. Chem. Phys 124, 154709 (2006).
²⁸ K. Govaerts, R. Saniz, B. Partoens, and D. Lamoen, Phys. Rev. B 87, 235210 (2013).
²⁹ J. Pannetier and G. Denes, Acta Cryst. B 36, 2763 (1980).
³⁰ H. Peng, J. D. Perkins, and S. Lany, Chem. Mater. 26, 4876 (2014).
³¹ K. Sundaram and G. Bhagavat, J. Phys. D Appl. Phys. 14, 921 (1981).
³² J. Sjakste, N. Vast, M. Calandra, and F. Mauri, Phys. Rev. B 92, 054307 (2015).
³³ M. Lundstrom, Fundamentals of carrier transport (Cambridge university press, 2009).
³⁴ J. Bardeen and W. Shockley, Phys. Rev. 80, 72 (1950).
³⁵ W. Perger, J. Criswell, B. Civalleri, and R. Dovesi, Comput. Phys. Commun. 180, 1753 (2009).
³⁶ J. Xi, M. Long, L. Tang, D. Wang, and Z. Shuai, Nanoscale 4, 4348 (2012).
³⁷ V.-A. Ha, F. Ricci, G.-M. Rignanese, and G. Hautier, J. Mater. Chem. C 5, 5772 (2017).
³⁸ C.-M. Liu, X.-R. Chen, and G.-F. Ji, Comput. Mater. Sci. 50, 1571 (2011).
³⁹ Y. Mi, H. Odaka, and S. Iwata, Jpn. J. Appl. Phys. 38, 3453 (1999).
⁴⁰ H. Frohlich, Adv. Phys. 3, 325 (1954).
⁴¹ P. Vogl, Phys. Rev. B 13, 694 (1976).
⁴² Y. Kang, K. Krishnaswamy, H. Peelaers, and C. G. Van de Walle, J. Phys. Condens. Matter 29, 234001 (2017).
⁴³ C. Verdi and F. Giustino, Phys. Rev. Lett. 115, 176401 (2015).
⁴⁴ J. Noffsinger, F. Giustino, B. D. Malone, C.-H. Park, S. G. Louie, and M. L. Cohen, Comput. Phys. Commun. 181, 2140 (2010).
⁴⁵ J. Kurkijarvi and D. Rainer, (1989).
⁴⁶ Y. Kang, K. Krishnaswamy, H. Peelaers, and C. G. J. J. o. P. C. M. Van de Walle, 29, 234001 (2017).
⁴⁷ http://www.ioffe.ru/SVA/NSM/Semicond/GaAs/.
⁴⁸ V. Coleman and C. Jagadish, in Zinc oxide bulk, thin films and nanostructures (Elsevier, 2006), p. 1.
⁴⁹ O. Madelung, U. Rossler, and M. Schulz, Non-Tetrahedrally Bonded Elements and Binary Compounds, Vol. 41 (Springer, 1998).
⁵⁰ http://www.matweb.com/search/datasheetprint.aspx?matguid=d2f30ef191544dab92b5167elaf d1195.
⁵¹ R. Weiher, J. Appl. Phys. 33, 2834 (1962).
⁵² A. Schleife, M. D. Neumann, N. Esser, Z. Galazka, A. Gottwald, J. Nixdorf, R. Goldhahn, and M. Feneberg, New J. Phys. 20, 053016 (2018).
⁵³ R. Gonzalez, R. Zallen, and H. Berger, Phys. Rev. B 55, 7014 (1997).
⁵⁴ T. S. Krasienapibal, T. Fukumura, Y. Hirose, and T. Hasegawa, Jpn. J. Appl. Phys. 53, 090305 (2014).
⁵⁵ C. Fonstad and R. Rediker, J. Appl. Phys. 42, 2911 (1971).
⁵⁶ N. Kikuchi, A. Samizo, S. Ikeda, Y. Aiura, K. Mibu, and K. Nishio, Phys. Rev. Mater. 1, 021601 (2017).
⁵⁷ Y. Hosogi, Y. Shimodaira, H. Kato, H. Kobayashi, and A. Kudo, Chem. Mater. 20, 1299 (2008).
⁵⁸ V. K. Sangwan and M. C. Hersam, Annu. Rev. Phys. Chem. 69, 299 (2018).
⁵⁹ D. O. Scanlon and G. W. Watson, J. Mater. Chem 22, 25236 (2012).

### Example 2: First Principles Design of High Hole Mobility P-Type Tin Ternary Oxides

Semiconducting metal oxides (MOs) have been studied as the transparent conducting electrodes for flexible electronics, optoelectronics and display applications for decades¹⁻⁴. Recently, MOs are proposed as the candidates for back-end-of-line (BEOL) compatible vertical CMOS channel materials due to their ease of synthesis at low temperature and wide band gaps.⁵⁻⁷ For vertical FETs, high-mobility MOs with bandgaps exceeding 1.5 eV are required for transistors in the upper layers of BEOL for applications as logic and memory access transistors.^{5,8} The band gaps of MOs suitable for vertical CMOS do not require optical transparency, but should be wide enough to ensure low off-state leakage current. Most common oxides (e.g., TiO₂, SnO₂, In₂O₃ . . . ) have significantly lower hole mobilities than the electron mobilities due to the large hole effective masses originating from the localized oxygen 2p-orbitals at the valence band maximum (VBM).⁹ Developing high mobility p-type oxides would enable a complementary transistor solution that provides more flexibility to design and implementation of more efficient BEOL vertical CMOS devices. Sn²⁺ based oxides have been proposed as promising materials for high mobility p-type oxide design.⁹⁻¹³ In Sn²⁺-containing oxide compounds, the extended Sn-5s orbital energetically lying above the O-2p orbital will hybridize with oxygen p-orbital and forms the VBM states, resulting in a dispersive VBM and the corresponding small hole effective mass. SnO and K₂Sn₂O₃ have been previously identified as promising candidates with 5s orbital of Sn²⁺ forming the VBM and hybridizing with O-2p orbital.¹⁴ However, the band gap of SnO (˜0.7 eV)⁶ is too small for practical p-type oxide devices, and the marginal phase stability of K₂Sn₂O₃⁹ can be a serious issue leading to K contamination of the surrounding device structures requiring diffusion barriers. The discovery of Sn²⁺—O—X compounds with X element other than K is an open possibility to develop high-performance p-type oxides with an appropriate bandgap and good phase stability.

For the purpose of designing p-type high mobility oxides, phase stability is a crucial criterion along with high hole mobility. Sn²⁺ based oxides tend to have an unfavorable phase stability because the additional valance states by Sn metal's s-orbitals above oxygen 2p-orbital would generally make the oxides less stable. The material design and identification have to ensure their thermodynamic phase stabilities for practical materials growth while achieving the low effective hole masses. In SnO, the lone pair from Sn 5s orbital that hybridizes with the O-2p orbital can be readily oxidized and transformed into Sn⁴⁺ oxidation state. As a result, SnO and Sn²⁺ based phases are thermodynamically less favorable when competing with SnO₂ or other Sn⁴⁺ containing phases under diverse synthesis conditions. An oxide phase with small phase region in the chemical potential space will generally have a narrower growth window and higher tendency to degradation, which poses a synthesis challenge and device stability issues. Thus, a high-performance figure-of-merit for p-type oxide should meet the balance between high mobility and phase stability.

Extending the SnO binary phase into Sn²⁺—O—X ternary compounds could be a possible solution to achieving high-mobility and robust-phase stability p-type oxides. Introducing a third element X into binary SnO can have the following two effects. First, it would enhance the thermodynamic stability of Sn²⁺ based phases. It is expected that the addition of X element would induce extra electrostatic energy among ions with difference sizes and also increase the local stability of the crystal structures. Since the oxidation of Sn²⁺ to Sn⁴⁺ requires adding oxygen atoms, the electrostatic interaction among Sn, O, and X ions and the increased lattice stability would result in a higher energy cost in Sn—O—X to rearrange the atomic positions to accommodate additional oxygen atoms. Phase changes of Sn—O—X compounds could thus be prevented since the underlying bond breaking and structure transformation are prohibited. A good example of complex oxide stabilization is the recently investigated diesel exhaust oxidation catalyst SmMn₂O₅,¹⁵ where Mn³⁺ is less favorable against other oxidation states, but overall this mullite phase is thermodynamically stable over a wide range of chemical potential of Mn and O due to the presence of Sm³⁺. Second, the introduction of X into SnO could increase the band gap by larger energy separation between bonding and anti-bonding states. The energy positions of the band edges, from a molecular orbital theory viewpoint, are associated with the orbital interactions and generally VBM corresponds to the bonding state while CBM to the antibonding state. When X atoms are inserted into the Sn—O network, the VBM/CBM orbital character and the atomic orbital interactions are altered so that their corresponding energy levels shift, which leads to the bandgap change. This bandgap tuning effect caused by X could overcome the issue of small band gap in SnO. Until now, there have been some reports searching for the appropriate “X value” for Sn²⁺—O—X ternary compounds.^{9-11,12} For example, based on the effective mass descriptor, BaSn₂O₃, TiSn₂O₄, Rb₂Sn₂O₃ have been identified as potential high mobility p-type oxides.⁹⁻¹¹ More recently, a thorough search for Sn²⁺ based p-type oxides, based on the criterion of p-type dopability, has led to the identification of SnSO₄.¹² However, their phase stabilities are either marginal or have not been explored. It is not clear whether other Sn²⁺ based oxides favor both low effective mass (thus high mobility) and robust thermodynamically phase stability. Identifying Sn²⁺—O—X p-type oxides with high-mobility as well as robust phase stability is a focus of current research.

In this example, we perform a systematic exploration of Sn²⁺ based ternary oxides to identify p-type oxides with high hole mobility and high phase stability, among a large database containing DFT computed data as available in the Materials Project database. We generalize the example of K₂Sn₂O₃ to search for the appropriate X value for complex Sn²⁺—O—X ternary oxides. In addition to the calculation of mobility values beyond the effective mass, thermodynamic phase stability has also been added as a critically important criterion. We design an efficient and effective p-type oxides identification strategy by using a step-by-step screening process. Through this search process, we have discovered 5 MOs including K₂Sn₂O₃, Rb₂Sn₂O₃, TiSnO₃, Ta₂SnO₆, and Sn₅(PO₅)₂ that would be of great interest as high-mobility p-type oxides. By balancing the phase robustness and hole mobility, Ta₂SnO₆ is identified as the initial p-type oxide with high phase stability and good mobility performance. Detailed analysis on the electronic structures and phase diagrams of these identified oxides demonstrated the tuning effect of X element on the electronic structure and thermodynamic properties of Sn—O base lattice structure. This example demonstrates a design rule that enables high mobility and robust stability for Sn²⁺—O—X ternary compounds, and provides useful insights into rational design of high mobility Sn²⁺ oxide compounds and also serve as a guide for experimental realization of new technological p-type oxide materials.

### Identification Criteria and Computational Methods

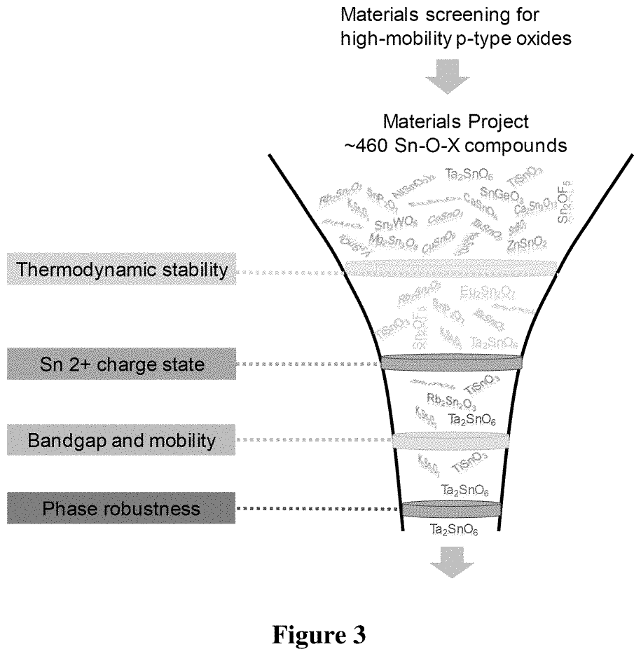

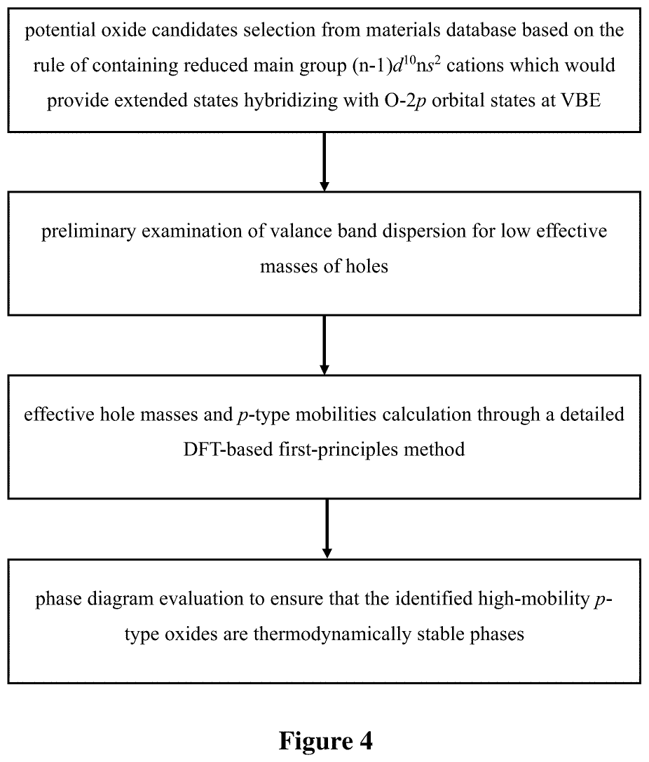

To identify promising Sn²⁺ based p-type oxides with high mobility and phase stability, we have searched among more than 460 Sn—O—X (X is the third element, see Table 5) ternary compounds present in the Materials Project database.¹⁶ FIG. 3 illustrates our step-by-step materials screening procedure. The first screening step was evaluating their stability, which was assessed by the energy above convex hull Eₕᵤₗₗ. A compound phase would be considered unstable and screened out if its formation energy lies above the minimum-free-energy convex hull in the scatter plot of formation energy versus composition, i.e., Eₕᵤₗₗ>0. In the second step, we have identified Sn—O—X compounds with Sn displaying nominal +2 charge state. For compounds where Sn charge state cannot be solely determined based on the Octet rule, we performed Bader charge analysis to identify Sn oxidation state. The identified potential Sn²⁺ oxides were then screened based on the criterion that the valence band maximums display strong E-k dispersions. This criterion ensures that all materials will lead to low effective masses and high hole mobilities. Finally, we gauge their phase robustness by calculating their phase diagrams in the chemical potential space. Thanks to the availability of extensive ab initio predicted electronic structures and formation energies provided by the Materials Project, our searching process is highly reliable and efficient. The screened oxides with good stability and favorable band dispersion are further characterized by detailed electronic structure and thermodynamic property calculations based on density functional theory (DFT). A flow chart for the process is outlined in FIG. 4.

TABLE 5
460 Sn—O—X ternary compounds present in the Materials Project database used for
the high-mobility p-type oxides search. To illustrate our filtering process, the compounds
with a formation energy lying on the convex hull (Eₕᵤₗₗ = 0) are in italics and the
compounds where Sn nominal oxidation state is +2 are in bold. Those compounds with
an energy above hull lower than 30 meV/atom (highlighted with light-yellow) also
deserve consideration due to our DFT computation accuracy and materials kinetics.

| | | | | Band | Nominal charge | |
|---|---|---|---|---|---|---|
| | | Space | E Above | Gap | state | |
| Materials Id | Formula | group | Hull (eV) | (eV) | Sn | X |
| mp-505306 | Eu2Sn2O7 | Fd3m | 0 | 0 | +4 | Eu³⁺ |
| mp-556489 | Ta2SnO6 | Cc | 0 | 2.29 | +2 | Ta⁵⁺ |
| mp-4527 | Li8SnO6 | R3 | 0 | 3.785 | +4 | Li⁺ |
| mp-3688 | Er2Sn2O7 | Fd3m | 0 | 2.679 | +4 | Er³⁺ |
| mp-753798 | Rb2SnO3 | Cmc21 | 0 | 2.121 | +4 | Rb⁺ |
| mp-27493 | Sn3(PO4)2 | P21/c | 0 | 3.438 | +2 | P⁵⁺ |
| mp-4747 | Ca2SnO4 | Pbam | 0 | 2.716 | +4 | Ca²⁺ |
| mp-766947 | Sn(PO3)2 | Pbca | 0 | 3.785 | +2 | P⁵⁺ |
| mp-29590 | Sn2OF5 | C2/m | 0 | 1.927 | +2/+4 | F⁻ |
| mp-3163 | BaSnO3 | Pm3m | 0 | 0.378 | +4 | Ba²⁺ |
| mp-36884 | Mn2SnO4 | Imma | 0 | 0.002 | +4 | Mn²⁺ |
| mp-4086 | La2Sn2O7 | Fd3m | 0 | 2.665 | +4 | La³⁺ |
| mp-767114 | SnP4O11 | P21/c | 0 | 4.439 | +2 | P⁵⁺ |
| mp-22467 | Sn(PbO2)2 | P42/mbe | 0 | 2.063 | +4 | Pb²⁺ |
| mp-27480 | Sn2OF2 | C2/m | 0 | 2.66 | +2/+4 | F⁻ |
| mp-542967 | SnSO4 | Pnma | 0 | 4.132 | +2 | S⁶⁺ |
| mp-28261 | Na4SnO3 | Cc | 0 | 1.894 | +2 | Na |
| mp-34022 | Mg2SnO4 | Imma | 0 | 2.534 | +4 | Mg²⁺ |
| mp-752692 | K2SnO₂ | P1 | 0 | 1.554 | +2 | K⁺ |
| mp-7863 | Rb2Sn2O3 | R3m | 0 | 1.225 | +2 | Rb⁺ |
| mp-3370 | Y2Sn2O7 | Fd3m | 0 | 2.752 | +4 | Y³⁺ |
| mp-556672 | Sn(SeO3)2 | Pa3 | 0 | 2.585 | +4 | Se⁴⁺ |
| mp-11651 | Yb3SnO | Pm3m | 0 | 0 | −4 | Yb⁺² |
| mp-36028 | Co2SnO4 | Imma | 0 | 1.318 | +4 | Co²⁺ |
| mp-778057 | Na2SnO₂ | Pbcn | 0 | 2.103 | +2 | Na⁺ |
| mp-12231 | SnTe3O8 | Ia3 | 0 | 2.925 | +4 | Te⁴⁺ |
| mp-3884 | Ho2Sn2O7 | Fd3m | 0 | 2.698 | +4 | Ho³⁺ |
| mp-7258 | K4SnO4 | P1 | 0 | 2.341 | +4 | K⁺ |
| mp-759223 | Sn(SO4)2 | Pbca | 0 | 2.38 | +4 | S⁶⁺ |
| mp-768950 | Sn2(SO4)3 | R3 | 0 | 2.593 | +2/+4 | S⁶⁺ |
| mp-3540 | Li2SnO3 | C2/c | 0 | 3.125 | +4 | Li²⁺ |
| mp-15170 | Lu2Sn2O7 | Fd3m | 0 | 2.613 | +4 | Lu³⁺ |
| mp-761184 | Na2SnO3 | C2/c | 0 | 2.51 | +4 | Na⁺ |
| mp-17114 | Nd2Sn2O7 | Fd3m | 0 | 2.669 | +4 | Nd³⁺ |
| mp-1024073 | K2Sn3O7 | Pnma | 0 | 1.913 | +4 | K⁺ |
| mp-2883 | Sm2Sn2O7 | Fd3m | 0 | 2.703 | +4 | Sm³⁺ |
| mp-17064 | Gd2Sn2O7 | Fd3m | 0 | 2.626 | +4 | Gd³⁺ |
| mp-17730 | K2SnO3 | Pnma | 0 | 2.121 | +4 | K⁺ |
| mp-540796 | Cs2Sn2O3 | Pnma | 0 | 2.579 | +2 | Cs⁺ |
| mp-773455 | V2SnO7 | Pa3 | 0 | 2.605 | +4 | V⁵⁺ |
| mp-5966 | Cd2SnO4 | Pbam | 0 | 0.406 | +4 | Cd²⁺ |
| mp-4394 | Pr2Sn2O7 | Fd3m | 0 | 2.641 | +4 | Pr³⁺ |
| mp-14988 | K4SnO3 | Pbca | 0 | 2.11 | +2 | K⁺ |
| mp-754246 | TiSnO3 | R3 | 0 | 1.102 | +2 | Ti⁴⁺ |
| mp-1198288 | Sn2Bi2O7 | P31 | 0 | 2.665 | +4 | Bi³⁺ |
| mp-30989 | Sn(NO3)4 | P21/c | 0 | 3.638 | +4 | N⁵⁺ |
| mp-754329 | CdSnO3 | R3 | 0 | 0.958 | +4 | Cd²⁺ |
| mp-3334 | Tm2Sn2O7 | Fd3m | 0 | 2.655 | +4 | Tm³⁺ |
| mp-29243 | Ba3SnO | Pm3m | 0 | 0 | −4 | Ba²⁺ |
| mp-29241 | Ca3SnO | Pm3m | 0 | 0 | −4 | Ca²⁺ |
| mp-4190 | CaSnO3 | R3 | 0 | 2.921 | +4 | Ca²⁺ |
| mp-8624 | K2Sn2O3 | I213 | 0 | 1.405 | +2 | K⁺ |
| mp-3359 | Ba2SnO4 | I4/mmm | 0 | 2.449 | +4 | Ba²⁺ |
| mp-867998 | In15SnO24 | R3 | 0 | 0 | +2/+4 | In³⁺ |
| mp-1178212 | FeSnO3 | P1 | 0 | 0.723 | +4 | Fe²⁺ |
| mp-560715 | Sn5(PO5)2 | P1 | 0 | 2.698 | +2 | P⁵⁺ |
| mp-757192 | SnP2O7 | P1 | 0 | 3.937 | +4 | P⁵⁺ |
| mp-4991 | Tb2Sn2O7 | Fd3m | 0 | 2.724 | +4 | Tb³⁺ |
| mp-17213 | Cs4SnO4 | P21/c | 0 | 2.343 | +4 | Cs⁺ |
| mp-770846 | Ba3Sn2O7 | Cmcm | 0 | 1.671 | +4 | Ba²⁺ |
| mp-756570 | Rb4SnO3 | Cc | 0 | 1.477 | +2 | Rb⁺ |
| mp-7961 | Sr3SnO | Pm3m | 0 | 0 | −4 | Sr²⁺ |
| mp-2879 | SrSnO3 | Pnma | 0 | 1.741 | +4 | Sr²⁺ |
| mp-20569 | MnSnO3 | R3 | 0 | 0.86 | +4 | Mn²⁺ |
| mp-27931 | Rb2SnO2 | P212121 | 0 | 2.228 | +2 | Rb⁺ |
| mp-4287 | Sr2SnO4 | P42/ncm | 0 | 2.647 | +4 | Sr²⁺ |
| mp-13252 | SnB4O7 | Pmn21 | 0 | 3.575 | +2 | B³⁺ |
| mp-7118 | Rb4SnO4 | P1 | 0 | 2.161 | +4 | Rb⁺ |
| mp-20845 | Dy2Sn2O7 | Fd3m | 0 | 2.714 | +4 | Dy³⁺ |
| mp-540586 | Tl2SnO3 | Pnma | 0 | 1.127 | +4 | Tl³⁺ |
| mp-554022 | Sn2P2O7 | P1 | 0 | 3.483 | +2 | P⁵⁺ |
| mp-769144 | SnGeO3 | P2/c | 0 | 2.067 | +2 | Ge⁴⁺ |
| mp-28456 | Sn15Os3O14 | Cm | 0 | 1.52 | +2/+4 | Os⁴⁺ |
| mp-9655 | Na4SnO4 | P1 | 0 | 2.085 | +4 | Na⁺ |
| mp-867730 | Cs2SnO3 | Cmcm | 0 | 2.386 | +4 | Cs⁺ |
| mvc-15350 | Ca2Sn3O8 | C2/m | 0 | 2.711 | +4 | Ca²⁺ |
| mp-1178513 | BaSnO3 | Imma | 0 | 0.612 | +4 | Ba²⁺ |
| mp-754745 | Na2SnO3 | C2/m | 0.001 | 2.47 | +4 | Na⁺ |
| mp-675857 | Cd2SnO4 | Imma | 0.001 | 0.221 | +4 | Cd²⁺ |
| mp-28932 | Sn4OF6 | P212121 | 0.001 | 3.21 | +2 | F⁻ |
| mp-18288 | Ti(SnO2)2 | P42/mbc | 0.001 | 1.084 | +2 | Ti⁴⁺ |
| mp-769368 | Rb4SnO3 | Pbca | 0.001 | 2.046 | +2 | RB⁺ |
| mp-766006 | In15SnO24 | C2 | 0.001 | 0 | +2/+4 | In³⁺ |
| mp-757076 | SnP2O7 | P21/c | 0.002 | 3.874 | +4 | P⁵⁺ |
| mp-4941 | Sr2SnO4 | Cmce | 0.002 | 2.704 | +4 | Sr²⁺ |
| mp-17743 | Sr3Sn2O7 | Cmcm | 0.003 | 2.162 | +4 | Sr²⁺ |
| mp-1194203 | Sr2SnO4 | Pccn | 0.003 | 2.678 | +4 | Sr²⁺ |
| mp-1176491 | MgSnO3 | R3 | 0.003 | 2.559 | +4 | Mn²⁺ |
| mp-767141 | Sn(PO3)2 | P21/c | 0.003 | 3.752 | +2 | P⁵⁺ |
| mp-779662 | Zr5Sn3O | P63/mcm | 0.004 | 0 | −2/−4 | Zr²⁺ |
| mp-766434 | SnP2O7 | P21/c | 0.004 | 3.745 | +4 | P⁵⁺ |
| mp-645709 | SnSO4 | P21/c | 0.004 | 4.174 | +2 | S⁶⁺ |
| mp-754848 | Na2SnO3 | Fddd | 0.004 | 2.377 | +4 | Na⁺ |
| mp-25908 | Sn(PO3)4 | Pbcn | 0.004 | 3.459 | +4 | P⁵⁺ |
| mp-555682 | Sn(SeO3)2 | P21/c | 0.005 | 3.076 | +4 | Se⁴⁺ |
| mp-761931 | Na8SnO6 | P63cm | 0.005 | 1.058 | +4 | Na⁺ |
| mp-12866 | SrSnO3 | Imma | 0.006 | 1.612 | +4 | Sr²⁺ |
| mp-561545 | Sn4P2O9 | P21/c | 0.006 | 3.114 | +2 | P⁵⁺ |
| mp-768510 | Ba4Sn3O10 | Cmce | 0.006 | 1.19 | +4 | Ba²⁺ |
| mp-768936 | Sn2(SO4)3 | P21/c | 0.007 | 2.341 | +2/+4 | S⁶⁺ |
| mp-7502 | K2Sn2O3 | R3m | 0.009 | 1.231 | +2 | K⁺ |
| mp-20342 | Yb2Sn2O7 | Fd3m | 0.009 | 0 | +4 | Yb³⁺ |
| mp-556100 | Si(Sn3O4)2 | P63mc | 0.009 | 1.903 | +2 | Si⁴⁺ |
| mp-1101518 | Sn(PO3)3 | P312 | 0.01 | 2.425 | +2/+4 | P⁵⁺ |
| mp-680202 | Ag2SnO3 | P212121 | 0.01 | 0 | +4 | Ag⁺ |
| mp-645774 | SnSO4 | P1 | 0.011 | 4.069 | +2 | S⁶⁺ |
| mp-23372 | Sn2Bi2O7 | Fd3m | 0.011 | 2.712 | +4 | Bi³⁺ |
| mp-12867 | SrSnO3 | I4/mcm | 0.011 | 1.555 | +4 | Sr²⁺ |
| mp-759209 | Ag2SnO3 | P6322 | 0.012 | 0 | +4 | Ag⁺ |
| mp-556031 | Sn2P2O7 | P21/c | 0.012 | 3.637 | +2 | P⁵⁺ |
| mp-768939 | Sn2(SO4)3 | P21/c | 0.012 | 2.347 | +2/+4 | S⁶⁺ |
| mp-1147658 | Cu6SnO8 | Fm3m | 0.013 | 0 | +4 | Cu²⁺ |
| mp-1101467 | SnP4O11 | P21/c | 0.013 | 4.114 | +2 | P⁵⁺ |
| mp-530571 | Na4Sn3O8 | P4132 | 0.013 | 2.378 | +4 | Na⁺ |
| mp-1179534 | Sn3(HO2)2 | Cc | 0.013 | 2.445 | +2 | H⁺ |
| mp-3376 | Sr2SnO4 | I4/mmm | 0.013 | 2.583 | +4 | Sr²⁺ |
| mp-766163 | TiSn9O20 | C2/m | 0.014 | 1.126 | +4 | Ti⁴⁺ |
| mp-685528 | Sn(WO3)18 | Pmmn | 0.014 | 0 | +4 | W^{4+/6+} |
| mp-4438 | CaSnO3 | Pnma | 0.014 | 2.334 | +4 | Ca²⁺ |
| mp-769294 | Rb8SnO6 | P63cm | 0.014 | 1.071 | +4 | Rb⁺ |
| mp-625541 | Sn3(HO2)2 | P421c | 0.015 | 2.305 | +2 | H⁺ |
| mp-752504 | VSnO4 | Cmmm | 0.015 | 1.608 | +2/+4 | V⁵⁺ |
| mp-767365 | SnP4O11 | P1 | 0.016 | 3.919 | +2 | P⁵⁺ |
| mp-35493 | Zn2SnO4 | Imma | 0.017 | 0.825 | +4 | Zn²⁺ |
| mp-752538 | KSnO2 | P1 | 0.017 | 2.209 | +2/+4 | K⁺ |
| mp-531245 | Co2SnO4 | P1 | 0.018 | 0.415 | +4 | Co²⁺ |
| mp-755486 | Na2SnO3 | P63/mcm | 0.018 | 2.26 | +4 | Na⁺ |
| mp-690495 | Fe5SnO8 | R3m | 0.019 | 1.003 | +4 | Fe^{2+/3+} |
| mp-767192 | Sn(PO3)2 | C2/c | 0.022 | 3.054 | +2 | P⁵⁺ |
| mp-691106 | MnSnO3 | R3c | 0.023 | 0.227 | +4 | Mn²⁺ |
| mp-767039 | Sn8P2O13 | C2/m | 0.024 | 1.777 | +2 | P⁵⁺ |
| mp-766979 | Sn4P2O9 | P21/c | 0.025 | 2.911 | +2 | P⁵⁺ |
| mp-757131 | Sn(PO3)4 | C2/c | 0.025 | 3.355 | +4 | P⁵⁺ |
| mp-766391 | Ti(Sn2O5)2 | P1 | 0.026 | 2.047 | +4 | Ti⁴⁺ |
| mp-761842 | Hf3SnO8 | P2 | 0.026 | 3.598 | +4 | Hf⁴⁺ |
| mp-776110 | SiSnO3 | P2/c | 0.026 | 2.554 | +2 | Si⁴⁺ |
| mp-754654 | NiSnO3 | R3 | 0.028 | 1.752 | +4 | Ni²⁺ |
| mp-973261 | Mg2SnO4 | Fd3m | 0.028 | 1.903 | +4 | Mg²⁺ |
| mvc-560 | Sn3(P2O7)2 | P21/c | 0.028 | 2.906 | +2/+4 | P⁵⁺ |
| mvc-14201 | Ca3Sn2O7 | Cmc21 | 0.029 | 2.961 | +4 | Ca²⁺ |
| mp-849371 | CdSnO3 | Pnma | 0.03 | 0.69 | +4 | Cd²⁺ |
| mvc-8179 | MgSn2O5 | Cmcm | 0.031 | 1.782 | +4 | Mg²⁺ |
| mp-757156 | Sn(PO3)4 | C2/c | 0.031 | 2.819 | +4 | P⁵⁺ |
| mp-767134 | Sn2P2O7 | P21/c | 0.034 | 2.886 | +2 | P⁵⁺ |
| mp-1101402 | Sn2N2O | I41/amd | 0.034 | 0.676 | +4 | N³⁻ |
| mp-761574 | CoSnO3 | R3 | 0.036 | 1.186 | +4 | Co²⁺ |
| mp-777394 | Sn2N2O | P3m1 | 0.036 | 0.762 | +4 | N³⁻ |
| mp-26950 | Sn2(PO3)5 | Pc | 0.036 | 0 | +2/+4 | P⁵⁺ |
| mp-767140 | Sn2P2O7 | P1 | 0.037 | 3.08 | +2 | P⁵⁺ |
| mp-765970 | Ti3Sn7O20 | Cmmm | 0.037 | 1.744 | +4 | Ti⁴⁺ |
| mp-1216649 | TiSnO4 | Cmmm | 0.037 | 1.583 | +4 | Ti⁴⁺ |
| mp-557633 | Sn2WO5 | P21/c | 0.037 | 2.41 | +2 | W⁵⁺ |
| mp-676320 | In4(SnO4)3 | P1 | 0.039 | 0.884 | +4 | In³⁺ |
| mp-768877 | Sn2Ge2O7 | P1 | 0.039 | 1.743 | +2/+4 | Ge⁴⁺ |
| mp-756857 | V4SnO12 | C2 | 0.039 | 2.509 | +4 | V⁵⁺ |
| mp-673669 | In4(SnO4)3 | P1 | 0.039 | 0.88 | +4 | In³⁺ |
| mp-781712 | Na2SnO₂ | P212121 | 0.039 | 2.407 | +2 | Na⁺ |
| mp-17887 | SnP2O7 | Pa3 | 0.04 | 3.322 | +4 | P⁵⁺ |
| mp-757375 | Ti2Sn3O10 | Cmm2 | 0.041 | 1.727 | +4 | Ti⁴⁺ |
| mp-13334 | ZnSnO3 | R3c | 0.041 | 1.077 | +4 | Zn²⁺ |
| mp-645740 | SnSO4 | P1 | 0.042 | 3.522 | +2 | S⁶⁺ |
| mp-769187 | Sn5P6O25 | R3 | 0.042 | 2.556 | +4 | P⁵⁺ |
| mvc-8086 | Sn(GeO3)2 | C2/c | 0.042 | 1.996 | +4 | Ge⁴⁺ |
| mp-1101728 | Sn2(SO4)3 | Pbca | 0.043 | 1.405 | +2/+4 | S⁶⁺ |
| mvc-8186 | Sn(GeO3)2 | P21/c | 0.043 | 2.054 | +4 | Ge⁴⁺ |
| mp-757495 | Sn(PO3)4 | C2/c | 0.043 | 2.955 | +4 | P⁵⁺ |
| mvc-7646 | Mg2Sn3O8 | P63mc | 0.043 | 1.934 | +4 | Mg²⁺ |
| mp-761148 | Ti9SnO020 | C2/m | 0.044 | 1.801 | +4 | Ti⁴⁺ |
| mp-753706 | Mn3SnO8 | P63mc | 0.044 | 1.366 | +4 | Mn²⁺ |
| mp-753683 | Sn2OF2 | P42/nmc | 0.044 | 2.247 | +2 | F⁻ |
| mp-753048 | TiSnO4 | Cm | 0.044 | 1.837 | +4 | Ti⁴⁺ |
| mp-760170 | Sn13(O5F3)2 | C2/c | 0.046 | 1.999 | +2 | F⁻ |
| mp-556980 | Sn3WO6 | C2/c | 0.046 | 2.204 | +2 | W⁶⁺ |
| mp-755448 | Rb2SnO3 | Cmce | 0.047 | 2.072 | +4 | Rb⁺ |
| mp-753246 | Sn3(OF)2 | Pnma | 0.047 | 2.452 | +2 | F⁻ |
| mp-774335 | Sn2P2O7 | P41 | 0.048 | 3.108 | +2 | P⁵⁺ |
| mp-546973 | SrSnO3 | Pm3m | 0.048 | 0.982 | +4 | Sr²⁺ |
| mp-766168 | Ti4SnO10 | P1 | 0.049 | 1.766 | +4 | Ti⁴⁺ |
| mp-762258 | Na2Sn4O9 | P3c1 | 0.049 | 1.484 | +4 | Na⁺ |
| mp-753979 | Sn2P2O7 | P1 | 0.049 | 2.909 | +2 | P⁵⁺ |
| mp-772086 | Ba4Sn3O10 | Cmce | 0.049 | 2.728 | +4 | Ba²⁺ |
| mp-759737 | Ti3(SnO5)2 | Cmm2 | 0.05 | 1.619 | +4 | Ti⁴⁺ |
| mp-1222532 | Li7(SnO3)4 | C2 | 0.05 | 0 | +4/−4 | Li⁺ |
| mp-672972 | Sn(PO3)3 | P1 | 0.051 | 2.345 | +2/+4 | P⁵⁺ |
| mp-1191975 | Sn2Pb2O7 | Fd3m | 0.053 | 0 | +4 | Pb^{2+/4+} |
| mp-17700 | SnWO4 | Pnna | 0.053 | 0.921 | +2 | W⁶⁺ |
| mvc-7761 | Ca2Sn3O8 | P63mc | 0.053 | 2.057 | +4 | Ca²⁺ |
| mp-761118 | Ti7Sn3O20 | Cmmm | 0.054 | 1.525 | +4 | Ti⁴⁺ |
| mp-777314 | Sn2N2O | P1 | 0.054 | 0.116 | +4 | N³⁻ |
| mvc-13015 | Cu3(SnO3)4 | Im3 | 0.054 | 0 | +4 | Cu²⁺ |
| mp-14628 | ZnSnO3 | R3 | 0.055 | 1.305 | +4 | Zn²⁺ |
| mp-850280 | Na8SnO6 | R3 | 0.055 | 1.732 | +4 | Na⁺ |
| mp-761454 | Sn(WO3)3 | P21/m | 0.055 | 0 | +4 | W^{4+/6+} |
| mp-27018 | SnPO4 | Pna21 | 0.056 | 2.44 | +2/+4 | P⁵⁺ |
| mp-767076 | Sn(PO3)2 | P21/c | 0.056 | 3.753 | +2 | P⁵⁺ |
| mp-773817 | Sn2N2O | P1 | 0.056 | 0.007 | +4 | N³⁻ |
| mp-673129 | Sn(PO3)3 | P6c2 | 0.056 | 0 | +2/+4 | P⁵⁺ |
| mp-779703 | Na4Sn5O12 | P1 | 0.056 | 1.41 | +4 | Na⁺ |
| mp-753564 | Sn3(OF)2 | Pnma | 0.057 | 1.951 | +2 | F⁻ |
| mp-755619 | Sn2P2O7 | C2/c | 0.058 | 2.726 | +2 | P⁵⁺ |
| mp-28025 | Sn2SO5 | P421c | 0.058 | 3.511 | +2 | S⁶⁺ |
| mp-777302 | Sn2N2O | P1 | 0.058 | 0.733 | +4 | N³⁻ |
| mp-773831 | Sn2N2O | P1 | 0.059 | 0.064 | +4 | N³⁻ |
| mvc-9723 | Sn2P2O9 | Pnma | 0.059 | 2.229 | +4 | P⁵⁺ |
| mp-26762 | Sn(PO3)3 | P212121 | 0.061 | 0 | +2/+4 | P⁵⁺ |
| mp-776966 | Sn2N2O | P1 | 0.061 | 0.103 | +4 | N³⁻ |
| mp-762250 | Sn2N2O | P1 | 0.061 | 0.036 | +4 | N³⁻ |
| mp-862606 | EuSnO3 | Pm3m | 0.061 | 0 | +4 | Eu²⁺ |
| mp-767063 | Sn(PO3)2 | C2221 | 0.062 | 3.594 | +2 | P⁵⁺ |
| mp-1178214 | FeSnO3 | Pnma | 0.062 | 0.739 | +4 | Fe²⁺ |
| mvc-3343 | Zn3Sn2O7 | Cmc21 | 0.063 | 1.949 | +4 | Zn²⁺ |
| mp-773830 | Sn2N2O | P1 | 0.063 | 0.038 | +4 | N³⁻ |
| mp-771769 | Co3SnO8 | P63mc | 0.063 | 0 | +4 | Co⁴⁺ |
| mvc-8236 | ZnSn2O5 | Cmcm | 0.063 | 0.846 | +4 | Zn²⁺ |
| mp-13554 | SnHgO3 | R3c | 0.064 | 0 | +4 | Hg²⁺ |
| mp-762347 | Sn2N2O | P1 | 0.064 | 0.631 | +4 | N³⁻ |
| mp-758863 | Sn2N2O | P1 | 0.065 | 0 | +4 | N³⁻ |
| mp-673118 | Sn3(P2O7)2 | P1 | 0.065 | 2.226 | +2/+4 | P⁵⁺ |
| mvc-7701 | Zn2Sn3O8 | P63mc | 0.066 | 1.251 | +4 | Zn²⁺ |
| mp-1142992 | Si2SnO6 | C2/c | 0.066 | 3.324 | +4 | Si⁴⁺ |
| mp-773864 | TiSnO4 | I4m2 | 0.066 | 2.259 | +4 | Ti⁴⁺ |
| mvc-15995 | Mg3Sn2O7 | Cmc21 | 0.067 | 2.869 | +4 | Mg²⁺ |
| mp-757467 | Mn5SnO12 | C2/m | 0.068 | 1.472 | +4 | Mn⁴⁺ |
| mp-767308 | Mn21Sn9O40 | I4 | 0.068 | 0.003 | +4 | Mn²⁺ |
| mp-766117 | Sn2N2O | P1 | 0.068 | 0.564 | +4 | N³⁻ |
| mp-778681 | V3SnO8 | Cm | 0.069 | 0.82 | +4 | V^{3+/5+} |
| mvc-6576 | Ca(SnO2)2 | Imma | 0.069 | 1.592 | +2/+4 | Ca²⁺ |
| mp-776083 | HfSnO3 | R3 | 0.069 | 2.364 | +2 | Hf⁴⁺ |
| mp-755856 | Mg2SnO4 | Pbam | 0.07 | 2.641 | +4 | Mg²⁺ |
| mp-765595 | Sn(PO3)3 | P212121 | 0.072 | 0 | +2/+4 | P⁵⁺ |
| mp-625789 | Sn3(HO2)2 | Cc | 0.073 | 2.209 | +2 | H⁺ |
| mp-769348 | MgSnO3 | Pnma | 0.073 | 2.01 | +4 | Mg²⁺ |
| mp-773498 | Na6Sn2O7 | P21/c | 0.073 | 1.993 | +4 | Na⁺ |
| mp-777814 | Na6Sn2O7 | C2/c | 0.074 | 1.358 | +4 | Na⁺ |
| mp-1101720 | SnPbO3 | Pbam | 0.076 | 1.354 | +4 | Pb²⁺ |
| mp-752613 | CoSnO3 | Pnma | 0.076 | 0.983 | +4 | Co²⁺ |
| mp-3593 | Ta2Sn2O7 | Fd3m | 0.078 | 1.492 | +2 | Ta⁵⁺ |
| mp-1101386 | Sn2P207 | C2/c | 0.078 | 2.417 | +2 | P⁵⁺ |
| mp-26944 | Sn2P3O10 | P21/m | 0.078 | 0 | +2/+4 | P⁵⁺ |
| mp-1226854 | Ce4SnO10 | R3m | 0.078 | 1.477 | +4 | Ce⁴⁺ |
| mp-1101413 | Sn4P2O9 | P1 | 0.079 | 2.076 | +2 | P⁵⁺ |
| mp-768330 | Sn2P2O7 | Cc | 0.079 | 2.407 | +2 | P⁵⁺ |
| mp-768883 | Sn2(SO4)3 | R3c | 0.082 | 0 | +2/+4 | S⁶⁺ |
| mvc-13441 | ZnSnO3 | Pnma | 0.083 | 1.918 | +4 | Zn²⁺ |
| mvc-14010 | Zn2Sn3O8 | C2/m | 0.083 | 1.784 | +4 | Zn²⁺ |
| mp-542769 | Sn(CO2)2 | C2/c | 0.084 | 2.608 | +4 | C²⁺ |
| mp-761872 | Na2Sn2O3 | I213 | 0.084 | 0.571 | +2 | Na⁺ |
| mvc-10331 | Sn3P3O13 | P21/m | 0.085 | 0 | +2/+4 | P⁵⁺ |
| mp-1221361 | Mn5SnO8 | I4m2 | 0.085 | 0 | +4 | Mn^{2+/4+} |
| mp-684053 | Sn6P7O24 | P21/m | 0.085 | 0 | +2/+4 | P⁵⁺ |
| mp-769046 | Si2Sn2O7 | P1 | 0.086 | 2.556 | +2/+4 | Sⁱ⁴⁺ |
| mp-777546 | NaSnO | P4/nmm | 0.087 | 0 | | |
| mp-766929 | Sn4P2O9 | Pnma | 0.087 | 2.22 | +2 | P⁵⁺ |
| mp-770865 | Mn3SnO8 | P4332 | 0.088 | 1.672 | +4 | Mn²⁺ |
| mp-26172 | Sn(PO3)3 | P1 | 0.088 | 0 | +2/+4 | P⁵⁺ |
| mp-754839 | SnBiO4 | I4m2 | 0.088 | 0 | +2/+4 | Bi⁵⁺ |
| mp-778451 | Na6Sn2O7 | C2/c | 0.088 | 1.962 | +4 | Na⁺ |
| mp-768943 | Sn2(SO4)3 | Pbcn | 0.088 | 0 | +2/+4 | S⁶⁺ |
| mp-26446 | Sn4(PO4)3 | R3c | 0.089 | 0 | +2/+4 | P⁵⁺ |
| mp-31004 | Sn(SO2)2 | P21/c | 0.089 | 2.681 | +4 | S²⁺ |
| mp-755834 | AgSnO3 | Cmmm | 0.09 | 0 | +4 | Ag⁺ |
| mp-1218921 | SnSbO4 | Cmmm | 0.09 | 0 | +2/+4 | Sb⁵⁺ |
| mp-540395 | Sn4(PO4)3 | P63 | 0.091 | 0 | +2/+4 | P⁵⁺ |
| mp-756229 | Na(SnO2)2 | Fd3m | 0.091 | 0.041 | +2/+4 | Na⁺ |
| mp-772724 | SnBO3 | Cc | 0.091 | 2.376 | +2/+4 | B³⁺ |
| mp-556524 | Nb2Sn2O7 | Fd3m | 0.092 | 0.87 | +2 | Nb⁵⁺ |
| mp-755027 | In2Sn2O7 | Fd3m | 0.092 | 0.281 | +4 | In³⁺ |
| mvc-5359 | Ca(SnO2)2 | Cm | 0.093 | 1.586 | +2/+4 | Ca²⁺ |
| mvc-7545 | SnAs2O7 | P21/c | 0.094 | 1.198 | +4 | As⁵⁺ |
| mp-849767 | Mn3SnO8 | R3m | 0.095 | 1.334 | +4 | Mn⁴⁺ |
| mvc-15812 | Mg2Sn3O8 | C2/m | 0.096 | 2.449 | +4 | Mg²⁺ |
| mp-1226901 | Ce4SnO10 | Immm | 0.097 | 1.439 | +4 | Ce⁴⁺ |
| mvc-660 | Sn(WO4)2 | P2/c | 0.097 | 2.674 | +4 | W⁶⁺ |
| mp-760054 | Sn9(O2F5)2 | P4/n | 0.097 | 2.49 | +2 | F⁻ |
| mp-1226979 | Ce3SnO8 | R3m | 0.098 | 1.474 | +4 | Ce⁴⁺ |
| mp-1104726 | Cd2SnO4 | Fd3m | 0.099 | 0.111 | +4 | Cd²⁺ |
| mvc-14586 | ZnSnO₂ | P1 | 0.101 | 1.645 | +2 | Zn²⁺ |
| mvc-5214 | Ca(SnO2)2 | Cm | 0.102 | 1.529 | +2/+4 | Ca²⁺ |
| mvc-16447 | Zn(SnO2)2 | Cm | 0.102 | 0.869 | +2/+4 | Zn²⁺ |
| mp-1101394 | SnGeO3 | R3 | 0.104 | 2.609 | +2 | Ge⁴⁺ |
| mvc-6497 | Mg(SnO2)2 | Imma | 0.109 | 1.047 | +2/+4 | Mg²⁺ |
| mvc-2075 | Mg2Sn9O13 | C2/m | 0.11 | 0 | +2/+4 | Mg²⁺ |
| mvc-5322 | SnP2O7 | P1 | 0.111 | 2.391 | +4 | P⁵⁺ |
| mp-978952 | SnPbO3 | Pm3m | 0.116 | 1.793 | +4 | Pb²⁺ |
| mp-1103830 | Zn2SnO4 | Fd3m | 0.117 | 0.403 | +4 | Zn²⁺ |
| mp-17844 | SnWO4 | P213 | 0.117 | 3.837 | +2 | W⁶⁺ |
| mp-1006619 | Sn3PO6 | P21/c | 0.118 | 0 | +2/+4 | P⁵⁺ |
| mp-1226805 | Ce3SnO8 | P4/mmm | 0.121 | 1.087 | +4 | Ce⁴⁺ |
| mvc-6532 | Zn(SnO2)2 | Imma | 0.123 | 1.142 | +2/+4 | Zn²⁺ |
| mp-685363 | Cd18Sn19O56 | P1 | 0.124 | 0 | +4 | Cd²⁺ |
| mvc-5221 | Mg(SnO2)2 | Cm | 0.124 | 1.3 | +2/+4 | Mg²⁺ |
| mp-1198177 | Sn2PO5 | P21/c | 0.124 | 0.605 | +2/+4 | P⁵⁺ |
| mp-684482 | Sn(PO3)3 | P212121 | 0.125 | 0 | +2/+4 | P⁵⁺ |
| mp-1187515 | YbSnO3 | Pm3m | 0.126 | 1.704 | +2/+4 | Yb³⁺ |
| mp-684502 | Sn2P3O10 | P21/c | 0.128 | 0.34 | +2/+4 | P⁵⁺ |
| mvc-5088 | Mg(SnO2)2 | Cm | 0.132 | 1.301 | +2/+4 | Mg²⁺ |
| mvc-6844 | Ca(SnO2)2 | Pmmn | 0.134 | 2.061 | +2/+4 | Ca²⁺ |
| mvc-5313 | Zn(SnO2)2 | Cm | 0.134 | 1.029 | +2/+4 | Zn²⁺ |
| mp-850192 | Co5SnO12 | C2/m | 0.138 | 0.992 | +4 | Co²⁺ |
| mvc-6795 | Si2SnO6 | Pbca | 0.14 | 3.209 | +4 | Si⁴⁺ |
| mp-1101484 | Sn2P3O10 | C2/c | 0.143 | 0 | +2/+4 | P⁵⁺ |
| mp-741677 | SnC18O25 | P3 | 0.145 | 0.012 | +4 | Cl⁻ |
| mvc-2898 | Zn(SnO2)4 | Cm | 0.146 | 0.663 | +2/+4 | Zn²⁺ |
| mp-27357 | Sn5W8O23 | P63/m | 0.146 | 1.719 | +2/+4 | W⁴⁺ |
| mvc-6860 | Zn(SnO2)2 | P2/c | 0.15 | 2.042 | +2/+4 | Zn²⁺ |
| mvc-2713 | Sn5(TeO6)3 | C2/c | 0.15 | 0.362 | +2/+4 | Te⁶⁺ |
| mvc-16287 | ZnSnO₂ | P1 | 0.15 | 1.137 | +2 | Zn²⁺ |
| mp-1186893 | RbSnO3 | Pm3m | 0.152 | 0 | +4 | Rb⁺ |
| mvc-668 | Sn(WO4)2 | P1 | 0.155 | 3.229 | +4 | W⁶⁺ |
| mvc-10708 | Ca(SnO2)4 | Cm | 0.155 | 0.587 | +2/+4 | Ca²⁺ |
| mp-504543 | SnPbO3 | Fd3m | 0.155 | 0 | +4 | Pb²⁺ |
| mvc-2834 | Mg(SnO2)4 | Cm | 0.158 | 0.48 | +2/+4 | Mg²⁺ |
| mvc-2048 | Zn2Sn9O13 | P1 | 0.158 | 0 | +2/+4 | Zn²⁺ |
| mp-1018639 | TiSnO3 | Pm3m | 0.158 | 1.095 | +2 | Ti⁴⁺ |
| mvc-7303 | Mg(SnO2)2 | C2/m | 0.158 | 0.901 | +2/+4 | Mg²⁺ |
| mvc-9905 | Ca(SnO2)2 | P1 | 0.158 | 0.412 | +2/+4 | Ca²⁺ |
| mvc-10491 | CaSn4O9 | P4/n | 0.159 | 0.759 | +4 | Ca²⁺ |
| mvc-7287 | Ca(SnO2)2 | C2/m | 0.16 | 0.94 | +2/+4 | Ca²⁺ |
| mvc-6826 | Mg(SnO2)2 | Pmmn | 0.162 | 2.093 | +2/+4 | Mg²⁺ |
| mvc-6370 | Mg(SnO2)2 | P21/c | 0.162 | 1.564 | +2/+4 | Mg²⁺ |
| mp-673117 | Sn2P3O10 | C2/c | 0.162 | 0 | +2/+4 | P⁵⁺ |
| mvc-1016 | SnP2O7 | P21/c | 0.167 | 1.876 | +4 | P⁵⁺ |
| mp-557003 | Sn5(W4O11)2 | P63/m | 0.168 | 1.72 | +2/+4 | W⁴⁺ |
| mvc-3803 | Ca2Sn2O5 | Pbam | 0.169 | 1.413 | +2/+4 | Ca²⁺ |
| mvc-16437 | Ca(SnO2)2 | Pnma | 0.171 | 1.003 | +2/+4 | Ca²⁺ |
| mp-673078 | SnPO4 | Cc | 0.173 | 0 | +2/+4 | P⁵⁺ |
| mvc-5975 | Mg(SnO2)2 | Pnma | 0.173 | 1.479 | +2/+4 | Mg²⁺ |
| mvc-10691 | Zn(SnO2)4 | Cm | 0.175 | 0 | +2/+4 | Zn²⁺ |
| mvc-13666 | MgSnO₂ | P1 | 0.177 | 0.633 | +2 | Mg²⁺ |
| mvc-3464 | YSnO3 | P63cm | 0.179 | 0 | +2/+4 | Y³⁺ |
| mvc-9024 | CaSn3O7 | Pnma | 0.179 | 1.103 | +4 | Ca²⁺ |
| mvc-9695 | Ca(SnO2)2 | Cm | 0.179 | 0.719 | +2/+4 | Ca²⁺ |
| mvc-6573 | Ca(SnO2)2 | Pca21 | 0.18 | 1.45 | +2/+4 | Ca²⁺ |
| mvc-6184 | Sn3(AsO4)4 | P21/c | 0.184 | 0.57 | +4 | As⁵⁺ |
| mp-27553 | Ta2SnO7 | C2/c | 0.184 | 1.481 | +4 | Ta⁵⁺ |
| mp-1226511 | CeSnO4 | R3m | 0.188 | 1.534 | +4 | Ce⁴⁺ |
| mvc-8797 | Ca(SnO2)4 | R3m | 0.19 | 0.209 | +2/+4 | Ca²⁺ |
| mvc-13971 | YSnO3 | P63/mmc | 0.19 | 0 | +2/+4 | Y³⁺ |
| mp-1143317 | Si4SnO10 | P4/ncc | 0.193 | 2.851 | +4 | Si⁴⁺ |
| mvc-4413 | CaSn2O5 | Pmmn | 0.194 | 1.142 | +4 | Ca²⁺ |
| mvc-4868 | CaSnO2 | P1 | 0.194 | 0 | +2 | Ca²⁺ |
| mp-7986 | CaSnO3 | Pm3m | 0.195 | 1.403 | +4 | Ca²⁺ |
| mvc-9617 | Ca(SnO2)2 | R3m | 0.198 | 0 | +2/+4 | Ca²⁺ |
| mvc-2430 | ZnSnO2 | P1 | 0.2 | 1.154 | +2 | Zn²⁺ |
| mvc-15767 | YSnO3 | P21/c | 0.2 | 2.097 | +2/+4 | Y³⁺ |
| mvc-2446 | MgSnO2 | P1 | 0.202 | 1.081 | +2 | Mg²⁺ |
| mvc-8773 | Mg(SnO2)4 | R3m | 0.206 | 0.509 | +2/+4 | Mg²⁺ |
| mvc-10473 | MgSn4O9 | P4/n | 0.207 | 0.761 | +4 | Mg²⁺ |
| mvc-8978 | MgSn3O7 | Pnma | 0.207 | 0.881 | +4 | Mg²⁺ |
| mvc-2292 | CaSn5O7 | Cmcm | 0.21 | 0 | +2/+4 | Ca²⁺ |
| mvc-8750 | Zn(SnO2)4 | R3m | 0.214 | 0.441 | +2/+4 | Zn²⁺ |
| mvc-9600 | Zn(SnO2)2 | R3m | 0.217 | 0.019 | +2/+4 | Zn²⁺ |
| mp-505802 | Sn(Mo2O3)2 | P4/mbm | 0.222 | 0.019 | +4 | Mo²⁺ |
| mvc-16404 | Ca(SnO2)2 | Imma | 0.224 | 0.907 | +2/+4 | Ca²⁺ |
| mp-1179348 | SnPO4 | P21/c | 0.225 | 0 | +2/+4 | P⁵⁺ |
| mvc-2447 | CaSnO₂ | P1 | 0.226 | 1.651 | +2 | Ca²⁺ |
| mvc-16313 | ZnSnO₂ | P1 | 0.227 | 0 | +2 | Zn²⁺ |
| mvc-9750 | Mg(SnO2)2 | Cm | 0.228 | 0.095 | +2/+4 | Mg²⁺ |
| mvc-2063 | Ca2Sn9O13 | C2/m | 0.229 | 0 | +2/+4 | Ca²⁺ |
| mvc-9774 | Zn(SnO2)2 | P3m1 | 0.229 | 0 | +2/+4 | Zn²⁺ |
| mp-14695 | SnMo5O8 | P21/c | 0.231 | 0.97 | +4 | Mo⁺⁶ |
| mvc-8976 | ZnSn3O7 | Pnma | 0.236 | 0.573 | +4 | Zn²⁺ |
| mvc-3876 | AlSnO3 | P21/c | 0.236 | 2.231 | +2/+4 | Al³⁺ |
| mvc-9559 | Mg(SnO2)2 | R3m | 0.236 | 0 | +2/+4 | Mg²⁺ |
| mvc-16236 | Zn(SnO2)2 | R3m | 0.24 | 0 | +2/+4 | Zn²⁺ |
| mp-1179370 | SnAsO4 | P21/c | 0.241 | 0 | +4 | As⁵⁺ |
| mvc-133 | MgSnO₂ | P1 | 0.244 | 1.029 | +2 | Mg²⁺ |
| mvc-9533 | Zn(SnO2)2 | Cm | 0.245 | 0 | +2/+4 | Zn²⁺ |
| mvc-10474 | ZnSn4O9 | P4/n | 0.246 | 0.388 | +4 | Zn²⁺ |
| mvc-1192 | Ba2Sn3O7 | Pmmm | 0.249 | 0 | +2/+4 | Ba²⁺ |
| mvc-6814 | Zn(SnO2)2 | Pc | 0.253 | 1.195 | +2/+4 | Zn²⁺ |
| mp-35718 | Ta4SnO12 | Im3m | 0.254 | 0 | +4 | Ta⁵⁺ |
| mp-1209694 | SnAs2O9 | P21/c | 0.257 | 0 | +4 | As⁵⁺ |
| mvc-4668 | CaSnO2 | P1 | 0.263 | 0.581 | +2 | Ca²⁺ |
| mvc-4767 | MgSnO2 | P1 | 0.263 | 0.944 | +2 | Mg²⁺ |
| mp-984745 | CsSnO3 | Pm3m | 0.264 | 0 | +4 | Cs⁺ |
| mvc-7286 | Zn(SnO2)2 | P1 | 0.267 | 0 | +2/+4 | Zn²⁺ |
| mp-1207852 | VSnO3 | Pnma | 0.268 | 0 | +4 | V²⁺ |
| mvc-9524 | Mg(SnO2)2 | Cm | 0.27 | 0 | +2/+4 | Mg²⁺ |
| mp-1244565 | CaSn2O5 | Cmcm | 0.271 | 0.353 | +4 | Ca²⁺ |
| mp-1192950 | Rb2SnO12 | P3c1 | 0.273 | 0 | +4 | Rb⁺ |
| mp-1187065 | SnGeO3 | Pm3m | 0.274 | 0 | +2 | Ge⁴⁺ |
| mvc-6019 | Zn(SnO2)2 | C2/m | 0.274 | 0 | +2/+4 | Zn²⁺ |
| mvc-4769 | ZnSn2O5 | P1 | 0.275 | 0.838 | +4 | Zn²⁺ |
| mp-1190954 | SnP2O9 | C2/c | 0.275 | 0.703 | +4 | P⁵⁺ |
| mp-1179547 | Sn7(SO10)2 | Pbca | 0.276 | 1.562 | +4 | S⁶⁺ |
| mvc-2305 | ZnSn5O7 | Cmcm | 0.281 | 0 | +2/+4 | Zn²⁺ |
| mvc-6074 | Ca(SnO2)2 | Cmcm | 0.281 | 0 | +2/+4 | Ca²⁺ |
| mp-1180275 | Na2SnO6 | C2/m | 0.283 | 0 | +4 | Na⁺ |
| mp-672986 | SnPO4 | P21/c | 0.285 | 0 | +2/+4 | P⁵⁺ |
| mvc-5993 | Mg(SnO2)2 | Imma | 0.291 | 0.196 | +2/+4 | Mg²⁺ |
| mvc-5491 | Mg(SnO2)2 | C2/m | 0.292 | 0.368 | +2/+4 | Mg²⁺ |
| mp-1209319 | SnP2O9 | P21/c | 0.298 | 0.025 | +4 | P⁵⁺ |
| mvc-3827 | Zn2Sn2O5 | Pmc21 | 0.301 | 0 | +2/+4 | Zn²⁺ |
| mvc-16406 | CaSnO2 | P1 | 0.306 | 1.828 | +2 | Ca²⁺ |
| mvc-404 | Ca(Sn2O3)2 | Cmcm | 0.306 | 0 | +2/+4 | Ca²⁺ |
| mvc-4689 | Zn(SnO2)2 | Fd3m | 0.308 | 0 | +2/+4 | Zn²⁺ |
| mp-1095139 | SnPO3 | Cc | 0.31 | 0.519 | +2/+4 | P⁵⁺ |
| mvc-4425 | MgSn2O5 | P2/c | 0.312 | 1.061 | +4 | Mg²⁺ |
| mvc-4706 | Ca(SnO2)2 | Fd3m | 0.313 | 0 | +2/+4 | Ca²⁺ |
| mp-8074 | TaSnO3 | Pm3m | 0.323 | 0 | +4 | Ta²⁺ |
| mp-863767 | Fe13(SnO10)2 | P1 | 0.324 | 0.928 | +4 | Fe²⁺ |
| mp-1187400 | TcSnO3 | Pm3m | 0.331 | 0 | +2 | Tc⁴⁺ |
| mvc-10669 | Mg(SnO2)4 | Cm | 0.336 | 0 | +2/+4 | Mg²⁺ |
| mp-1016837 | SnHgO3 | Pm3m | 0.337 | 0 | +4 | Hg²⁺ |
| mvc-600 | Ba(SnO2)4 | P31m | 0.341 | 0 | +2/+4 | Ba²⁺ |
| mvc-4659 | Mg(SnO2)2 | Fd3m | 0.344 | 0 | +2/+4 | Mg²⁺ |
| mvc-366 | Zn(Sn2O3)2 | Cmcm | 0.344 | 0.017 | +2/+4 | Zn²⁺ |
| mp-1016881 | CdSnO3 | Pm3m | 0.346 | 0 | +4 | Cd²⁺ |
| mp-1182572 | Ba2SnO16 | P1 | 0.359 | 0 | +4 | Ba²⁺ |
| mp-1142770 | SiSnO4 | Ia3d | 0.36 | 2.019 | +4 | Si⁴⁺ |
| mvc-4456 | Y(SnO2)2 | I41/a | 0.36 | 0 | +2/+4 | Y³⁺ |
| mvc-4299 | Al(SnO2)2 | R3m | 0.378 | 0 | +2/+4 | Al³⁺ |
| mp-1179438 | SnAs2O9 | P21/c | 0.383 | 0.677 | +4 | As⁵⁺ |
| mvc-6087 | Zn(SnO2)2 | Cmcm | 0.394 | 0 | +2/+4 | Zn²⁺ |
| mvc-6035 | Mg(SnO2)2 | Cmcm | 0.396 | 0 | +2/+4 | Mg²⁺ |
| mvc-5733 | Zn(SnO2)2 | Pnma | 0.399 | 0 | +2/+4 | Zn²⁺ |
| mvc-1208 | BaSn4O7 | P63mc | 0.414 | 0.065 | +2/+4 | Ba²⁺ |
| mvc-3800 | Mg2Sn2O5 | Pbam | 0.414 | 1.517 | +2/+4 | Mg²⁺ |
| mp-1255006 | Al(SnO2)2 | Fd3m | 0.426 | 0 | +2/+4 | Al³⁺ |
| mp-1248301 | AlSnO3 | P63cm | 0.43 | 0 | +2/+4 | Al³⁺ |
| mvc-4120 | Y(SnO2)2 | R3m | 0.455 | 1.515 | +2/+4 | Y³⁺ |
| mp-978493 | SiSnO3 | Pm3m | 0.487 | 1.777 | +2 | Si⁴⁺ |
| mvc-4453 | Al(SnO2)2 | C2/c | 0.491 | 0 | +2/+4 | Al³⁺ |
| mp-1079820 | K2SnO6 | R3 | 0.492 | 0.184 | +4 | K⁺ |
| mp-1179519 | Sn2C14O3 | P21/c | 0.498 | 1.624 | +4 | Cl⁻ |
| mp-1180644 | Li2SnO6 | P21/c | 0.504 | 0.487 | +4 | Li⁺ |
| mp-1185122 | LaSnO3 | Pm3m | 0.533 | 0 | +2/+4 | La³⁺ |
| mp-1260244 | Al2Sn2O7 | Fd3m | 0.546 | 1.348 | +4 | Al³⁺ |
| mp-1086677 | Na2SnO6 | R3 | 0.565 | 0 | +4 | Na⁺ |
| mp-34910 | Nd2Sn2O7 | Fd3m | 0.572 | 0 | +4 | Nd³⁺ |
| mp-1184243 | GaSnO3 | Pm3m | 0.575 | 0 | +2/+4 | Ga³⁺ |
| mp-1179419 | Sn(ClO)2 | P21/c | 0.592 | 0.233 | +4 | Cl⁻ |
| mp-1181801 | CuSnO6 | Pnn2 | 0.601 | 0 | +4 | Cu²⁺ |
| mp-1202466 | CuSnO6 | P42/nnm | 0.607 | 0 | +4 | Cu²⁺ |
| mp-1188358 | Sn(ClO)2 | P21/c | 0.609 | 0.831 | +4 | Cl⁻ |
| mp-1213499 | CuSnO12 | P42/nnm | 0.611 | 0.016 | +4 | Cu²⁺ |
| mp-1190009 | Sn(ClO)2 | P21/c | 0.614 | 0.993 | +4 | Cl⁻ |
| mp-1016820 | MgSnO3 | Pm3m | 0.629 | 0.845 | +4 | Mg²⁺ |
| mp-1197571 | SnCl3O4 | P21/c | 0.639 | 1.201 | +4 | Cl⁻ |
| mp-1179400 | SnCl3O4 | P21/c | 0.644 | 0.789 | +4 | Cl⁻ |
| mvc-15937 | AlSnO3 | P63/mmc | 0.658 | 0 | +2/+4 | Al³⁺ |
| mp-981376 | ScSnO3 | Pm3m | 0.672 | 0 | +2/+4 | Sc³⁺ |
| mp-1183692 | CoSnO3 | Pm3m | 0.685 | 0 | +4 | Co²⁺ |
| mp-1201737 | CaSnO6 | Pn3 | 0.69 | 0.507 | +4 | Ca²⁺ |
| mp-1016902 | ZnSnO3 | Pm3m | 0.713 | 0 | +4 | Zn²⁺ |
| mp-1180444 | MgSnO6 | Fm3m | 0.726 | 0 | +4 | Mg²⁺ |
| mp-1197808 | CaSnO6 | Pn3m | 0.759 | 0 | +4 | Ca²⁺ |
| mp-1182179 | CaSnO6 | Fm3m | 0.763 | 0 | +4 | Ca²⁺ |
| mp-1207083 | FeSnO3 | Pm3m | 0.772 | 0 | +4 | Fe²⁺ |
| mp-1202032 | FeSnO6 | Pn3 | 0.79 | 0.718 | +4 | Fe⁺ |
| mvc-15474 | YSnO3 | Pm3m | 0.809 | 0 | +2/+4 | Y³⁺ |
| mp-1186346 | NpSnO3 | Pm3m | 0.84 | 0 | +4 | Np²⁺ |
| mp-1184153 | DySnO3 | Pm3m | 0.849 | 0 | +2/+4 | Dy³⁺ |
| mp-973977 | HoSnO3 | Pm3m | 0.869 | 0 | +2/+4 | Ho³⁺ |
| mp-1188562 | SnCl4O5 | C2/c | 0.882 | 0.704 | +4 | Cl⁻ |
| mp-1197322 | FeSnO6 | Fm3m | 0.9 | 0 | +4 | Fe⁺ |
| mp-972442 | SnBO3 | Pm3m | 1.125 | 0 | +2/+4 | B³⁺ |
| mp-1202685 | Sn(C0)4 | Iba2 | 1.305 | 0.903 | +4 | C^{2+/0} |
| mvc-11052 | AlSnO3 | Pm3m | 1.317 | 0 | +2/+4 | Al³⁺ |
| mp-546910 | CaSnO3 | Pm3m | 1.435 | 0 | +4 | Ca²⁺ |

DFT calculations were performed by using Vienna ab initio Simulation Package (VASP)^{17, 18} with projected augmented wave (PAW)^{19, 20} pseudopotentials. Perdew-Burke-Ernzerhof generalized gradient approximation (GGA-PBE) functional was employed to depict the exchange-correlation potential energy. For all calculations, an energy cutoff of 520 eV was adopted for plane wave basis expansion. Brillouin-zone integrations were performed based on the Gamma-centered Monkhorst-Pack k-point mesh, with sampling density varying with lattice constants to ensure the desired accuracy. Atomic structures were relaxed using conjugate gradient (CG) method with the convergence criterion of the force on each atom less than 0.02 eV/Å. The converged energy criterion is 10⁻⁵ eV for electronic minimization.

Effective masses were evaluated based on the second derivative of energy versus wavenumber k along three principle directions from the DFT-GGA band structures. The mobility μ is connected to the effective mass m* through μ=eτ/m* where τ is the relaxation time and determined by various scattering mechanisms combined. In this work, we only took into account the phonon scatterings, which determines the intrinsic mobilities of materials and provides the upper limits of the real mobilities for their device applications. Details of the relaxation time computation method and phonon-limited mobility evaluation model used in this example can be found in our previous studies.²¹

### Results

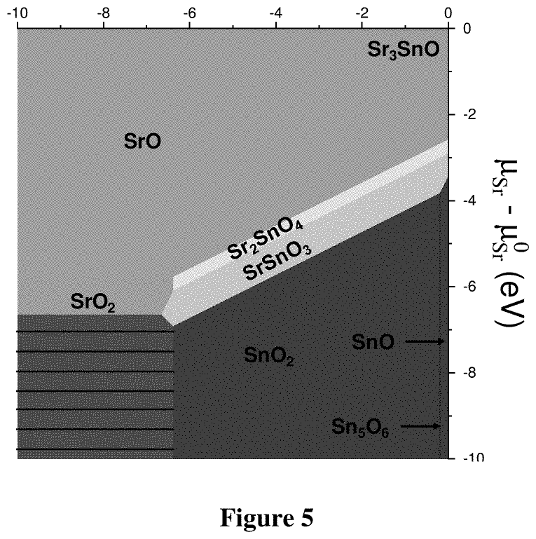

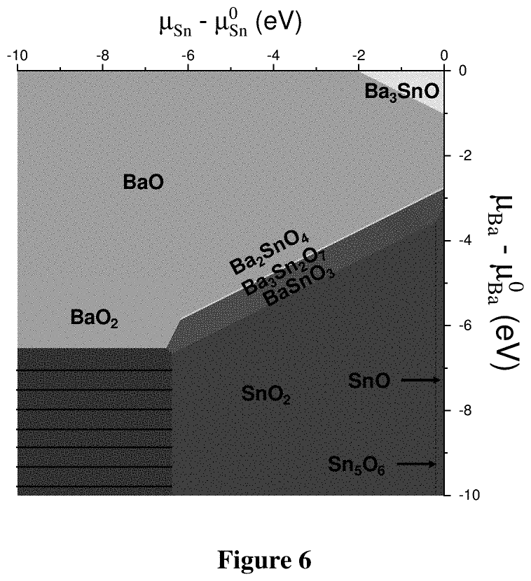

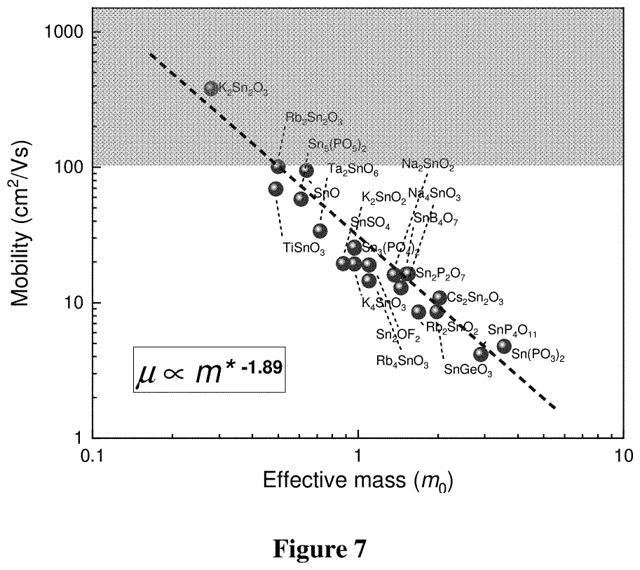

Equipped with the screening criteria outlined in the previous section, we have identified 15 potential Sn²⁺-containing p-type Sn—O—X ternary oxides. They are listed in Table 6, together with their space group, Materials project ID, band gap, hole effective mass, and hole carrier mobility. The mobility is a tensor, and here we focus on the three diagonal values of the mobility tensor and sort the materials based on the highest value of the three principal hole mobilities. From Table 6 we can see that K₂Sn₂O₃, Rb₂Sn₂O₃, and TiSnO₃ are the three most promising candidates, as they offer high hole mobilities larger than or close to 100 cm²/Vs. The cubic phase K₂Sn₂O₃ presents a remarkably low hole effective mass and an ultra-high p-type mobility, well agreeing with a recent work by Ha et al.¹⁰ It is noted that in their work, rhombohedral phase K₂Sn₂O₃ was also predicted to show decent effective masses at 0.23-0.43 m₀. However, the rhombohedral polymorph is screened out in our searching process due to its unfavorable formation energy. It is interesting to note that although sharing the similar chemical characteristics with K, Rb, and Cs, the light elements Li, Na in group I alkali metals do not enter our p-type oxide candidate list because of less favorable formation energies. This trend suggests that a more electropositive X element would be favorable to stabilize Sn—O—X compounds. We should mention that the alkaline-earth metal based Sn²⁺ oxides have previously been studied for p-type conductors,¹¹ but none of them are stable in our formation energy evaluation (see FIG. 5 and FIG. 6). Continuing to explore the list of materials we identified a new candidate TiSnO₃, which has not been investigated as a p-type oxide. TiSnO₃ occurs in two distinct polymorphs of perovskite and ilmenite structures. Perovskite TiSnO₃ has been previously proposed as a good Pb-free ferroelectric but was found less stable than the ilmenite phase.²² The ilmenite TiSnO₃, as predicted by our identification approach, presents satisfactory hole mobilities as well as good thermodynamic stability (discussed below). The Sn—O—Ta compound Ta₂SnO₆, which was identified in our previous work²¹, also offers a competitive effective mass and hole mobility. It is noted that another Sn²⁺ based Sn—O—Ta ternary oxide Ta₂Sn₂O₇ has recently been investigated as a p-type oxide for its VBM containing Sn-5s orbital contribution.²³ However, the thermodynamic instability issue of Ta₂Sn₂O₇ lowers its interest for practical applications.²⁴ Sn₅(PO₅)₂ also attracts our attention as it stands out among those non-metal X containing Sn—O—X compounds, providing a good hole carrier mobility of 58 cm²/Vs. Broadly speaking, for Sn²⁺—O—X ternary oxides, the metal X elements are more favorable than the non-mental X elements, as the former generally gives lower effective masses and higher hole mobilities of the compounds (Table 6 and FIG. 7). One helpful finding from our identified candidates is that the hole mobilities are highly correlated with the hole effective masses: materials with smaller effective masses will generally show higher carrier mobilities. Even though a general inverse correlation between the mobility and effective mass is well known, a quantitative correlation equation has not been derived for p-type oxide semiconductors. A detailed data fitting revels that the hole mobility quite follows the effective mass by a power function with the parameter of −1.9 (FIG. 7). Such a dominant role of effective mass in determining the carrier mobility also rationalize the effective mass as a reliable descriptor for high mobility p-type oxides, which is widely adopted in the previous high-throughput searching works.⁹⁻¹¹ There are, however, also many more compounds beyond Sn²⁺—O—X that exhibit similar, if not even more promising, effective mass values and that have apparently not yet been considered for an application as a p-type oxide. Considering that most p-type oxides are synthesized in amorphous or polycrystal form where the mobilities often reduce by 1˜3 order of magnitude below those of their respective crystalline phases, these candidates may also deserve attention for further studies.

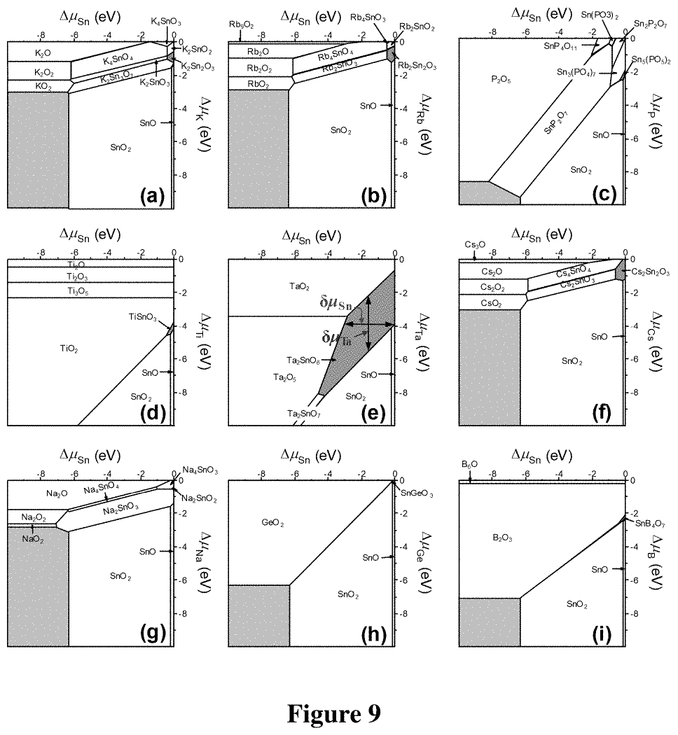

TABLE 6
Summary of the identified Sn²⁺-containing p-type oxides. Chemical formula, Materials Project identification number
(MP-id), space group, crystal system, DFT-GGA level band gap, diagonal components along three principle directions
(x, y, z) of the hole effective mass tensor and the mobility tensor, and the thermodynamic phase stability characterizing
the ease of experimental synthesis are listed. The thermodynamic phase stability is defined as S = min(δμ_{Sn}, δμ_{X}), where
δμ represents the maximum chemical potential range over which the phase is stable (See FIG. 9). For the phase stability,
the limiting element is shown in the parentheses. The materials are sorted based on the highest value (highlighted)
of the three principal hole mobilities. Information about SnO is also included for comparison.

| | | Space | Crystal | Band gap | m* (m₀) | | | Mobility (cm²/Vs) | | | Stability |
|---|---|---|---|---|---|---|---|---|---|---|---|
| Oxides | mp-id | group | system | (eV) | x | y | z | x | y | z | (eV) |
| SnO | mp-2097 | P4/nmm | tetragonal | 0.7 | 2.98 | 2.98 | 0.64 | 9.4 | 9.4 | 94.4 | 0.18 (Sn) |
| K₂Sn₂O₃ | mp-8624 | I2₁3 | cubic | 1.9 | 0.28 | 0.28 | 0.28 | 380 | 380 | 380 | 0.48 (Sn) |
| Rb₂Sn₂O₃ | mp-540796 | R3m | trigonal | 1.2 | 0.64 | 0.53 | 0.50 | 69.7 | 92.5 | 100.9 | 0.50 (Sn) |
| TiSnO₃ | mp-754246 | R3 | trigonal | 2.4 | 0.49 | 0.51 | 0.51 | 68.9 | 64.8 | 64.8 | 0.24 (Sn) |
| Sn₅(PO₅)₂ | mp-560715 | P1 | triclinic | 2.8 | 0.61 | 15.34 | 4.85 | 58.0 | 0.46 | 2.59 | 0.16 (Sn) |
| Ta₂SnO₆ | mp-556489 | Cc | monoclinic | 2.3 | 8.4 | 0.72 | 0.98 | 0.9 | 33.8 | 21.3 | 2.80 (Sn) |
| K₂SnO₂ | mp-752692 | P1 | triclinic | 1.5 | 2.13 | 3.00 | 0.97 | 7.89 | 4.72 | 25.67 | 0.40 (K) |
| Sn₃(PO4)2 | mp-27493 | P2₁/c | monoclinic | 3.4 | 0.97 | 2.64 | 0.93 | 25.2 | 5.61 | 0.19 | 0.82 (Sn) |
| SnSO₄ | mp-542967 | Pnma | orthorhombic | 3.9 | 0.88 | 5.16 | 1.39 | 19.43 | 1.37 | 9.79 | 0.18 (Sn) |
| K₄SnO₃ | mp-14988 | Pbca | orthorhombic | 2.2 | 2.43 | 7.81 | 0.97 | 4.86 | 0.84 | 19.28 | 0.34 (K) |
| Sn₂OF₂ | mp-27480 | C2/m | monoclinic | 2.3 | 3.78 | 2.23 | 1.10 | 2.98 | 6.57 | 18.97 | 0.52 (F) |
| Sn₂P₂O₇ | mp-554022 | P1 | triclinic | 2.3 | 2.78 | 1.55 | 15.14 | 6.78 | 16.3 | 0.53 | 0.59 (Sn) |
| SnB₄O₇ | mp-13252 | Pmn2₁ | orthorhombic | 3.6 | 1.53 | 1.52 | 1.83 | 16.1 | 16.3 | 12.3 | 0.16 (Sn) |
| Na₂SnO₂ | mp-778057 | Pbcn | orthorhombic | 2.1 | 1.37 | 1.42 | 1.54 | 16.05 | 15.21 | 13.47 | 0.10 (Sn) |
| Rb₄SnO₃ | mp-756570 | Cc | monoclinic | 1.6 | 21.78 | 1.10 | 4.02 | 0.17 | 14.50 | 2.15 | 0.07 (Rb) |
| Na₄SnO₃ | mp-28261 | Cc | monoclinic | 1.9 | 3.98 | 1.45 | 2.26 | 2.84 | 12.90 | 6.63 | 0.49 (Na) |
| Cs₂Sn₂O₃ | mp-7863 | Pnma | orthorhombic | 2.5 | 8.64 | >10 | 2.03 | 1.23 | <1 | 10.8 | 0.60 (Sn) |
| Rb₂SnO₂ | mp-27931 | P2₁2₁2₁ | orthorhombic | 2.2 | 1.69 | 1.78 | 2.46 | 8.54 | 7.90 | 4.86 | 0.38 (Rb) |
| SnGeO₃ | mp-769144 | P2/c | monoclinic | 2.0 | 5.92 | 3.00 | 1.98 | 1.65 | 4.58 | 8.55 | 0.07 (Sn) |
| SnP₄O₁₁ | mp-767114 | P2₁/c | monoclinic | 4.5 | 3.84 | 2.90 | 3.66 | 2.72 | 4.15 | 2.93 | 0.77 (P) |
| Sn(PO₃)₂ | mp-766947 | Pbca | orthorhombic | 3.8 | 4.64 | 24.33 | 3.55 | 3.18 | 0.26 | 4.75 | 0.30 (Sn) |
| Sn₂(SO₄)₃ | mp-768950 | R3 | trigonal | 2.8 | 23.18 | 15.24 | 73.14 | <1 | <1 | <1 | 0.68 (Sn) |

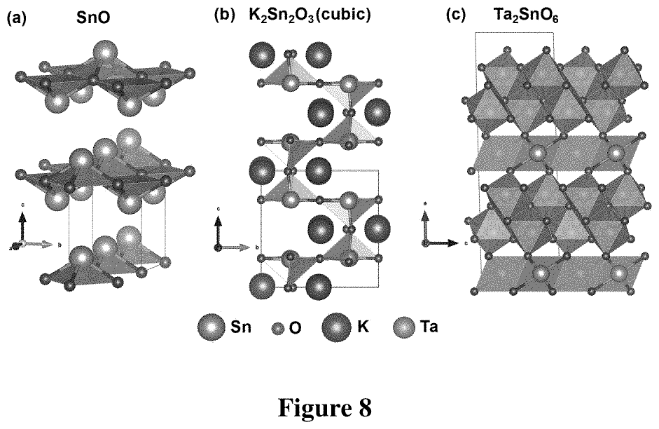

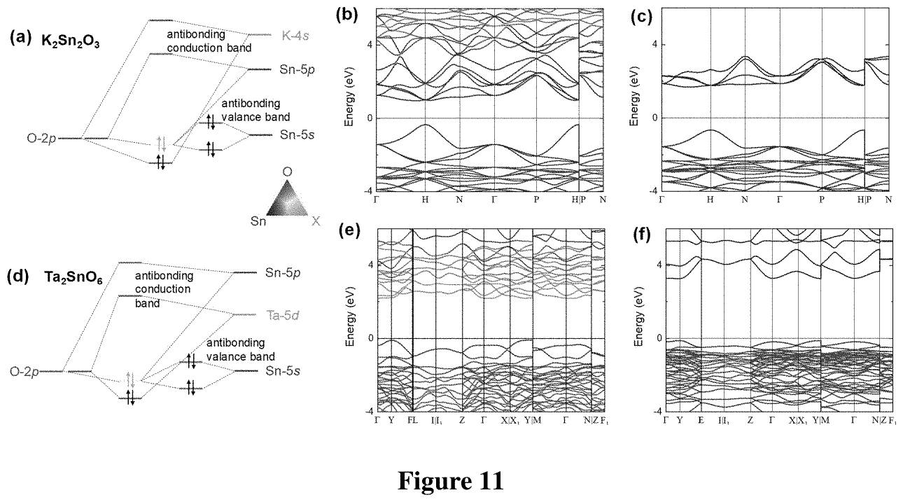

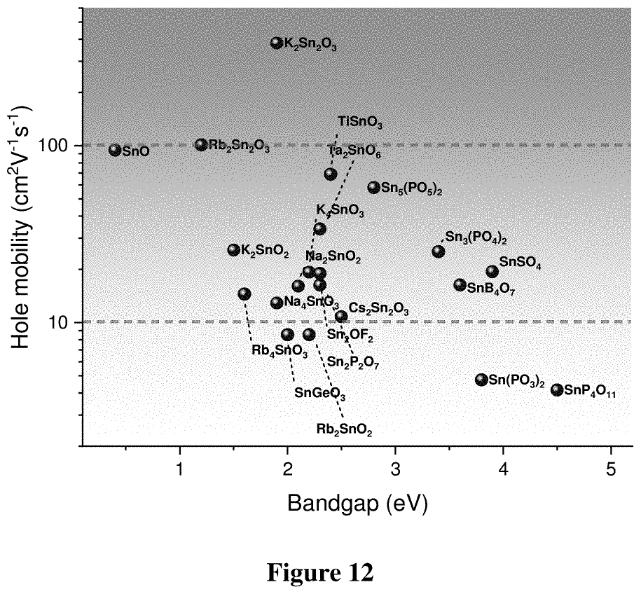

It is noted that although all these identified Sn—O—X compounds contain Sn²⁺ oxidation state, their effective masses (and corresponding hole carrier mobilities) vary in a wide range from 1.98 m₀ in SnGeO₃ to 0.28 m₀ in K₂Sn₂O₃. This variation points to that the Sn²⁺ is not sufficient condition for a low effective hole mass. From the tight-binding electronic structure point of view, the effective mass is determined by the orbital overlapping between neighboring atoms. Larger overlapping leads to a lower effective mass. Therefore, any factors such as atomic arrangements and orbital characteristics that facilitate the orbital overlapping will result in smaller effective masses. For example, SnO has a layered structure with each layer consisting of a network of SnO₄ polyhedra linked together by corner-sharing of O atoms (panel (a), FIG. 8). The spatially extended and spherically symmetric Sn 5s orbital wavefunctions in SnO favor the larger intraplane Sn—Sn and interplane Sn—O—Sn orbital overlapping at VBM throughout the entire network of SnO₄ polyhedra, thus leading to small hole effective mass. It is worthwhile to note that the VBM states of SnO are contributed by Sn s orbitals and O p_{z} orbitals. The O p_{z} orbitals are almost orthogonal to Sn s orbitals in the plane leading to small overlap matrix and the correspondingly large in-plane effective mass values. Along the vertical direction, Sn s-orbital and O p_{z}-orbital as well as interlayer Sn s-orbital overlaps are large so that the out-of-plane effective mass is significantly smaller with large hole mobility. Stoichiometrically, the Sn—O—X ternary compounds are equivalent to SnO+XₓO_{y}, where XₓO_{y} stands for the oxide of the third element. For example, the Sn—O—Ta system Ta₂SnO₆ is corresponding to SnO+Ta₂O₅. Regarding the crystal structure, the identified Sn—O—X compounds can be classified into two groups. In the first group, the linked SnOₓ polyhedra constitutes the structural motif of Sn—O—X, while metallic X donate electrons to the SnOₓ network and stabilize the lattice via Madelung potential.¹¹ In this group X are highly electropositive alkali metals K and Rb. Panel (b) of FIG. 8 shows the structure of K₂Sn₂O₃ illustrating how SnOₓ polyhedra form the framework of Sn—O—X while K cations disperse between SnOₓ polyhedra. The insertion of X atoms does not interrupt the interconnection of SnOₓ polyhedra so they remain a continuous network in three dimension (3D). Such kind of structure is called Zintl phase²⁵ where the electronic transport properties of Sn²⁺—O—X compounds would be dominated by the SnOₓ network. As a result, this group of Sn²⁺—O—X oxides generally present small effective masses and high hole mobilities because of the Sn²⁺ electronic nature. It is worthwhile to mention that not all the alkaline metal-Sn²⁺ oxides display such Zintl phase behavior, and for example, K₄SnO₃ and Rb₄SnO₃ can be classified into the next group. In the second group, Sn²⁺—O—X atomic structure consists of a network of SnOₓ polyhedra with alternating XOₓ polyhedra. The SnOₓ polyhedra in this group are thus not continuously connected in 3D but instead separated by the XOₓ polyhedra. Compounds with transition metals Ta, Ti, and nonmetals Ge, P, fall into this group. Panel (c) of FIG. 8 shows the structure of Ta₂SnO₆ illustrating how SnO₄ and TaO₆ polyhedra are spatially distributed in alternating layers. The interruption of the continuity of SnOₓ network by the XOₓ polyhedra undermines the Sn—O—Sn orbital overlapping in vertical direction. Since most oxides including the aforementioned XOₓ have the localized oxygen p orbital states as their valence bands, the second group Sn²⁺—O—X tend to exhibit flat valence band edges and comparatively large hole effective masses along the vertical direction of alternating SnOₓ/XOₓ layers. Furthermore, electronic structure analysis shows that the VBM states in Sn²⁺—O—X compounds mainly comprise of Sn s-orbital and O p-orbital with X making a negligible contribution (FIG. 11). This orbital contribution analysis shows that for the VBM states, there is marginal orbital or wavefunction overlapping at the Sn—O/X—O interlayer boundaries as well as within the X—O network. Viewing the electron transport as a wave propagation, it is reasonable to argue that the X—O network will impede the electron wave from further propagating whenever electrons in the lattice travel across the X—O layer. The resultant immobility of carriers in this group of Sn²⁺—O—X compounds is characterized by their large effective mass. The transition-metal and non-metal based Sn²⁺ oxides belong to this group and exhibit the effective masses falling into the middle to lower range of the broad effective mass spectrum (see FIG. 12).

As stated previously, a high-performance p-type oxide require not only high hole mobility, but also robust phase stability. The thermodynamic stability is closely related to experimental growth so that a large phase stability region in the chemical potential map indicates experimental ease of synthesis. To examine the phase stability, we performed a thorough quantitative evaluation of the phase stability diagram analysis for the 15 identified Sn—O—X compounds, which account for various combinations of the competing phases including all the existing binary and ternary compounds from the Materials Project. During practical materials growth, a thermodynamically stable Sn—O—X phase with the chemical formula XₕSnⱼOₖ requires the following three conditions to be satisfied:

hΔμ_{X}+jΔμ_{Sn}+kΔμ_{O}=E_{f}(XₕSnⱼOₖ) (17)

Δμᵢ≤0(i=X,Sn,O) (18)

hₗΔμ_{X}+jₗΔμ_{Sn}+kₗΔμ_{O}≤E_{f}(Xₕ_{ₗ}Snⱼ_{ₗ}Oₖ_{ₗ}), l=1 . . . N (19)

where Δμᵢ=μᵢ−μᵢ⁰ is the relative chemical potential of atomic specie i during growth (μᵢ) to that of its elemental bulk phase (μᵢ⁰), E_{f} is formation energy relative to the elemental phases, Xₕ_{ₗ}Snⱼ_{ₗ}Oₖ_{ₗ} represents all the existing competing phases identified from the Materials Project (with the total number of N). Here, Eq. (1) is condition for thermodynamic equilibrium, Eq. (2) is to prevent atomic species from precipitating to elemental phases, and Eq. (3) is to ensure the phase at consideration is thermodynamically favorable over other competing phases. Eq. (1) determines only two Δμᵢ are independent. Solutions to this group of equations, i.e., the ranges of Δμᵢ that stabilize XₕSnⱼOₖ are bound in a polyhedron in the two-dimensional space with two Δμᵢ as variables. Choosing Δμ_{X} and Δμ_{Sn} as the independent variables, we can plot the phase diagrams of Sn—O—X ternary compounds in a Sn—X chemical potential map. FIG. 9 depicts the phase diagram of most promising Sn—O—X compounds.

From FIG. 9, it can be seen that in the Sn—O—X ternary phase diagrams, the identified Sn²⁺—O—X compounds all occupy an insignificant area in the Sn—X chemical potential maps, except Ta₂SnO₆ which presents an exceptionally sizable phase region. Such a marginal phase stability in Sn²⁺—O—X compounds points to their thermodynamic unfavourability towards other competing phases with varying chemical potentials, as noted for the corresponding binary oxides which remain stable over a wide range of Sn—X chemical potentials. One common feature among these Sn—O—X phase diagrams is that SnO exhibits a very small stability region width, which indicates its marginal stability against its two bordered competing phases Sn and SnO₂. This feature explains the experimental observation that in SnO films there are a certain amount of metallic Sn and SnO₂ phase present.⁶ The inferior Sn²⁺ valence stability is the fundamental origin of low phase stability of Sn²⁺—O—X p-type oxides. Sn²⁺—O—X under thermodynamically unfavorable conditions might degrade and transform into more stable phases, which would cause the device instability and contamination issue. The undesirable phase stability among Sn²⁺—O—X compounds also suggests a synthesis challenging. The elemental chemical potentials reflect their atomic concentrations during the growth, which is experimentally governed by gas flow rate, partial pressure, temperature, etc. Therefore, a tiny phase region over limited chemical potential ranges corresponds to a narrow growth condition window which is often quite demanding to access and optimize. It is intuitive to gauge the thermodynamic stability based on the area size of stable region in the Sn—X chemical potential space. However, it should be noted that the ease of synthesis, i.e., accessing the growth condition, is determined by the smaller one of the Sn and X potential ranges, since the synthesizing condition for the element with narrower potential range is more challenging to approach. Given this, we can define the thermodynamic phase stability as S=min(δμ_{Sn},δμ_{X}), where Δμ represents the maximum chemical potential range across the phase region. Panel (e) of FIG. 9 shows our definition of stability S. Under such definition, Table 6 lists the stability of Sn²⁺—O—X compounds, with the limiting elements also indicated. In FIG. 9 and Table 6, the marginal phase stabilities of alkali metal Sn²⁺ oxides K₂Sn₂O₃ and Rb₂Sn₂O₃ counteract their high hole mobilities and lower their interest for technological applications, whereas thermodynamically more competitive Ta₂SnO₆ reinforce its promise despite its comparatively low hole mobility. In fact, as mentioned in the introduction section, there is generally a trade-off between mobility and phase stability. Among the identified high-mobility Sn²⁺ based p-type ternary oxides, Ta₂SnO₆ balances the carrier mobility and phase stability achieving an overall optimal performance. Because of this, we recommend Ta₂SnO₆ is the initial practical Sn²⁺ based p-type oxides for vertical CMOS application.

The phase diagram predicted here further provide useful guide for experimental efforts to optimize synthesis approaches for Sn—O—X compounds. From FIG. 9, it can be seen that a common feature between these Sn—O—X ternary phase diagrams is that the identified Sn²⁺—O—X p-type oxides are exclusively located to the right region of Sn—X chemical potential maps. Thermodynamically, higher Sn chemical potential represents Sn-rich condition and corresponding less oxygen partial pressure, which reveals that Sn²⁺—O—X p-type oxides should be synthesized at Sn-rich and reducing environment. This can be understood since the reduced Sn²⁺ in Sn²⁺—O—X phase can readily be oxidized to Sn⁴⁺ chemical state under oxygen rich environment. This finding agrees well with experimental observation that the synthesized p-type SnOₓ films tend to show off-stoichiometry with O/Sn ratio x>1.^{6, 7} Therefore, it is important to note that through incorporating a third element X, most Sn²⁺—O—X ternary compounds can be stabilized over an extended Sn chemical potential region and thus a wider optimum growth windows compared to the binary phase SnO. In terms of growth conditions for X elements, our calculated phase diagrams suggest that these p-type oxides should be grown in X-rich or intermediate rich environment since they are distributed within the high or middle X chemical potential regions.

### Discussion

With hole mobility and phase stability as the screening descriptors, our searching approach has led to the identification of several high figure-of-merit existing Sn²⁺ based p-type ternary oxides including K₂Sn₂O₃, Rb₂Sn₂O₃, TiSnO₃, Ta₂SnO₆, and Sn₅(PO₅)₂, with Ta₂SnO₆ providing the best performance balancing the carrier mobility and phase stability. We thus propose Ta₂SnO₆ as the initial promising candidate for further experimental realization. Currently, the experimental research on synthesis of Ta₂SnO₆ by atomic layer deposition (ALD) and molecular beam epitaxy (MBE) as well as related characterization works are ongoing. The identified p-type oxides exhibit wide band gaps ranging from 1.2 eV to 2.8 eV, high hole mobility higher or close to 100 cm²/Vs, and moderate phase stability, which are all favorable for the applications in BEOL transistor channel materials. Since DFT generally underestimates the band gap, we expect that their experimental band gaps would be somewhat higher than our predictions. It should be mention that due to the low-temperature synthesis in BEOL process, p-type oxides would preferably assume nanocrystal or amorphous phase. Therefore, the crystalline-phase intrinsic mobilities predicted here would provide an upper limit to the actual values in their practical devices.

The above identification process shows that by carefully selecting suitable the X element, we can transform the narrow gaped and less stable SnO binary phase into wide gaped, robust and high mobility Sn²⁺—O—X ternary compounds. Until now it is not clear how X insertion alters the electronic band structure and modulates the thermodynamic properties of SnO. In the following part, we will examine and unveil the underlying mechanisms of how introducing X widens the band gap and enhancing the phase stability. We will particularly focus on Ta₂SnO₆ since it stands out in terms of thermodynamic stability.

Wide band gaps of p-type oxides are critically important as they ensure the low off-state current leakage in BEOL vertical CMOS. It is noted that all identified Sn²⁺—O—X p-type oxides exhibit significantly wider band gap than binary SnO. For Sn—O—X ternary compounds, their band gaps can be viewed as a result from tuning the band gap of SnO by introducing a third element X.

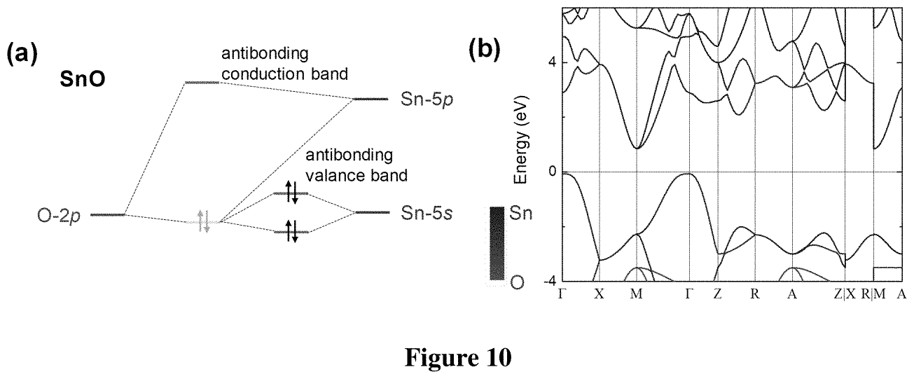

To develop a deep understanding on the bandgap tuning effect by X, we first identify the key features of the band structure of binary SnO. From a molecular orbital point of view, when Sn (5s²5 p²) and O (2s²2 p⁴) atoms join together forming the SnO solid, Sn-5p and O-2p orbitals interact and form the bonding state as well as antibonding state (see panel (a) of FIG. 10). The bonding state, largely contributed by O-2p orbital, will be occupied by electrons from both atoms while the higher energy antibonding state, mostly contributed by Sn-5p orbital, remains empty. This is equivalent to the statement that in SnO crystal tin atom has lost its two 5p electrons to oxygen and exhibits the +2 oxidation state. Modern band theory states²⁶ that the medium-range inter-SnO-cell interaction, i.e. Sn-5p/Sn-5p orbital interaction, splits the antibonding molecular level into an energy band, which comprises the conduction band; while the orbital interaction between O-2p/O-2p causes the bonding molecular level splitting into the valance band of SnO. The energy level difference between the bonding and antibonding state would determine the SnO bandgap if no other factors alter this orbital interaction picture. However, it has been shown from DFT calculations^{27 28} that the bonding state resulted from Sn-5p/O-2p charge transfer interaction will further interact with Sn-5s orbital, generating the O-2p/Sn-5s bonding and antibonding states. Since both the individual Sn-5s and O-2p orbitals are fully occupied, their bonding and antibonding orbitals will be occupied and form the valance band (FIG. 10). Because of this interaction, the O-2p/Sn-5s antibonding state becomes the VBM and the bandgap is now determined by the energy difference between Sn-5p/O-2p antibonding orbital and O-2p/Sn-5s antibonding orbital. From the above analysis, we can distill some general bandgap determining factors in oxides which can be divided into (i) constituent atomic orbital energy level difference, (ii) inner-cell atomic orbital overlap (typically heteroatomic) interaction, and (iii) band dispersion due to intercell interaction (typically homoatomic). If the original difference between constituent atomic orbital energy levels are large, and if the inner-cell atomic orbital overlap is strong, the resultant bonding and antibonding state energy separation would be large, which will translate into a wider CBM/VBM energy gap. Similarly, if the band dispersion is weak (molecular energy level splitting is small), the band width would be small and hence the bandgap between bands would be wide. We should mention that among these three factors, the atomic orbital energy level difference depends on the comprising elements, whereas the other two factors, the inner-cell atomic orbital overlap and the band dispersion, are determined by the crystal structure.

A detailed molecular orbital analysis on selected Sn—O—X compounds was then performed to unveil the origin of large bandgaps in Sn—O—X and shed light on the bandgap modulating effect of introducing X. In K₂Sn₂O₃, the electropositive alkali metal K has a small ionization energy, therefore in terms of atomic orbital energy level K-4s should lie above Sn-5p (panel (a) of FIG. 11), which is also evidenced in the K₂Sn₂O₃ orbital projected band structure where K-4s dominated bands stand above Sn-5p dominated bands (panel (b) of FIG. 11). Since K-4s bands enter into the conduction band and do not contribute to the band edges, the bandgap of K₂Sn₂O₃ would be solely determined by the constituent SnO latticework. In Ta₂SnO₆, the comparatively inert transition metal Ta has a higher ionization energy, and correspondingly, Ta-5d atomic orbital level lies below Sn-5p (panel (d) of FIG. 11). This is also verified by the calculated Ta₂SnO₆ orbital resolved band structure where Ta-5d bands lie below Sn-5p bands (panel (e) of FIG. 11). As a result, the Ta-5d bands would take place of Sn-5p bands and form the conduction band edge of Ta₂SnO₆. Intuitively, this would suggest that the Ta₂SnO₆, or the insertion of Ta into SnO, reduces the bandgap of SnO latticework, while K₂Sn₂O₃, or the insertion of K into SnO, does not tailor the bandgap. However, when a third element X is introduced into SnO, it also changes the SnO lattice structure, specifically the chemical bonding environment and the translation symmetry. In view of the bandgap determining factors we have outlined previously, the altered chemical bonding configuration will lead to a different atomic orbital overlap and bonding/antibonding energy separation; while the modified structural translation symmetry will generate different intercell interaction and band dispersion. Both of these two factors contribute to a tuned bandgap from binary SnO. To more concretely illustrate this idea, we have calculated the band structures of K₂Sn₂O₃ and Ta₂SnO₆ but removing the X element out from the Sn—O—X lattice, i.e., the constituent SnO lattice in K₂Sn₂O₃ and Ta₂SnO₆. Panels (c) and (f) of FIG. 11 plot the band structures of K₂SnO₃ and Ta₂SnO₆ without K and Ta, respectively. It can be seen that for K₂Sn₂O₃ system the band edge shapes of SnO latticework without K remain similar to the full K₂Sn₂O₃ band structure, with only slightly reduced band dispersion. This is reasonable since in K₂Sn₂O₃ the K atomic orbitals do not contribute to the band edges. In addition, it is noticeable that the hypothetical SnO latticework without K results in a wider bandgap (˜1.4 eV) when compared with the simple binary phase SnO (˜0.7 eV). This is originated from the different crystal structures between SnO latticework in K₂Sn₂O₃ and binary SnO. In binary SnO, alternating Sn and O atoms consist the square pyramids which are connected by O-corner sharing whereas in K₂Sn₂O₃ each Sn atom is coordinated to 3 oxygen atoms with bond angles approximately at 90° and 180°, respectively. The different bonding coordination and bonding distance results in different inter-cell orbital overlap and band dispersion, which eventually leads to different bandgaps. In contrast, in Ta₂SnO₆ system the conduction band edge shape of SnO latticework without Ta is completely different from that of full Ta₂SnO₆ band structure. This can be explained by the fact that in Ta₂SnO₆ Ta-5d atomic orbital dominates the conduction band edge. When comparing the hypothetical SnO latticework without Ta with binary SnO, it is noticed that SnO latticework without Ta give rise to a significant wide bandgap (˜3.0 eV). A closer examination of the Ta₂SnO₆ crystal structure reveals that Ta₂SnO₆ can be regarded as alternating SnO and Ta₂O₅ layers. The SnO layers in Ta₂SnO₆ are much similar to the SnO layer in binary SnO, with the only difference being the slightly distorted SnO₄ square pyramids in Ta₂SnO₆. Nevertheless, in Ta₂SnO₆ the SnO layers are separated by Ta₂O₅ layers and as a result, the inter-SnO-layer interaction is suppressed by the large space separation. This leads to SnO latticework without Ta presenting a less dispersive band edge and consequently, a wider bandgap than binary SnO, though Ta-5d reduces the bandgap of the hypothetical SnO lattice by forming and lowering the conduction band edge. The above analysis unveils the origin of the large bandgaps in K₂Sn₂O₃ and Ta₂SnO₆ and also sheds light on how introducing X into SnO lattice affects the electronic band structure of SnO.

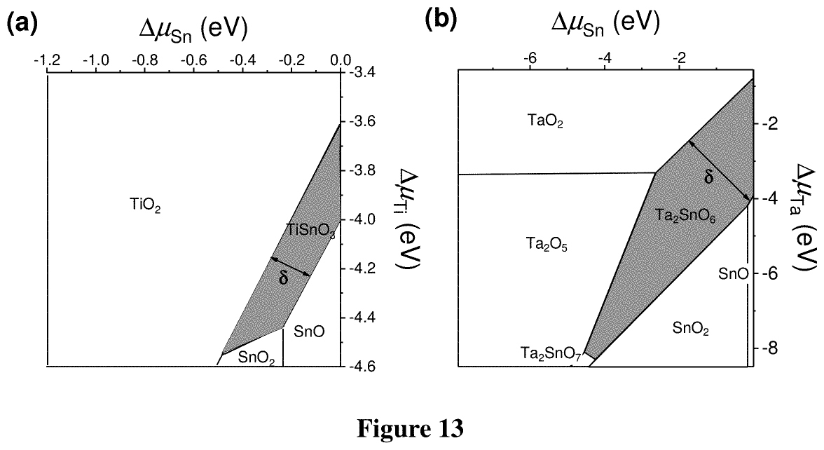

In addition to the wide bandgap, Ta₂SnO₆ also presents a remarkably robust phase stability. Our next consideration therefore comes to the phase stability analysis. Notably, most of Sn²⁺-containing oxides lack a robust thermodynamic stability in the Sn—X chemical potential space, due to the reduced and readily-oxidizable Sn²⁺ 5s² chemistry. Such thermodynamic character inherent from the nature of reduced (n−1)d¹⁰ns² cations is also likely to affect other possible p-type oxide chemistries such as Pb²⁺, Bi³⁺, and Sb³⁺. Nevertheless, Ta₂SnO₆ presents a substantial phase stability over a wide range of its constituent elemental chemical potentials, making it the most favorable Sn²⁺ based p-type oxide in terms of phase stability. Revealing the underlying mechanism will be certainly useful in identifying and designing other possible p-type oxides with robust phase stability. To gain insights on what factors govern the thermodynamic stability, we start from considering the geometric features of Sn²⁺—O—X phase regions on the chemical potential diagram. Fundamentally, a stability region of a phase is the result of competition between this phase and its bordered phases under varying chemical environments. A phase with more negative formation energy will push its bordered phases to the marginal limit and assume larger space in the chemical potential diagram. By analyzing the geometric shape of the stability regions, we have identified two common features among these among Sn²⁺—O—X compounds. The first common feature (except for alkali metals) is that these ternary oxides are parallelly bordered by their constituent binary oxides SnO and XₓO_{y}. Panel (a) of FIG. 13 gives an example of the ternary oxide TiSnO₃ where the phase regions of TiO₂, TiSnO₃, and SnO are parallelly arranged. From a thermochemical point of view, this parallel arrangement corresponds to the decomposition reaction TiSnO₃=TiO₂+SnO. More generally, the Sn²⁺—O—X compounds would suffer from the decomposition XₓSnO_{1+y}=SnO+XₓO_{y}. As a result, the phase stability region width of Sn²⁺—O—X is determined by the reaction energy, i.e., the formation energy difference between Sn²⁺—O—X and its constituent binary oxides SnO and XₓO_{y}. In fact, a more systematic mathematical derivation shows that the parallel region width 6 (FIG. 13) is given by

$$δ = \frac{( 1 + y ) \vert {E}_{f} ( SnO ) + {E}_{f} ( {X}_{x} {O}_{y} ) - {E}_{f} ( {X}_{x} {SnO}_{1 + y} ) \vert}{\sqrt{{x}^{2} + {y}^{2}}} \qquad ( 4 )$$

where E_{f} is the formation energy relative to the elemental phase. This equation directly relates the phase stability area to the reaction energy. The second common feature, in addition to the parallel arrangement, is that the stability areas of Sn²⁺—O—X are intervened by that of SnO₂. Such intervention arrangement also implies a chemical reaction where Sn² being oxidized to Sn⁴⁺. For example, in TiSnO₃ and Ta₂SnO₆ the Sn²⁺—O—X phase region are intervened by SnO₂ (panels (a) and (b) of FIG. 13). Therefore, the stability area width of Sn²⁺—O—X is also determined by the formation energy difference between Sn²⁺—O—X and SnO₂. Based on these two observed common geometric features, we can propose the mechanism of X increasing the stability of SnO and explain why Ta₂SnO₆ stands out exhibiting the widest phase stability region. We will elaborate this mechanism from (i) a thermodynamic perspective, i.e., the stabilization energy of Sn²⁺—O—X ternary oxides from their component binary oxides; and (ii) an electronic bonding perspective: how the introduced X—O bonds electronically interact Sn—O bonds to increase the Sn²⁺ valence stability.²⁹

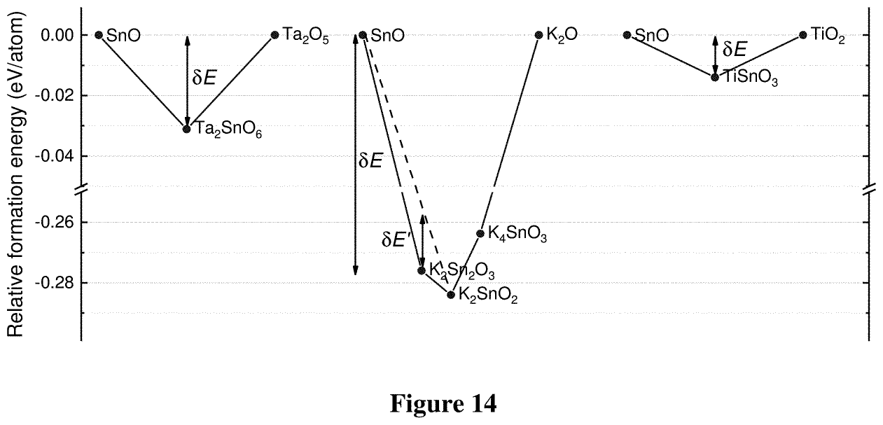

(i) Reaction energy of Sn—O—X from its constituent binary oxides. In terms of chemical composition, all Sn²⁺—O—X oxides can be viewed as the combination of SnO and XₓO_{y}. We can define the stabilization energy of the Sn²⁺—O—X oxide as the reaction energy of decomposition reaction XₓSnO_{1+y}=SnO+XₓO_{y}. The larger the stabilization energy, the more stable the Sn²⁺—O—X oxide. The stabilization energy is also referred as “depth of the binary hull”.²⁹ FIG. 14 plots the binary convex hull visualizing the stabilization energy. It is apparent that the “deeper” the formation energy of Sn²⁺—O—X, the more robust this Sn²⁺—O—X phases (note that multiple phases are present for some Sn—O—X compounds) will be against decomposition into the binary oxides. Thermochemically, when two different binary oxides react forming a ternary oxide, the reaction energy can be qualitatively predicted by the so-called Lewis acid-base interaction.³⁰ If X element is more electropositive than Sn, SnO will behave as basic oxide and XₓO_{y} as acidic oxide; conversely, if X is more electronegative than Sn, SnO will behave as the acid and XₓO_{y} as the base. For a typical Lewis acid-base interaction, a larger acidity difference between the two binary oxides generally leads to a more negative reaction energy and as a result, an increased thermodynamically stability of the ternary oxide.^{31, 32} Since the acidic and basic strength of the binary oxides are closely related to the atomic electronegativity³², that is, a high electronegativity of element corresponds to a high acidity of binary oxide, the stabilization energy of Sn²⁺—O—X can be rationalized by the electronegativity difference between Sn and X. Table 7 lists the calculated the stabilization energy of Sn²⁺—O—X relative to their binary oxides, along with their stability region width and the Sn—X electronegativity difference. Among our identified X elements, Ta and Ti are more electropositive than Sn. Since Ta is less electronegative than Ti, χ(Ta)<χ(Ti)³³, Ta₂SnO₆ shows more negative stabilization energy and presents a much wider stability area than TiSnO₃. Likewise, for electronegative elements Ge and B, SnB₄O₇ shows a slightly larger phase region than SnGeO₃ due to the larger electronegativity difference between Sn and B.³³ Nonetheless, both SnB₄O₇ and SnGeO₃ exhibits a tiny stability area due to the similarity of electronegativity between B, Ge and Sn. Note that there is only one Sn—O—X phase for these compounds, and the current thermodynamic analysis is sufficient to explain the relative stability regions in the chemical potential maps. In contrast, other Sn—O—X compounds show multiple stable phases and further examination is necessary to refine the stability analysis.

Those examples are shown for alkali metals which have large electronegativity difference with Sn, but nevertheless exhibit weak thermodynamic stabilities. A closer examination reveals that alkali metals (AMs), in addition to forming Sn²⁺—O—X p-type oxides, also constitute many other Sn—O—X ternary phases. This means that different from Ta₂SnO₆ which only competes with its binary phases SnO and Ta₂O₅, the alkali metal based Sn²⁺—O—X oxides are also subject to competition from other Sn—O—X ternary phases. For example, in the K—Sn—O chemical potential space, the identified p-type oxide K₂Sn₂O₃ would competes with K₂SnO₂ and K₄SnO₃ for stable phase region, which certainly limits its stability area. FIG. 14 illustrates that K₂Sn₂O₃ shows a large stabilization energy (SE) against SnO and K₂O, but suffers from other ternary phase competition and that K₂Sn₂O₃ does not show a “deep” formation energy (δE′) when compared to its bordered phases. We should mention that for AM group elements, the stabilization energy of AM₂Sn₂O₃ gradually increases as we move from Li to Cs, which again suggests that it is the Sn—X electronegativity difference that determines the reaction energy. Similar trend is also found in recently identified alkali earth (AE) metals based Sn²⁺—O—X where Mg and Ca do not form stable AESn₂O₃ compounds but Sr and Ba do exhibit stable Sn²⁺—O—X ternary oxides.¹¹ Note that Sn—O—P compounds also show similar behavior to K₂Sn₂O₃ due to the presence to multiple stable phases in spite of sizable reaction energy δE and parallel region width δ=1.151 eV.

TABLE 7
Summary of the stabilization energy of identified Sn²⁺-containing p-type oxides. The third element
X, Sn²⁺—O—X compounds, electronegativity of χ(X), Sn—X electronegativity difference δχ
(=χ(X) − χ(Sn)), stabilization energy δE per SnO formula unit, and the Sn²⁺—O—X phase stability
region width δ defined in FIG. 6. Clearly, the larger the Sn—X electronegativity difference δχ, the
more negative the stabilization energy of Sn²⁺—O—X against binary oxides SnO and XₓO_{y}.

| X | Sn²⁺—O—X | XₓO_{y} | χ(X)³³ | δχ | δE (eV/SnO) | δ (eV) |
|---|---|---|---|---|---|---|
| Ta | Ta₂SnO₆ | Ta₂O₅ | 1.50 | +0.46 | −0.28 | 0.312 |
| Ti | TiSnO₃ | TiO₂ | 1.54 | +0.42 | −0.07 | 0.093 |
| Ge | GeSnO₃ | GeO₂ | 2.01 | −0.05 | −0.05 | 0.067 |
| B | B₄SnO₇ | B₂O₃ | 2.04 | −0.08 | −0.16 | 0.155 |
| P | Sn₅(PO₅)₂ | P₂O₅ | 2.19 | −0.23 | −0.62 | 1.151 |
| Na | Na₂Sn₂O₃ | Na₂O | 0.93 | +1.03 | −0.47 | 0.630 |
| K | K₂Sn₂O₃ | K₂O | 0.82 | +1.14 | −0.97 | 1.301 |
| Rb | Rb₂Sn₂O₃ | Rb₂O | 0.82 | +1.14 | −1.04 | 1.395 |
| Cs | Cs₂Sn₂O₃ | Cs₂O | 0.79 | +1.17 | −0.97 | 1.301 |

(ii) X stabilizing Sn²⁺ valance state through inductive effect. In addition to decomposition into SnO and XₓO_{y}, the instability of Sn²⁺—O—X also comes from the propensity of Sn²⁺ being oxidized into Sn⁴⁺. For the stability area of Sn²⁺—O—X oxides, the potential range of X is comparably wider than that of Sn. This is due to the lower stability of SnO than XO; that is, a possible oxidation takes place in Sn²⁺—O—X because SnO in Sn²⁺—O—X can be easily oxidized. Generally, the stability of a ternary oxide is determined by its weakest component binary oxide.³⁴ Nevertheless, the Sn²⁺—O—X compounds exhibit an extended stable Sn chemical potential range when comparing to binary SnO, especially for those electropositive X. Such Sn potential range extension effect is the most pronounced when X equals to Ta where Ta₂SnO₆ phase area is horizontally much wider than SnO. This implies that X could strengthen Sn(2+)-O bond and raise the valence stability of Sn²⁺. We can apply the inductive effect³⁵ to explain the valence stability strengthening effect.²⁹ The introduction of X into SnO would induce electron density redistribution among Sn—O bond which eventually leads to an increased stability of Sn²⁺. More specifically, in consideration of X—O—Sn bonding configuration, a more electropositive X will transfer its valency electrons to oxygen more thoroughly, prompting a less electron donation from Sn to O in the Sn—O bond. This would lead to Sn reduction and more covalent character in Sn—O bond. Considering that in Sn²⁺—O—X ternary compounds, the essential bonding chemistry driving the high hole mobility is Sn 5s/O-2p bonding-antibonding electron pairs sharing interaction, an electropositive X will strengthen such bonding feature in Sn—O bond and therefore stabilize the Sn²⁺ valence state through the inductive effect. Since Ta is the most electropositive after AM elements among our identified X elements, Ta₂SnO₆ assumes the widest stability area in terms of Sn chemical potential range.

Finally, our analysis of atomic structure characters accounting for the effective masses also outlines the importance of the continuous SnOₓ network in identifying or designing high-mobility p-type oxides. For Sn—O—X ternary compounds, the VBM electronic states are mostly contributed by Sn-5s and O-2p orbitals and correspondingly, the electron transport, i.e., electron wave propagation, essentially relies on the Sn—O—Sn and Sn—Sn orbital overlap. For most Sn—O—X compounds, the addition of X atoms does not participate into this valence electronic characteristic, but only spatially separates the SnOₓ network leading to the hinderance to electron transport. A low-effective mass p-type oxide would be potentially designed if the SnOₓ polyhedra forms a continuous 3D meshwork connecting throughout the entire crystal and without being intercepted by the connected XOₓ polyhedra. Such a structural behavior generally requires a comparatively more electropositive X element as in this case Sn—O—X would be considered as Sn metallate where Sn²⁺-centered ligands constitute the framework of Sn—O—X. Such structure design principle could be applied to further precise identification of low-effective-mass Sn²⁺ based p-type oxides, and furthermore, generally extended to other reduced main group (n−1)d¹⁰s² chemistries including Pb²⁺, Bi³⁺, Sb³⁺, etc.

### Conclusions

In this example, a systematic design of Sn²⁺-based p-type oxides with high hole mobility and robust phase stability by searching for the appropriate X for Sn—O—X ternary compounds is described. Using a large database and a step-by-step filtering strategy, several promising candidate p-type oxide materials: K₂ Sn₂O₃, Rb₂Sn₂O₃, TiSnO₃, Ta₂SnO₆, and Sn₅(PO₅)₂ have been identified. These compounds exhibit wide band gaps and high carrier mobilities, suitable for p-channel materials in the vertical CMOS. Among the five identified Sn²⁺ p-type oxides, Ta₂SnO₆ achieves an overall optimal performance balancing the carrier mobility and phase stability. By performing a thorough analysis of the crystal structure, interatomic bonding, electronic structure, and thermodynamics for the identified Sn²⁺ oxides, we uncovered that a continuous Sn—O network favors for high carrier mobility and electropositive X promotes robust phase stability. The revealed structure and chemical characters favoring high mobility and good phase stability will provide useful guidance for materials design in other chemical spaces.

### REFERENCES IN EXAMPLE 2

1. Nomura, K.; Ohta, H.; Takagi, A.; Kamiya, T.; Hirano, M.; Hosono, H., Room-temperature fabrication of transparent flexible thin-film transistors using amorphous oxide semiconductors. Nature 2004, 432, (7016), 488.
2. Fortunato, E.; Barquinha, P.; Martins, R., Oxide semiconductor thin-film transistors: a review of recent advances. Adv. Mater. 2012, 24, (22), 2945-2986.
3. Ellmer, K., Past achievements and future challenges in the development of optically transparent electrodes. Nat. Photonics 2012, 6, (12), 809.
4. Petti, L.; Münzenrieder, N.; Vogt, C.; Faber, H.; Büthe, L.; Cantarella, G.; Bottacchi, F.; Anthopoulos, T. D.; Tröster, G., Metal oxide semiconductor thin-film transistors for flexible electronics. Appl. Phys. Rev 2016, 3, (2), 021303.
5. Salahuddin, S.; Ni, K.; Datta, S., The era of hyper-scaling in electronics. Nat. Electron. 2018, 1, (8), 442.
6. Ogo, Y.; Hiramatsu, H.; Nomura, K.; Yanagi, H.; Kamiya, T.; Hirano, M.; Hosono, H., p-channel thin-film transistor using p-type oxide semiconductor, SnO. Appl. Phys. Lett. 2008, 93, (3), 032113.
7. Fortunato, E.; Barros, R.; Barquinha, P.; Figueiredo, V.; Park, S.-H. K.; Hwang, C.-S.; Martins, R., Transparent p-type SnO x thin film transistors produced by reactive rf magnetron sputtering followed by low temperature annealing. Appl. Phys. Lett. 2010, 97, (5), 052105.
8. Shulaker, M. M.; Hills, G.; Park, R. S.; Howe, R. T.; Saraswat, K.; Wong, H.-S. P.; Mitra, S., Three-dimensional integration of nanotechnologies for computing and data storage on a single chip. Nature 2017, 547, (7661), 74.
9. Hautier, G.; Miglio, A.; Ceder, G.; Rignanese, G.-M.; Gonze, X., Identification and design principles of low hole effective mass p-type transparent conducting oxides. Nat. Commun. 2013, 4, 2292.
10. Ha, V.-A.; Ricci, F.; Rignanese, G.-M.; Hautier, G., Structural design principles for low hole effective mass s-orbital-based p-type oxides. J. Mater. Chem. C 2017, 5, (23), 5772-5779.
11. Li, Y.; Singh, D. J.; Du, M.-H.; Xu, Q.; Zhang, L.; Zheng, W.; Ma, Y., Design of ternary alkaline-earth metal Sn (II) oxides with potential good p-type conductivity. J. Mater. Chem. C 2016, 4, (20), 4592-4599.
12. Yim, K.; Youn, Y.; Lee, M.; Yoo, D.; Lee, J.; Cho, S. H.; Han, S. J. n. C. M., Computational discovery of p-type transparent oxide semiconductors using hydrogen descriptor. 2018, 4, (1), 1-7.
13. Broberg, D.; Medasani, B.; Zimmermann, N. E.; Yu, G.; Canning, A.; Haranczyk, M.; Asta, M.; Hautier, G., PyCDT: A Python toolkit for modeling point defects in semiconductors and insulators. Comput. Phys. Commun. 2018, 226, 165-179.
14. Banerjee, A.; Chattopadhyay, K., Recent developments in the emerging field of crystalline p-type transparent conducting oxide thin films. Prog. Cryst. Growth Charact. Mater 2005, 50, (1-3), 52-105.
15. Wang, W.; McCool, G.; Kapur, N.; Yuan, G.; Shan, B.; Nguyen, M.; Graham, U. M.; Davis, B. H.; Jacobs, G.; Cho, K. J. S., Mixed-phase oxide catalyst based on Mn-mullite (Sm, Gd) Mn2O5 for NO oxidation in diesel exhaust. 2012, 337, (6096), 832-835.
16. materialsproject.org/.
17. Kresse, G.; Hafner, J., Ab initio molecular dynamics for liquid metals. Phys. Rev. B 1993, 47, (1), 558.
18. Kresse, G.; Furthmüller, J., Efficient iterative schemes for ab initio total-energy calculations using a plane-wave basis set. Phys. Rev. B 1996, 54, (16), 11169.
19. Kresse, G.; Hafner, J., Norm-conserving and ultrasoft pseudopotentials for first-row and transition elements. J. Phys. Condens. Matter 1994, 6, (40), 8245.
20. Kresse, G.; Joubert, D., From ultrasoft pseudopotentials to the projector augmented-wave method. Phys. Rev. B 1999, 59, (3), 1758.
21. Hu, Y.; Hwang, J.; Lee, Y.; Conlin, P.; Schlom, D. G.; Datta, S.; Cho, K., First principles calculations of intrinsic mobilities in tin-based oxide semiconductors SnO, SnO2, and Ta2SnO6. J. Appl. Phys. 2019, 126, (18), 185701.
22. Hautier, G.; Fischer, C. C.; Jain, A.; Mueller, T.; Ceder, G., Finding nature's missing ternary oxide compounds using machine learning and density functional theory. Chem. Mater. 2010, 22, (12), 3762-3767.
23. Kikuchi, N.; Samizo, A.; Ikeda, S.; Aiura, Y.; Mibu, K.; Nishio, K., Carrier generation in a p-type oxide semiconductor: Sn 2 (Nb 2−x Tax) O 7. Phys. Rev. Mater. 2017, 1, (2), 021601.
24. materialsproject.org/materials/mp-556489/.
25. Schafer, H.; Eisenmann, B.; Müller, W., Zintl phases: transitions between metallic and ionic bonding. Angew. Chem. Int. 1973, 12, (9), 694-712.
26. Kittel, C.; McEuen, P.; McEuen, P., Introduction to solid state physics. Wiley New York: 1996; Vol. 8.
27. Walsh, A.; Payne, D. J.; Egdell, R. G.; Watson, G. W., Stereochemistry of post-transition metal oxides: revision of the classical lone pair model. Chem. Soc. Rev. 2011, 40, (9), 4455-4463.
28. Zhou, W.; Umezawa, N., Band gap engineering of bulk and nanosheet SnO: an insight into the interlayer Sn—Sn lone pair interactions. Phys. Chem. Chem. Phys. 2015, 17, (27), 17816-17820.
29. Sun, W.; Bartel, C. J.; Arca, E.; Bauers, S. R.; Matthews, B.; Orvañanos, B.; Chen, B.-R.; Toney, M. F.; Schelhas, L. T.; Tumas, W., A map of the inorganic ternary metal nitrides. Nat. Mater. 2019, 18, (7), 732.
30. Jensen, W. B., The Lewis acid-base concepts: an overview. Krieger Publishing Company: 1979.
31. Jayadevan, K.; Jacob, K., Trends in the stability of ternary oxides: Systems M-Pb—O (M=Ca, Sr, Ba). High Temp. Mater. Processes (London) 2000, 19, (6), 399-408.
32. Aronson, S., Estimation of the heat of formation of refractory mixed oxides. 1982.
33. www.tutor-homework.com/Chemistry Help/electronegativity_table/electronegativity.html.
34. Yokokawa, H., Generalized chemical potential diagram and its applications to chemical reactions at interfaces between dissimilar materials. Journal of phase equilibria 1999, 20, (3), 258.
35. Etourneau, J.; Portier, J.; Menil, F., The role of the inductive effect in solid state chemistry: how the chemist can use it to modify both the structural and the physical properties of the materials. J. Alloys Compd. 1992, 188, 1-7.

The foregoing is illustrative of the present invention and is not to be construed as limiting thereof. The invention is defined by the following claims, with equivalents of the claims to be included therein.

1. An electronic device comprising a p-type oxide material of formula (I):
M-O—X (I)
wherein M is a metal or metal ion having an electron configuration of (n−1)d¹⁰ns², X is a metal, metal ion, non-metal, or non-metal ion, and wherein the p-type oxide material has an Eₕᵤₗₗ less than or equal to about 0.03 eV, a hole mobility greater than about 30 cm²/Vs, and a band gap greater than or equal to about 1.5 eV.

2. The electronic device of claim 1, wherein M is selected from the group consisting of Sn²⁺, Pb²⁺, Sb³⁺, Bi³⁺, and Tl¹⁺.

3. (canceled)

4. The electronic device of claim 1, wherein X is a metal or metal ion selected from the group consisting of K, Rb, Ti, Nb, and Ta.

5. (canceled)

6. The electronic device of claim 1, wherein X is a non-metal or non-metal ion selected from the group consisting of B³⁺, Ge⁴⁺, S⁶⁺ and P⁵⁺.

7. (canceled)

8. The electronic device of claim 1, wherein the p-type oxide material is selected from the group consisting of Ta₂SnO₆, Nb₂SnO₆, TiSnO₃, K₂Sn₂O₃, Rb₂Sn₂O₃, and Sn₅(PO₅)₂.

9. The electronic device of claim 8, wherein the p-type oxide material is Ta₂SnO₆.

10-12. (canceled)

13. A method of forming an electronic device, the method comprising:
forming a gate electrode on a substrate;
forming a dielectric layer on the gate electrode, the dielectric layer comprising a p-type oxide material selected to provide extended orbital electronic states at a valence band maximum (VBM) above an oxygen p-orbital of the p-type oxide material and to provide phase stability of the p-type oxide material;
forming a semiconductor substrate on the dielectric layer opposite the gate electrode to provide a channel region in the semiconductor substrate opposite the gate electrode; and
forming a source region on the semiconductor substrate and forming a drain region on the semiconductor substrate at opposing ends of the channel region.

14. The method of claim 13, wherein the p-type oxide material comprises a ternary compound selected from the group consisting of Ta₂SnO₆, Nb₂SnO₆, TiSnO₃, K₂Sn₂O₃, Rb₂Sn₂O₃, and Sn₅(PO₅)₂.

15. The method of claim 13, wherein the extended orbital electronic states at the valence band maximum above the oxygen p-orbital of the p-type oxide material are provided by s-orbitals of a metal included in the p-type oxide material.

16. The method of claim 13, wherein the extended orbital electronic states at the valence band maximum above the oxygen p-orbital of the p-type oxide material are provided by s-orbitals of a non-metal included in the p-type oxide material.

17. The method of claim 13, wherein a metal or metal ion included in the p-type oxide material has an electron configuration of (n−1)d¹⁰ns².

18. The method of claim 13 wherein a metal included in the p-type oxide material is selected from the group consisting of Sn²⁺, Pb²⁺, Sb³⁺, Bi³⁺, and Tl¹⁺.

19. The method of claim 13 wherein a non-metal included in the p-type oxide material is selected from the group consisting of B³⁺, Ge⁴⁺, S⁶⁺ and P⁵⁺.

20. The method of claim 13 wherein the extended orbital electronic states at the valence band maximum above the oxygen p-orbital of the p-type oxide material are provided by fully or partially occupied s-orbitals of a reduced cation.

21. The method of claim 13 wherein the p-type oxide material is selected to provide extended orbital electronic states at the valence band maximum above the oxygen p-orbital of the p-type oxide material and to further provide a sufficient carrier mobility.

22. The method of claim 13 the p-type oxide material comprises a binary compound, ternary compound, or a quaternary compound.

23.-24. (canceled)

25. A semiconductor device comprising a p-type oxide material of formula (I):
M-O—X (I)
wherein M is a metal or metal ion, X is a metal, metal ion, non-metal, or non-metal ion, and wherein the p-type oxide material is selected to provide extended orbital electronic states at a valence band maximum (VBM) above an oxygen p-orbital of the p-type oxide material and to provide phase stability of the p-type oxide material.

26. (canceled)

27. The semiconductor device of claim 25, wherein the extended orbital electronic states at the valence band maximum above the oxygen p-orbital of the p-type oxide material are provided by s-orbitals of a metal included in the p-type oxide material.

28. The semiconductor device of claim 25, wherein the extended orbital electronic states at the valence band maximum above the oxygen p-orbital of the p-type oxide material are provided by s-orbitals of a non-metal included in the p-type oxide material.

29-32. (canceled)

33. The semiconductor device of claim 25 wherein the p-type oxide material is selected to provide extended orbital electronic states at the valence band maximum above the oxygen p-orbital of the p-type oxide material and to further provide a sufficient hole mobility.

34-36. (canceled)
